(19) United States
(12) Patent Application Publication
(10) Pub. No.: US 2024/0145456 A1
(43) Pub. Date: May 2, 2024

(54) SEMICONDUCTOR DEVICE

(71) Applicants: Kabushiki Kaisha Toshiba, Tokyo (JP); Toshiba Electronic Devices & Storage Corporation, Tokyo (JP)

(72) Inventors: Yuichiro NIIKURA, Kamakura Kanagawa (JP); Yukio TSUNETSUGU, Yokohama Kanagawa (JP); Hitoshi IMAI, Kawasaki Kanagawa (JP)

(21) Appl. No.: 18/457,992

(22) Filed: Aug. 29, 2023

(30) Foreign Application Priority Data
Oct. 26, 2022 (JP) 2022-171610

(51) Int. Cl. H01L 25/16

(52) U.S. Cl. CPC H01L 25/167; H01L 24/48; H01L 2224/48137

(57) ABSTRACT

According to one embodiment, a semiconductor device includes: a first insulating element and a second insulating element each controlled based on a control signal; a first control circuit configured to control selection of one of the first insulating element and the second insulating element based on the control signal; a first switch element; a second switch element; a second control circuit configured to control the first switch element based on an output of the first insulating element; and a third control circuit configured to control the second switch element based on an output of the second insulating element.

### CROSS-REFERENCE TO RELATED APPLICATIONS

This application is based upon and claims the benefit of priority from Japanese Patent Application No. 2022-171610, filed Oct. 26, 2022, the entire contents of which are incorporated herein by reference.

### FIELD

Embodiments described herein relate generally to a semiconductor device.

### BACKGROUND

There is known an insulating element that causes a switch element in a secondary-side (reception-side) circuit to perform ON/OFF operations by controlling a primary-side (transmission-side) circuit based on a control signal input thereto with the primary-side circuit and the secondary-side circuit being electrically insulated from each other. Furthermore, as a semiconductor device using such an insulating element, for example, a photo relay device is known. The photo relay device is a semiconductor relay device that includes a light emitting element, a light receiving element, and an insulating element having an insulating layer provided between the light emitting element and the light receiving element, and causes switch operations to be performed using two metal oxide semiconductor field effect transistors (MOSFETs). The photo relay device is a relay having no contact and is used in causing a primary-side circuit to perform ON/OFF controls of MOSFETs in a secondary-side circuit based on a control signal input to the primary-side circuit.

### BRIEF DESCRIPTION OF THE DRAWINGS

FIG. 1 is a circuit diagram showing an example of a configuration of a semiconductor device according to a first embodiment.

FIG. 2 is a perspective view showing an example of a structure of the semiconductor device according to the first embodiment.

FIG. 3 is a plan view showing an example of a planar structure of the semiconductor device according to the first embodiment.

FIG. 4 is a perspective view showing an example of a structure of a semiconductor device according to a first modification of the first embodiment.

FIG. 5 is a perspective view showing an example of a structure of the semiconductor device according to a second modification of the first embodiment.

FIG. 6 is a perspective view showing an example of a structure of the semiconductor device according to a third modification of the first embodiment.

FIG. 7 is a plan view showing an example of a planar structure of the semiconductor device according to the third modification of the first embodiment.

FIG. 8 is a circuit diagram showing an example of a configuration of a semiconductor device according to a fourth modification of the first embodiment.

FIG. 9 is a circuit diagram showing an example of a configuration of a semiconductor device according to a fifth modification of the first embodiment.

FIG. 10 is a circuit diagram showing an example of a configuration of a semiconductor device according to a sixth modification of the first embodiment.

FIG. 11 is a circuit diagram showing an example of a configuration of a semiconductor device according to a seventh modification of the first embodiment.

FIG. 12 is a circuit diagram showing an example of a configuration of a semiconductor device according to an eighth modification of the first embodiment.

FIG. 13 is a circuit diagram showing an example of a configuration of a semiconductor device according to a second embodiment.

FIG. 14 is a truth table showing an example of an operation of the semiconductor device according to the second embodiment.

FIG. 15 is a timing chart showing an example of the operation of the semiconductor device according to the second embodiment.

FIG. 16 is a circuit diagram showing an example of a configuration of a semiconductor device according to a first modification of the second embodiment.

FIG. 17 is a circuit diagram showing an example of a configuration of a semiconductor device according to a second modification of the second embodiment.

FIG. 18 is a circuit diagram showing an example of a configuration of a semiconductor device according to a third modification of the second embodiment.

FIG. 19 is a circuit diagram showing an example of a configuration of a semiconductor device according to a fourth modification of the second embodiment.

FIG. 20 is a circuit diagram showing an example of a configuration of a semiconductor device according to a fifth modification of the second embodiment.

FIG. 21 is a circuit diagram showing an example of a configuration of a semiconductor device according to a third embodiment.

FIG. 22 is a truth table showing an example of an operation of the semiconductor device according to the third embodiment.

FIG. 23 is a timing chart showing an example of the operation of the semiconductor device according to the third embodiment.

FIG. 24 is a circuit diagram showing an example of a configuration of a semiconductor device according to a fourth embodiment.

FIG. 25 is a circuit diagram showing an example of a configuration of a secondary-side circuit within the semiconductor device according to the fourth embodiment.

FIG. 26 is a circuit diagram showing an example of a configuration of a semiconductor device according to a first modification of the fourth embodiment.

FIG. 27 is a circuit diagram showing an example of a configuration of a semiconductor device according to a fifth embodiment.

FIG. 28 is a perspective view showing an example of a structure of the semiconductor device according to the fifth embodiment.

FIG. 29 is a plan view showing an example of a planar structure of the semiconductor device according to the fifth embodiment.

### DETAILED DESCRIPTION

In general, according to one embodiment, a semiconductor device includes: a first insulating element and a second insulating element each controlled based on a control signal; a first control circuit configured to control selection of one of the first insulating element and the second insulating element based on the control signal; a first switch element; a second switch element; a second control circuit configured to control the first switch element based on an output of the first insulating element; and a third control circuit configured to control the second switch element based on an output of the second insulating element.

Hereinafter, embodiments will be described with reference to the accompanying drawings. The dimensions and ratios in the drawings are not always the same as the actual ones. In the following description, constituent elements having substantially the same function and configuration will be assigned the same reference symbol and repeat descriptions may be omitted. In the case where elements having similar configurations are distinguished from each other in particular, their identical reference symbols may be assigned different letters or numbers. All of the descriptions of an embodiment are applicable as descriptions of another embodiment, unless explicitly or self-evidently excluded.

### 1. First Embodiment

A semiconductor device according to a first embodiment will be described. As an example of the semiconductor device, the present embodiment will describe a photo relay device that controls ON/OFF of a switch element in a secondary-side circuit based on a control signal by utilizing optical coupling between a light emitting element and a light receiving element. In the following description, a control signal for a primary-side circuit to use in controlling such a switch element of the secondary-side circuit will also be simply referred to as a signal.

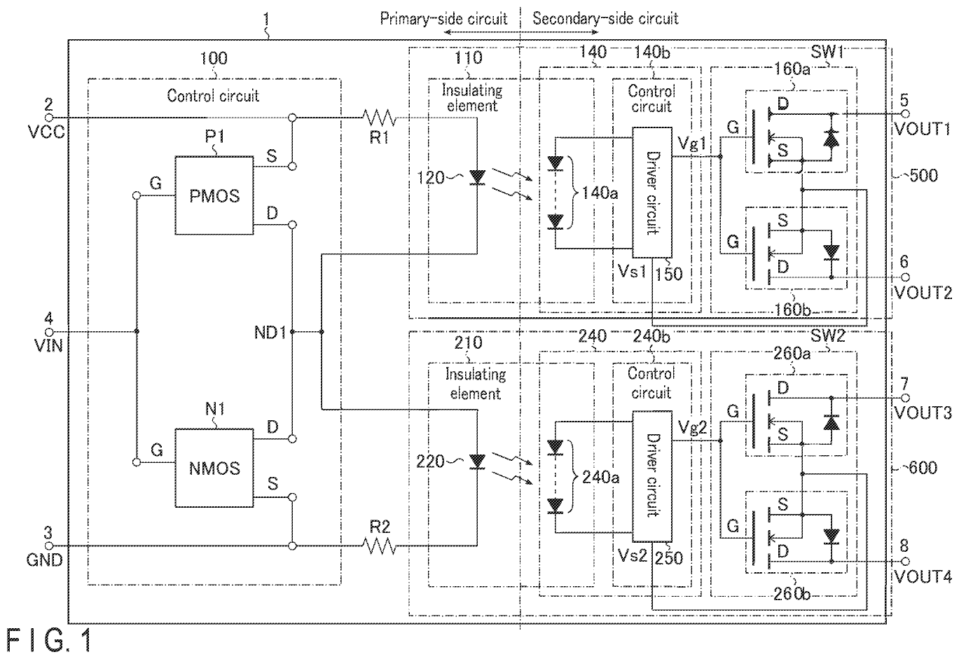

A configuration of the semiconductor device will be described with reference to FIG. 1. FIG. 1 is a circuit diagram showing an example of the configuration of the semiconductor device.

As shown in FIG. 1, a semiconductor device 1 is comprised of a power supply voltage terminal 2, a ground voltage terminal 3, a control input terminal 4, input/output terminals 5 to 8, a control circuit 100, resistance elements R1 and R2, insulating elements 110 and 210, control circuits 140b and 240b, a switch element SW1 including Metal Oxide Semiconductor Field Effect Transistors (MOSFETs) 160a and 160b, and a switch element SW2 including MOSFETs 260a and 260b.

A power supply voltage VCC is externally supplied to the power supply voltage terminal 2.

A ground voltage GND is externally supplied to the ground voltage terminal 3. The ground voltage terminal 3 may be ground.

A voltage VIN is externally supplied to the control input terminal 4. The voltage VIN is a voltage (hereinafter also referred to as a “control signal”) for controlling an operation of the semiconductor device 1. The voltage VIN is a voltage at a high (H) level or a voltage at a low (L) level.

Each of the input/output terminals 5 to 8 is coupled to a circuit, etc. externally provided. A voltage VOUT1 is input to or output from the input/output terminal 5. A voltage VOUT2 is input to or output from the input/output terminal 6. A voltage VOUT3 is input to or output from the input/output terminal 7. A voltage VOUT4 is input to or output from the input/output terminal 8. The switch elements SW1 and SW2 are bidirectional switch elements. Therefore, in the case where the switch elements SW1 and SW2 are turned on, the input/output terminals 5 to 8 may be either an input or an output. For example, in the case where the voltage VOUT1 is positive and the voltage VOUT2 is negative, a current flows into the input/output terminal 5.

The MOSFETs 160a, 160b, 260a, and 260b are, for example, n-channel MOS transistors of an enhancement type. The MOSFETs 160a, 160b, 260a, and 260b are used in controlling a signal to be transmitted. A threshold voltage of each of the MOSFETs 160a, 160b, 260a, and 260b is, for example, 1 V. In the case where the MOSFETs 160a and 160b are in the ON state, the semiconductor device 1 transmits a signal via the input/output terminals 5 and 6. In the case where the MOSFETs 160a and 160b are in an OFF state, the semiconductor device 1 transmits no signal. Furthermore, in the case where the MOSFETs 260a and 260b are in the ON state, the semiconductor device 1 transmits a signal via the input/output terminals 7 and 8. In the case where the MOSFETs 260a and 260b are in the OFF state, the semiconductor device 1 transmits no signal. The semiconductor device 1 may transmit a signal via either the input/output terminals 5 and 6 or the input/output terminals 7 and 8. In the following, the combination of MOSFETs 160a and 160b will also be referred to as the switch element SW1. The combination of MOSFETs 260a and 260b will also be referred to as the switch element SW2.

The control circuit 100 is a circuit configured to control the insulating elements 110 and 210 based on the voltage VIN. Specifically, the control circuit 100 controls selection of one of the insulating element 110 and the insulating element 210 based on the voltage VIN. The control circuit 100 includes a p-channel MOS transistor P1 (hereinafter referred to as a “transistor P1”) and an re-channel MOS transistor N1 (hereinafter referred to as a “transistor N1”).

The voltage VIN is applied to a gate of the transistor P1. The voltage VCC is applied to a source of the transistor P1. A drain of the transistor P1 is coupled to a node ND1.

The voltage VIN is applied to a gate of the transistor N1. A drain of the transistor N1 is coupled to the node ND1. The voltage GND is applied to a source of the transistor N1.

One end of the resistance element R1 is coupled to the source of the transistor P1. The other end of the resistance element R1 is coupled to the insulating element 110. One end of the resistance element R2 is coupled to the source of the transistor N1. The other end of the resistance element R2 is coupled to the insulating element 210. The resistance elements R1 and R2 may be included in the control circuit 100.

The insulating elements 110 and 210 are elements capable of controlling ON/OFF of the switch elements SW1 and SW2 in the secondary-side circuit based on a control signal while maintaining electrical insulation between an input and an output. The insulating element 110 includes a light emitting element 120 and a light receiving element 140a. The light emitting element 120 and the light receiving element 140a are electrically insulated from each other by an insulating layer (not shown) provided therebetween. The insulating element 210 includes a light emitting element 220 and a light receiving element 240a. The light emitting element 220 and the light receiving element 240a are electrically insulated from each other by an insulating layer (not shown) provided therebetween.

The light emitting elements 120 and 220 are, for example, light emitting diodes (LEDs). The following will describe the case in which the light emitting elements 120 and 220 are LEDs. An anode of the light emitting element 120 is coupled to the other end of the resistance element R1. A cathode of the light emitting element 120 is coupled to the node ND1. An anode of the light emitting element 220 is coupled to the node ND1. A cathode of the light emitting element 220 is coupled to the other end of the resistance element R2. In other words, the light emitting elements 120 and 220 are coupled in series.

With the control circuit 100 thus configured, either the insulating element 110 or the insulating element 210 is selected based on a voltage of the node ND1.

The light receiving elements 140a and 240a are, for example, photodiodes, phototransistors, etc. The following will describe the case in which the light receiving elements 140a and 240a are photodiodes. The light receiving elements 140a and 240a include, for example, several to dozens of photodiodes coupled in series. Both ends of the light receiving element 140a are coupled to the control circuit 140b. Both ends of the light receiving element 240a are coupled to the control circuit 240b. In the following, the combination of light receiving element 140a and control circuit 140b will also be referred to as a light receiving unit 140. The combination of light receiving element 240a and control circuit 240b will also be referred to as a light receiving unit 240. The light receiving units 140 and 240 are each, for example, a photo diode array (PDA) and exhibit independent optical interference (have a configuration with no crosstalk).

The control circuit 140b is a circuit configured to control the MOSFETs 160a and 160b based on voltages at both ends of the light receiving element 140a. Specifically, the control circuit 140b controls a gate voltage and a source voltage of the MOSFET 160a and a gate voltage and a source voltage of the MOSFET 160b (switch element SW1) based on voltages at both ends of the light receiving element 140a, that is, an output of the insulating element 110 (light receiving element 140a). The control circuit 140b includes a driver circuit 150.

The driver circuit 150 is a circuit configured to drive the MOSFETs 160a and 160b based on voltages at both ends of the light receiving element 140a. For example, the driver circuit 150 applies a voltage Vg1 based on voltages at both ends of the light receiving element 140a to gates of the MOSFETs 160a and 160b. The voltage Vg1 is, for example, a voltage at an anode of the light receiving element 140a. The driver circuit 150 applies a voltage Vs1 based on voltages at both ends of the light receiving element 140a to sources of the MOSFETs 160a and 160b. The voltage Vs1 is, for example, a voltage at a cathode of the light receiving element 140a.

The control circuit 240b is a circuit configured to control the MOSFETs 260a and 260b based on voltages at both ends of the light receiving element 240a. Specifically, the control circuit 240b controls a gate voltage and a source voltage of the MOSFET 260a and a gate voltage and a source voltage of the MOSFET 260b (switch element SW2) based on voltages at both ends of the light receiving element 240a, that is, an output of the insulating element 210 (light receiving element 240a). The control circuit 240b includes a driver circuit 250.

The driver circuit 250 is a circuit configured to drive the MOSFETs 260a and 260b based on voltages at both ends of the light receiving element 240a. For example, the driver circuit 250 applies a voltage Vg2 based on voltages at both ends of the light receiving element 240a to gates of the MOSFETs 260a and 260b. The voltage Vg2 is, for example, a voltage at an anode of the light receiving element 240a. The driver circuit 250 applies a voltage Vs2 based on voltages at both ends of the light receiving element 240a to sources of the MOSFETs 260a and 260b. The voltage Vs2 is, for example, a voltage at a cathode of the light receiving element 240a. The configuration of the driver circuit 250 may be the same as or different from that of the driver circuit 150.

The gate of the MOSFET 160a is coupled to the gate of the MOSFET 160b. The source of the MOSFET 160a is coupled to the source of the MOSFET 160b. A drain of the MOSFET 160a is coupled to the input/output terminal 5. A drain of the MOSFET 160b is coupled to the input/output terminal 6. The gate of the MOSFET 260a is coupled to the gate of the MOSFET 260b. The source of the MOSFET 260a is coupled to the source of the MOSFET 260b. A drain of the MOSFET 260a is coupled to the input/output terminal 7. A drain of the MOSFET 260b is coupled to the input/output terminal 8.

The semiconductor device 1 configured as described above controls the switch elements SW1 and SW2 based on a signal by utilizing optical coupling between the light emitting element 120 and the light receiving element 140a and optical coupling between the light emitting element 220 and the light receiving element 240a. In other words, a signal based on the voltage VIN (a signal obtained by converting the voltage VIN into light) is transmitted between the light emitting element 120 and the light receiving element 140a, and between the light emitting element 220 and the light receiving element 240a. Furthermore, the semiconductor device 1 includes a photo relay 500 having the light emitting element 120, the light receiving element 140a, and the switch element SW1, and a photo relay 600 having the light emitting element 220, the light receiving element 240a, and the switch element SW2. In the present embodiment, the power supply voltage terminal 2, the ground voltage terminal 3, the control input terminal 4, the control circuit 100, the resistance elements R1 and R2, and the light emitting elements 120 and 220 correspond to the primary-side (transmission-side) circuit. The light receiving elements 140a and 240a, the control circuits 140b and 240b, the MOSFETs 160a, 160b, 260a, and 260b, and the input/output terminals 5 to 8 correspond to the secondary-side (reception-side) circuit. Meanwhile, the configurations of the primary-side circuit and the secondary-side circuit are not limited to those described above.

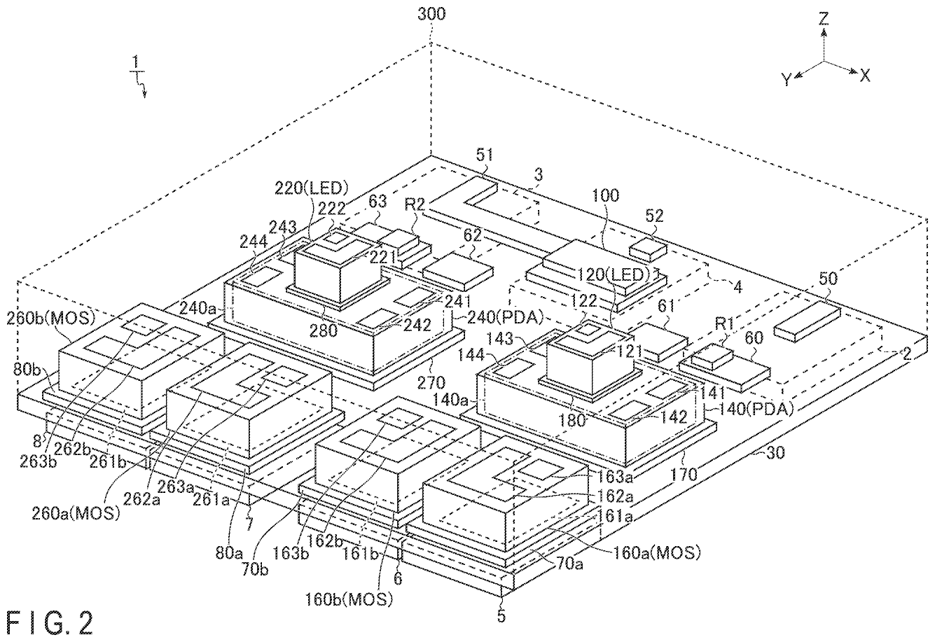

Next, the structure of the semiconductor device 1 will be described with reference to FIG. 2. FIG. 2 is a perspective view showing an example of the structure of the semiconductor device 1. In the following description, a Z direction corresponds to a direction perpendicular to a surface of a substrate for use in formation of the semiconductor device 1. An X direction is a direction parallel to the surface of the aforementioned substrate. A Y direction is a direction parallel to the surface of the aforementioned substrate and perpendicular to the X direction. For easy reference to FIG. 2, illustration of interconnects within the semiconductor device 1 is omitted.

As shown in FIG. 2, the semiconductor device 1 is a package of electronic components. The semiconductor device 1 further includes a substrate 30, electrodes 50 to 52, 60 to 63, 70a, 70b, 80a, and 80b, supporting bases 170 and 270, adhesive layers 180 and 280, and a sealing member 300. In the following description, with reference to the substrate 30 and the MOSFET 160a, an end on which the MOSFET 160a is arranged will be referred to as an upper end in the Z direction. With reference to the substrate 30 and the MOSFET 160a, furthermore, an end on which the substrate is arranged will be referred to as a lower end in the Z direction. The electrodes 60 to 63 may be eliminated. In such a case, the resistance elements R1 and R2 are provided in the control circuit 100 (are included in the control circuit 100).

The substrate 30 is, for example, a circuit substrate using a bismaleimide triazine (BT) resin or a flexible substrate (flexible printed circuit: FPC) using polyimide.

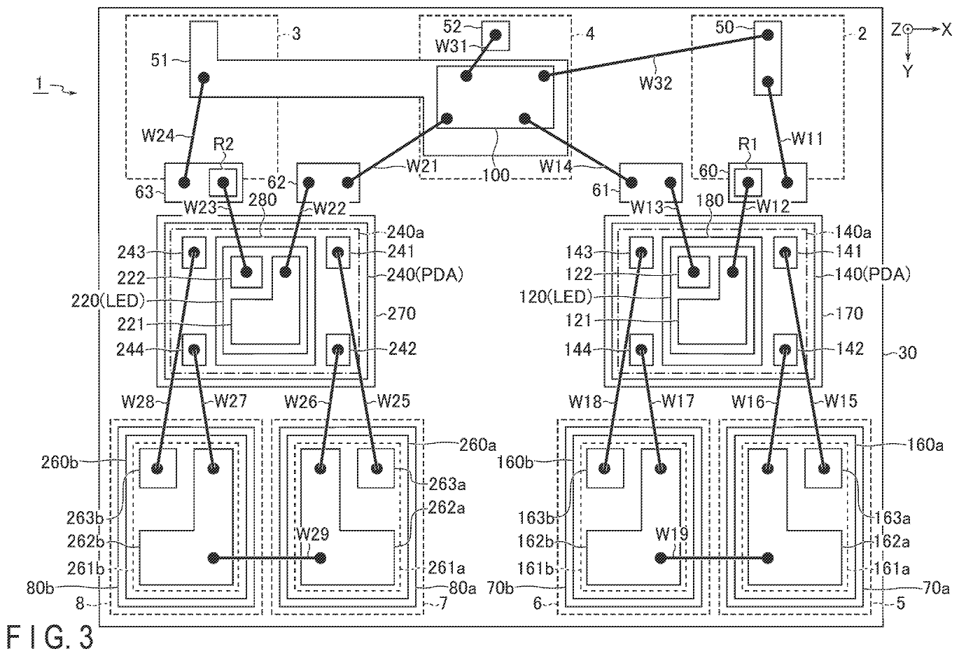

The electrodes 50 to 52, 60 to 63, 70a, 70b, 80a, and 80b are provided on the upper surface of the substrate 30. The electrode 51 is formed into, for example, a substantially letter L shape when viewed from a top (when viewed from the top of the drawing sheet of FIG. 2). The electrode 51 may be configured in such a manner that one end portion to which an interconnect W24 is coupled (see FIG. 3) and the other end portion on which an element configuring the control circuit 100 is installed each have a size necessary for assembly, a portion connecting these end portions may be narrower than them in the Y direction, and denaturation is made to increase adhesion between the substrate 30 and the sealing member 300.

The control circuit 100 is provided on the upper surface of the electrode 51. The control circuit 100 is electrically coupled to the electrode 51.

The resistance element R1 is provided on the upper surface of the electrode 60. The resistance element R1 is electrically coupled to the electrode 60. The resistance element R2 is provided on the upper surface of the electrode 63. The resistance element R2 is electrically coupled to the electrode 63.

The MOSFETs 160a, 160b, 260a, and 260b are provided as different chips, respectively.

The MOSFET 160a includes the electrodes 161a, 162a, and 163a. The electrode 161a is arranged on the lower surface of the MOSFET 160a. On the lower surface of the MOSFET 160a, the electrode 161a is arranged in contact with the electrode 70a. By this, the MOSFET 160a is provided on the upper surface of the electrode 70a. In other words, the MOSFET 160a is provided above the substrate 30. The electrodes 162a and 163a are arranged on the upper surface of the MOSFET 160a. The electrode 161a functions as a drain electrode of the MOSFET 160a. The electrode 162a functions as a source electrode of the MOSFET 160a. The electrode 163a functions as a gate electrode of the MOSFET 160a.

The MOSFET 160b includes electrodes 161b, 162b, and 163b. The electrode 161b is arranged on the lower surface of the MOSFET 160b. On the lower surface of the MOSFET 160b, the electrode 161b is arranged in contact with the electrode 70b. By this, the MOSFET 160b is provided on the upper surface of the electrode 70b. In other words, the MOSFET 160b is provided above the substrate 30. The electrodes 162b and 163b are arranged on the upper surface of the MOSFET 160b. The electrode 161b functions as a drain electrode of the MOSFET 160b. The electrode 162b functions as a source electrode of the MOSFET 160b. The electrode 163b functions as a gate electrode of the MOSFET 160b.

The MOSFET 260a includes electrodes 261a, 262a, and 263a. The electrode 261a is arranged on the lower surface of the MOSFET 260a. On the lower surface of the MOSFET 260a, the electrode 261a is arranged in contact with the electrode 80a. By this, the MOSFET 260a is provided on the upper surface of the electrode 80a. In other words, the MOSFET 260a is provided above the substrate 30. The electrodes 262a and 263a are arranged on the upper surface of the MOSFET 260a. The electrode 261a functions as a drain electrode of the MOSFET 260a. The electrode 262a functions as a source electrode of the MOSFET 260a. The electrode 263a functions as a gate electrode of the MOSFET 260a.

The MOSFET 260b includes electrodes 261b, 262b, and 263b. The electrode 261b is arranged on the lower surface of the MOSFET 260b. On the lower surface of the MOSFET 260b, the electrode 261b is arranged in contact with the electrode 80b. By this, the MOSFET 260b is provided on the upper surface of the electrode 80b. In other words, the MOSFET 260b is provided above the substrate 30. The electrodes 262b and 263b are arranged on the upper surface of the MOSFET 260b. The electrode 261b functions as a drain electrode of the MOSFET 260b. The electrode 262b functions as a source electrode of the MOSFET 260b. The electrode 263b functions as a gate electrode of the MOSFET 260b.

The MOSFETs 260b, 260a, 160b, and 160a are arranged in this order in the X direction, for example.

The supporting base 170 is provided on the upper surface of the substrate 30. The supporting base 170 supports the light receiving unit 140 and the light emitting element 120. The supporting base 170 may be a conductor or may be an insulator. The supporting base 170 is formed into a plate shape extending in the X direction and the Y direction.

The light receiving unit 140 is provided as a chip including the light receiving element 140a. The light receiving unit 140 is arranged in such a manner that the light receiving element 140a is in contact with the upper surface of the supporting base 170. In other words, the light receiving element 140a is provided above the substrate 30. Furthermore, the light receiving element 140a is arranged on the upper surface of the light receiving unit 140. The light receiving unit 140 is arranged in such a manner that, for example, the light receiving element 140a has a light receiving surface on its upper surface.

The light receiving element 140a includes electrodes 141 to 144. The electrodes 141 to 144 are arranged on the upper surface of the light receiving element 140a. Although not shown in FIG. 2, the electrodes 141 and 143 are electrically coupled together within the light receiving element 140a, for example. Furthermore, although not shown in FIG. 2, the electrodes 142 and 144 are electrically coupled together within the light receiving element 140a, for example. The electrodes 141 and 143 each function as an anode electrode of the light receiving element 140a, for example. The electrodes 142 and 144 each function as a cathode electrode of the light receiving element 140a, for example.

The supporting base 270 is provided on the upper surface of the substrate 30. The supporting base 270 supports the light receiving unit 240 and the light emitting element 220. The supporting base 270 may be a conductor or may be an insulator. The supporting base 270 is formed into a plate shape extending in the X direction and the Y direction.

The light receiving unit 240 is provided as a chip including the light receiving element 240a. The light receiving unit 240 is arranged in such a manner that the light receiving element 240a is in contact with the upper surface of the supporting base 270. In other words, the light receiving element 240a is provided above the substrate 30. Furthermore, the light receiving element 240a is arranged on the upper surface of the light receiving unit 240. The light receiving unit 240 is arranged in such a manner that, for example, the light receiving element 240a has a light receiving surface on its upper surface.

The light receiving element 240a includes electrodes 241 to 244. The electrodes 241 to 244 are arranged on the upper surface of the light receiving element 240a. Although not shown in FIG. 2, the electrodes 241 and 243 are electrically coupled together within the light receiving element 240a, for example. Furthermore, although not shown in FIG. 2, the electrodes 242 and 244 are electrically coupled together within the light receiving element 240a, for example. The electrodes 241 and 243 each function as an anode electrode of the light receiving element 240a, for example. The electrodes 242 and 244 each function as a cathode electrode of the light receiving element 240a, for example.

The light emitting elements 120 and 220 are provided as different chips, respectively.

The light emitting element 120 is arranged above the light receiving element 140a. The light emitting element 220 is arranged above the light receiving element 240a. The light emitting elements 120 and 220 respectively have light irradiation surfaces on their lower surfaces. The irradiation surface of the light emitting element 120 faces a light receiving surface of the light receiving element 140a. The irradiation surface of the light emitting element 220 faces a light receiving surface of the light receiving element 240a. For example, the irradiation surface of each of the light emitting elements 120 and 220 is greater in size than the corresponding one of the light receiving surfaces of the light receiving elements 140a and 240a.

The light emitting element 120 includes electrodes 121 and 122. The electrodes 121 and 122 are arranged on the upper surface of the light emitting element 120. The electrode 121 functions as an anode electrode of the light emitting element 120, for example. The electrode 122 functions as a cathode electrode of the light emitting element 120, for example.

The light emitting element 220 includes electrodes 221 and 222. The electrodes 221 and 222 are arranged on the upper surface of the light emitting element 220. The electrode 221 functions as an anode electrode of the light emitting element 220, for example. The electrode 222 functions as a cathode electrode of the light emitting element 220, for example.

The adhesive layer 180 in contact with each of the light emitting element 120 and the light receiving element 140a is arranged between the light emitting element 120 and the light receiving element 140a. Furthermore, the adhesive layer 280 in contact with each of the light emitting element 220 and the light receiving element 240a is arranged between the light emitting element 220 and the light receiving element 240a. Each of the adhesive layers 180 and 280 includes an insulating material having transmissibility to light emitted from the light emitting elements 120 and 220, for example. Such an insulating material is, for example, a silicone or an epoxy resin. The adhesive layers 180 and 280 are, for example, insulating films including such an insulating material. The adhesive layers 180 and 280 may be formed using an insulating paste including such an insulating material, for example. The adhesive layers 180 and 280 formed of an insulating film is greater in film thickness than those formed using an insulating paste. In order to improve pressure resistance, each of the adhesive layers 180 and 280 is preferably an insulating film.

The power supply voltage terminal 2, the ground voltage terminal 3, and the control input terminal 4 are arranged in contact with the lower surface of the substrate 30, for example. Although not shown in FIG. 2, the power supply voltage terminal 2 is electrically coupled to the electrode 50 via a conductor penetrating the substrate 30. Although not shown in FIG. 2, the ground voltage terminal 3 is electrically coupled to the electrode 51 via a conductor penetrating the substrate 30. Although not shown in FIG. 2, the control input terminal 4 is electrically coupled to the electrode 52 via a conductor penetrating the substrate 30.

The input/output terminals 5 to 8 are arranged in contact with the lower surface of the substrate 30, for example. Although not shown in FIG. 2, the input/output terminal 5 is electrically coupled to the electrode 161a of the MOSFET 160a via a conductor penetrating the substrate and the electrode 70a. Although not shown in FIG. 2, the input/output terminal 6 is electrically coupled to the electrode 161b of the MOSFET 160b via a conductor penetrating the substrate 30 and the electrode 70b. Although not shown in FIG. 2, the input/output terminal 7 is electrically coupled to the electrode 261a of the MOSFET 260a via a conductor penetrating the substrate 30 and the electrode 80a. Although not shown in FIG. 2, the input/output terminal 8 is electrically coupled to the electrode 261b of the MOSFET 260b via a conductor penetrating the substrate 30 and the electrode 80b.

The sealing member 300 is provided in such a manner as to cover the MOSFETs 160a, 160b, 260a, and 260b, the supporting bases 170 and 270, the light receiving units 140 and 240, the light emitting elements 120 and 220, the electrodes 50 to 52, 60 to 63, 70a, 70b, 80a, and 80b, the control circuit 100, and the resistance elements R1 and R2. A distance from each of the electrodes 50 to 52, 60 to 63, 70a, 70b, 80a, and 80b to the edge of the substrate 30 is set such that the sealing member 300 does not peel off when the MOSFETs 160a, 160b, 260a, and 260b, the supporting bases 170 and 270, the light receiving units 140 and 240, the light emitting elements 120 and 220, the electrodes 50 to 52, 60 to 63, 70a, 70b, 80a, and 80b, the control circuit 100, and the resistance elements R1 and R2 are covered with the sealing member 300. The sealing member 300 includes a non-translucent material. Such a non-translucent material is, for example, an epoxy resin into which a silicon carbide or a carbon black is kneaded. By this, the sealing member 300 protects the semiconductor device 1 and also prevents light leakage between the photo relays 500 and 600.

Herein, such light leakage includes light crosstalk between the photo relays 500 and 600 and light leakage from the light emitting elements 120 and 220 to a channel of each MOSFET. Examples of the light crosstalk include light emitted from the light emitting element 120 being leaked to the light receiving surface of the light receiving element 240a and light emitted from the light emitting element 220 being leaked to the light receiving surface of the light receiving element 140a. By suppressing such light crosstalk, a MOSFET in the OFF state is prevented from unintentionally transitioning to the ON state. Furthermore, a channel of a MOSFET may include a portion having photosensitivity. In such a case, each of the MOSFETs in the ON state or the OFF state is prevented from unintentionally transitioning to the OFF state or the ON state, by suppressing light leakage from the light emitting elements 120 and 220 to a channel of the MOSFET concerned.

The resistance elements R1 and R2 may be each incorporated into the control circuit 100. In such a case, the control circuit 100 may be directly coupled to the anode electrode 121 of the light emitting element 120 and the cathode electrode 222 of the light emitting element 220.

Electrical coupling within the semiconductor device 1 will be described with reference to FIG. 3. FIG. 3 is a plan view showing an example of the planar structure of the semiconductor device 1.

As shown in FIG. 3, the semiconductor device 1 further includes interconnects W11 to W19, W21 to W29, W31 and W32.

The interconnects W11 to W19, W21 to W29, W31, and W32 are, for example, wires that are formed by wire bonding. The interconnects W11 to W19, W21 to W29, W31, and W32 are formed of a conductive material. The interconnects W11 to W19, W21 to W29, W31, and W32 may be, for example, a flexible substrate.

The interconnect W11 provides electrical coupling between the electrode 50 and the electrode 60. The interconnect W12 provides electrical coupling between the resistance element R1 and the electrode 121. The interconnect W13 provides electrical coupling between the electrode 61 and the electrode 122. The interconnect W14 provides electrical coupling between the control circuit 100 and the electrode 61. The interconnect W15 provides electrical coupling between the electrode 141 and the electrode 163a. The interconnect W16 provides electrical coupling between the electrode 142 and the electrode 162a. The interconnect W17 provides electrical coupling between the electrode 144 and the electrode 162b. The interconnect W18 provides electrical coupling between the electrode 143 and the electrode 163b. The interconnect W19 provides electrical coupling between the electrode 162a and the electrode 162b.

The interconnect W21 provides electrical coupling between the control circuit 100 and the electrode 62. The interconnect W22 provides electrical coupling between the electrode 62 and the electrode 221. The interconnect W23 provides electrical coupling between the resistance element R2 and the electrode 222. The interconnect W24 provides electrical coupling between the electrode 51 and the electrode 63. The interconnect W25 provides electrical coupling between the electrode 241 and the electrode 263a. The interconnect W26 provides electrical coupling between the electrode 242 and the electrode 262a. The interconnect W27 provides electrical coupling between the electrode 244 and the electrode 262b. The interconnect W28 provides electrical coupling between the electrode 243 and the electrode 263b. The interconnect W29 provides electrical coupling between the electrode 262a and the electrode 262b.

The interconnect W31 provides electrical coupling between the electrode 52 and the control circuit 100. The interconnect W32 provides electrical coupling between the electrode 50 and the control circuit 100.

In the case of eliminating the electrodes 60 to 63, the number of interconnects can be reduced by coupling the control circuit 100 to the light emitting element 120 via an interconnect and coupling the control circuit 100 to the light emitting element 220 via an interconnect. Specifically, the resistance elements R1 and R2 are each incorporated into the control circuit 100. The interconnects W12 and W13 are eliminated, and the interconnect W11 is directly coupled to the electrode 121, and the interconnect W14 is directly coupled to the electrode 122. The interconnects W22 and W23 may be eliminated, the interconnect W21 may be directly coupled to the electrode 221, and the interconnect W24 may be directly coupled to the electrode 222.

Next, the operation of the semiconductor device 1 will be described with reference to FIG. 1.

In the case where the voltage VIN is at the “H” level, the transistor P1 is turned off, and the transistor N1 is turned on. By this, a voltage of the node ND1 becomes the voltage GND (“L” level). As a result, since a current flows from the anode to the cathode of the light emitting element 120, the light emitting element 120 transitions to the ON state (emission state). At this time, because the resistance element R1 is provided, a current flowing through the light emitting element 120 is limited such that the light emitting element 120 is not destroyed. Furthermore, since a current does not flow from the anode to the cathode of the light emitting element 220, the light emitting element 220 transitions to the OFF state (non-emission state).

In the case where the light emitting element 120 transitions to the ON state, the light receiving element 140a receives light from the light emitting element 120, thereby generating a voltage. The driver circuit 150 applies the voltage Vg1 (a voltage greater than the threshold voltage of the MOSFETs 160a and 160b, for example, 5 V) at the “H” level based on voltages at both ends of the light receiving element 140a to the gates of the MOSFETs 160a and 160b. The driver circuit 150 applies the voltage Vs1 (for example, the voltage GND) at the “L” level based on voltages at both ends of the light receiving element 140a to the sources of the MOSFETs 160a and 160b. By this, the MOSFETs 160a and 160b (the switch element SW1) are turned on, and the input/output terminals 5 and 6 are electrically coupled together. Furthermore, in the case where the light emitting element 220 transitions to the OFF state, the light receiving element 240a receives no light from the light emitting element 220, thereby generating no voltage. The driver circuit 250 applies the voltage Vg2 (for example, the voltage GND) at the “L” level based on voltages at both ends of the light receiving element 240a to the gates of the MOSFETs 260a and 260b. The driver circuit 250 applies the voltage Vs2 (for example, the voltage GND) at the “L” level based on voltages at both ends of the light receiving element 240a to the sources of the MOSFETs 260a and 260b. By this, the MOSFETs 260a and 260b (the switch element SW2) are turned off, and the input/output terminals 7 and 8 are not electrically coupled together.

On the other hand, in the case where the voltage VIN is at the “L” level, the transistor P1 is turned on, and the transistor N1 is turned off. By this, a voltage of the node ND1 becomes the voltage VCC (“H” level). As a result, since a current does not flow from the anode to the cathode of the light emitting element 120, the light emitting element 120 transitions to the OFF state (non-emission state). Furthermore, since a current flows from the anode to the cathode of the light emitting element 220, the light emitting element 220 transitions to the ON state (emission state). At this time, because the resistance element R2 is provided, a current flowing through the light emitting element 220 is limited such that the light emitting element 220 is not destroyed.

In the case where the light emitting element 120 transitions to the OFF state, the light receiving element 140a receives no light from the light emitting element 120, thereby generating no voltage. The driver circuit 150 applies the voltage Vg1 (for example, the voltage GND) at the “L” level based on voltages at both ends of the light receiving element 140a to the gates of the MOSFETs 160a and 160b. The driver circuit 150 applies the voltage Vs1 (for example, the voltage GND) at the “L” level based on voltages at both ends of the light receiving element 140a to the sources of the MOSFETs 160a and 160b. By this, the MOSFETs 160a and 160b (the switch element SW1) are turned off, and the input/output terminals 5 and 6 are not electrically coupled together. In the case where the light emitting element 220 transitions to the ON state, the light receiving element 240a receives light from the light emitting element 220, thereby generating a voltage. The driver circuit 250 applies the voltage Vg2 (voltage greater than the threshold voltage of the MOSFETs 260a and 260b, for example, 5 V) at the “H” level based on voltages at both ends of the light receiving element 240a to the gates of the MOSFETs 260a and 260b. The driver circuit 250 applies the voltage Vs2 (for example, the voltage GND) at the “L” level based on voltages at both ends of the light receiving element 240a to the sources of the MOSFETs 260a and 260b. By this, the MOSFETs 260a and 260b (the switch element SW2) are turned on, and the input/output terminals 7 and 8 are electrically coupled together.

According to the present embodiment, the switch elements SW1 and SW2 can be made to be alternatively conductive. In other words, the switch elements SW1 and SW2 can be prevented from being simultaneously turned on.

The semiconductor device 1 according to the present embodiment includes the control circuit 100, the insulating elements 110 and 210, the control circuits 140b and 240b, and the MOSFETs 160a, 160b, 260a, and 260b.

The control circuit 100 controls selection of either the insulating element 110 or the insulating element 210 based on the control signal VIN.

Specifically, the control circuit 100 includes the transistors P1 and N1. The control signal VIN is input to the gate of the transistor P1, the voltage VCC is applied to the source of the transistor P1, and the drain of the transistor P1 is coupled to the node ND1. The control signal VIN is input to the gate of the transistor N1, the drain of the transistor N1 is coupled to the node ND1, and the voltage GND is applied to the source of the transistor N1.

With the configuration described above, one of the insulating elements 110 and 210 is selected based on a voltage of the node ND1. That is, in the present embodiment, one of the light emitting elements 120 and 220 is selected based on a voltage of the node ND1. In other words, based on a voltage of the node ND1, the light emitting element 220 transitions to the OFF state while the light emitting element 120 is in the ON state, and the light emitting element 220 transitions to the ON state while the light emitting element 120 is in the OFF state. Since the light emitting elements 120 and 220 alternatively emit light, the light receiving elements 140a and 240a alternatively receive light. In the case where the light receiving element 140a receives light, the MOSFETs 160a and 160b (the switch element SW1) are turned on by the control circuit 140b. In the case where the light receiving element 140a receives no light, the MOSFETs 160a and 160b (the switch element SW1) are turned off by the control circuit 140b. In the case where the light receiving element 240a receives light, the MOSFETs 260a and 260b (the switch element SW2) are turned on by the control circuit 240b. In the case where the light receiving element 240a receives no light, the MOSFETs 260a and 260b (the switch element SW2) are turned off by the control circuit 240b. Thus, according to the present embodiment, the switch elements SW1 and SW2 can be prevented from being simultaneously turned on.

Furthermore, with the configuration according to the present embodiment, even in the case where the control signal VIN becomes open, the switch element SW2 can be turned on to bring about a latch state.

The MOSFETs have variations in the characteristic value between elements. As with the MOSFETs, the light receiving elements and the light emitting elements also have variations in characteristic value between elements. The variations in characteristic value of the MOSFETs correspond to a difference between a characteristic value of each MOSFET included in one of the photo relays of the semiconductor device and a characteristic value of each MOSFET included in the other photo relay, for example. The characteristic values of a MOSFET include, for example, a turn-on starting time at the time of supplying a voltage of a predetermined magnitude (charging current) to the MOSFET concerned. The variations in characteristic value between the light receiving elements correspond to a difference in light sensitivity between one light receiving element and the other light receiving element, for example. The variations in characteristic value between the light emitting elements correspond to a difference in irradiation light intensity between one light emitting element and the other light emitting element, for example.

According to the present embodiment, as the MOSFETs 160a, 160b, 260a, and 260b, MOSFETs of the same type, that is, the n-channel MOSFETs of the enhancement type, are used. This can approximate dynamic characteristics of ON and OFF of the switch elements SW1 and SW2, that is, the characteristic values of the MOSFETs. Accordingly, dead time can be designed easily as compared to the case where the MOSFETs have larger variations in characteristic values.

Furthermore, according to the present embodiment, the semiconductor device 1 is formed as a single package. Therefore, for example, through the manufacturing process, chips that are close to each other within the same wafer can be used as the MOSFETs 160a, 160b, 260a, and 260b. As with the MOSFETs 160a, 160b, 260a, and 260b, for example, chips that are close to each other within the same wafer can be used as the light receiving elements 140a and 240a. As with the MOSFETs 160a, 160b, 260a, and 260b, for example, chips that are close to each other within the same wafer can be used as the light emitting elements 120 and 220. This can suppress an increase in variations in characteristic value between the MOSFETs, an increase in variations in characteristic value between the light receiving elements, and an increase in variations in characteristic value between the light emitting elements.

Furthermore, according to the present embodiment, the light emitting element 120 is arranged above the light receiving element 140a. The light emitting element 220 is arranged above the light receiving element 240a. In other words, the light emitting element 120 is close to the light receiving element 140a. The light emitting element 220 is close to the light receiving element 240a. This can improve photoelectric effects.

### (First Modification)

A semiconductor device according to a first modification of the first embodiment will be described. The semiconductor device 1 according to the first modification of the first embodiment differs from that of the first embodiment in terms of structure. The following will omit a description of a configuration similar to that of the first embodiment and will mainly provide a description of a configuration different from that of the first embodiment.

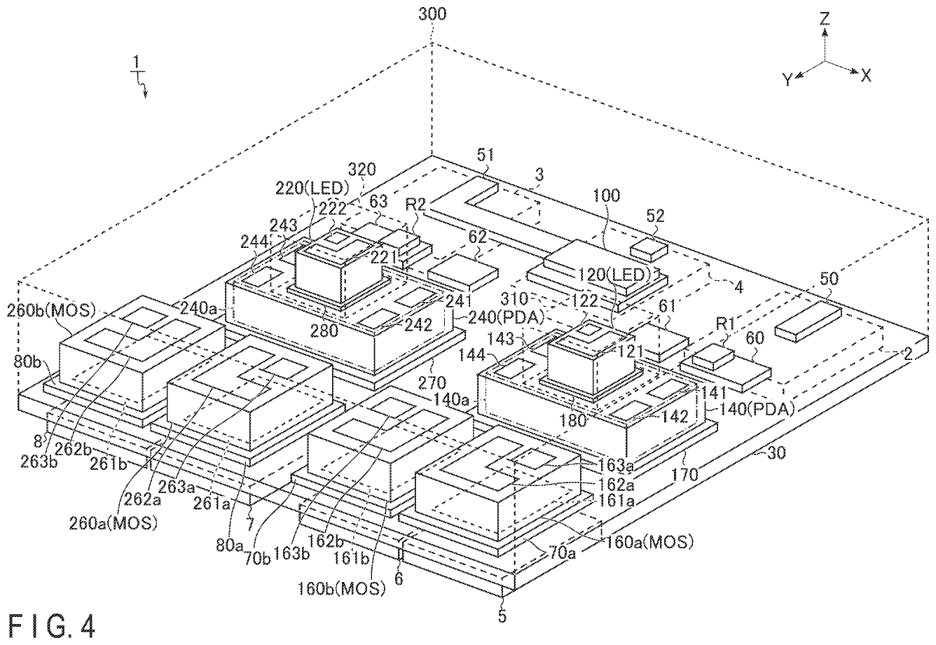

The structure of the semiconductor device 1 will be described with reference to FIG. 4. FIG. 4 is a perspective view showing an example of the structure of the semiconductor device 1. FIG. 4 omits illustration of interconnects as with FIG. 2.

As shown in FIG. 4, the semiconductor device 1 further includes sealing members 310 and 320.

The sealing member 310 is provided in such a manner as to cover the partial upper surface of the light receiving unit 140, the adhesive layer 180, and the light emitting element 120. The sealing member 320 is provided in such a manner as to cover the partial upper surface of the light receiving unit 240, the adhesive layer 280, and the light emitting element 220. The sealing members 310 and 320 include a non-translucent material smaller in thermal expansion coefficient than the sealing member 300. Examples of the non-translucent material include an epoxy resin and a silicone resin.

The sealing member 300 is provided in such a manner as to cover the sealing members 310 and 320, the electrodes 50 to 52, 60 to 63, 70a, 70b, 80a, and 80b, the control circuit 100, the MOSFETs 160a, 160b, 260a, and 260b, the supporting bases 170 and 270, the side surfaces and the partial upper surfaces of the light receiving units 140 and 240, and the resistance elements R1 and R2.

The substrates 60 to 63 may be eliminated. In such a case, the resistance elements R1 and R2 are provided in the control circuit 100.

The rest of the structure is similar to that shown in FIG. 2 and FIG. 3 described in the first embodiment.

The present modification produces advantageous effects similar to those of the first embodiment.

Furthermore, according to the present modification, the partial upper surface of the light receiving unit 140 (the light receiving element 140a), the adhesive layer 180, and the light emitting element 120 are covered with the sealing member 310. The partial upper surface of the light receiving unit 240 (the light receiving element 240a), the adhesive layer 280, and the light emitting element 220 are covered with the sealing member 320. This enables the sealing member 310 to protect the adhesive layer 180 provided between the light emitting element 120 and the light receiving element 140a (to suppress a decrease in the amount of light reaching the light receiving surface of the light receiving element 140a due to peeling between the light receiving surface of the light receiving element 140a and the light emitting surface of the light emitting element 120 caused by a stress exerted when a sealing resin 300 is thermally deformed). This also enables the sealing member 320 to protect the adhesive layer 280 provided between the light emitting element 220 and the light receiving element 240a (to suppress a decrease in the amount of light reaching the light receiving surface of the light receiving element 240a due to peeling between the light receiving surface of the light receiving element 240a and the light emitting surface of the light emitting element 220 caused by a stress exerted when the sealing resin 300 is thermally deformed). Furthermore, the sealing members 310 and 320 can suppress change over time of light received by the light receiving surface of the light receiving elements (140a and 240a) between the photo relays 500 and 600.

### (Second Modification)

A semiconductor device according to a second modification of the first embodiment will be described. The semiconductor device 1 according to the second modification of the first embodiment differs from that of the first embodiment in terms of structure. The following will omit a description of a configuration similar to that of the first embodiment and will mainly provide a description of a configuration different from that of the first embodiment.

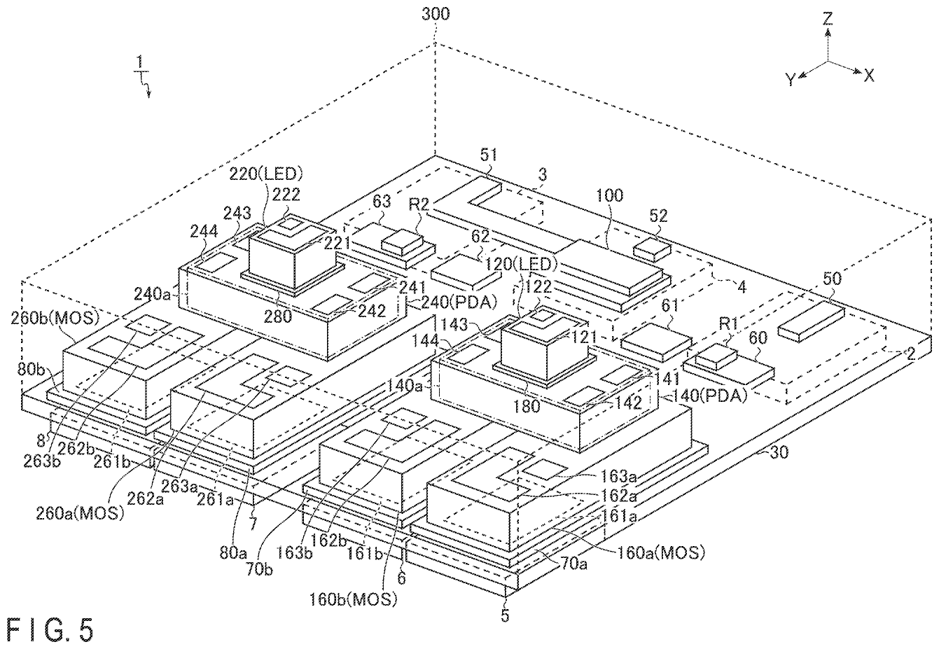

The structure of the semiconductor device 1 will be described with reference to FIG. 5. FIG. 5 is a perspective view showing an example of the structure of the semiconductor device 1.

As shown in FIG. 5, the light receiving unit 140 (the light receiving element 140a) is provided on, for example, two adjacent MOSFETs (the MOSFETs 160a and 160b). In other words, in the example shown in FIG. 5, the light receiving element 140a includes a portion in contact with the upper surfaces of the MOSFETs 160a and 160b. The light receiving unit 140 is spaced apart from the electrodes 162a, 163a, 162b, and 163b. The light receiving unit 240 (the light receiving element 240a) is provided on, for example, two adjacent MOSFETs (the MOSFETs 260a and 260b). In other words, in the example shown in FIG. 5, the light receiving element 240a includes a portion in contact with the upper surfaces of the MOSFETs 260a and 260b. The light receiving unit 240 is spaced apart from the electrodes 262a, 263a, 262b, and 263b. The supporting bases 170 and 270 in the first embodiment are eliminated.

The adhesive layers 180 and 280 are, for example, insulating films.

The substrates 60 to 63 may be eliminated. In such a case, the resistance elements R1 and R2 are provided in the control circuit 100. Furthermore, the interconnects can be reduced in number as described in the first embodiment, thereby realizing downsizing and manufacturing at a low cost.

The rest of the structure is similar to that shown in FIG. 2 and FIG. 3 described in the first embodiment.

The present modification produces advantageous effects similar to those of the first embodiment.

Furthermore, according to the present modification, the light receiving unit 140 is provided on the MOSFETs 160a and 160b. The light receiving unit 240 is provided on the MOSFETs 260a and 260b. For this reason, channel portions of the respective MOSFETs having light sensitivity can be shielded. Furthermore, it is also possible to combine the first modification.

### (Third Modification)

A semiconductor device according to a third modification of the first embodiment will be described. The semiconductor device 1 according to the third modification of the first embodiment differs from that of the second modification of the first embodiment in terms of structure. In the following description, the description of the similar configurations to those of the second modification of the first embodiment will be omitted, and the configurations different from those of the second modification of the first embodiment will be mainly described.

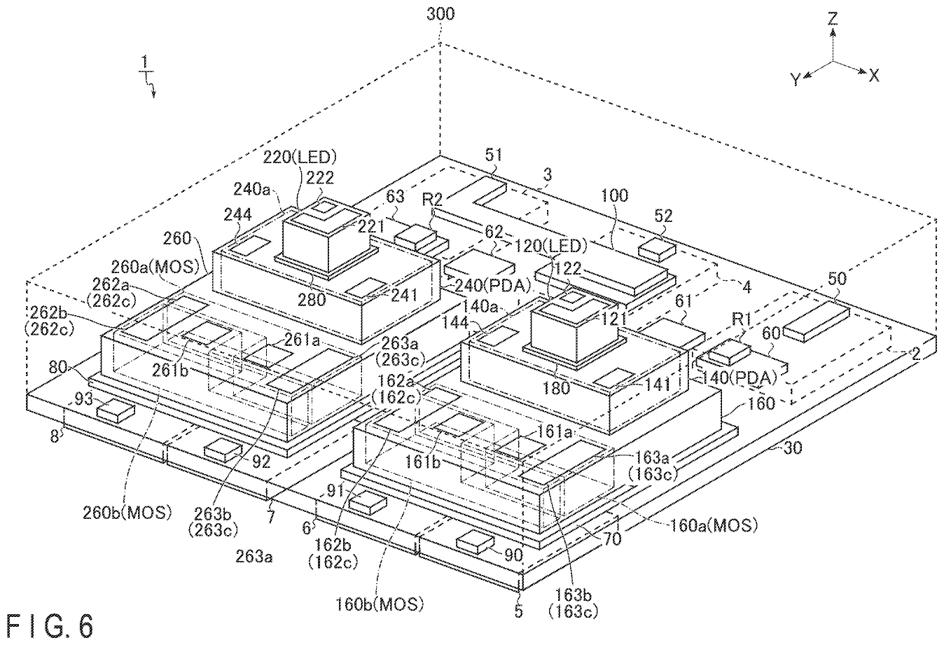

The structure of the semiconductor device 1 will be described with reference to FIG. 6. FIG. 6 is a perspective view showing an example of the structure of the semiconductor device 1.

As shown in FIG. 6, the semiconductor device 1 further includes electrodes 70, 80, and 90 to 93. The electrodes 70a, 70b, 80a, and 80b in the second modification of the first embodiment are eliminated.

The electrodes 70, 80, and 90 to 93 are provided on the upper surface of the substrate 30.

The electrodes 141 and 144 are arranged on a side close to the MOSFET 160a in the Y direction on the upper surface of the light receiving element 140a. The electrodes 142 and 143 are eliminated.

The MOSFETs 160a and 160b are provided as, for example, a single chip (hereinafter referred to as a “chip 160”). In other words, the MOSFETs 160a and 160b (the chip 160) are provided on the electrode 70 in an integral manner. In the example shown in FIG. 6, the electrodes 161a and 161b are arranged on the upper surface of the chip 160. The electrode 161a is spaced apart from the electrode 161b. The electrodes 162a and 162b described with reference to FIG. 5 and each functioning as a source electrode are integrally formed as a common electrode (hereinafter referred to as an “electrode 162c”). The electrode 162c is arranged on the upper surface of the chip 160. The electrode 162c is spaced apart from the electrode 161b. The electrodes 163a and 163b described with reference to FIG. 5 and each functioning as a gate electrode are integrally formed as a common electrode (hereinafter referred to as an “electrode 163c”). The electrode 163c is arranged on the upper surface of the chip 160. The electrode 163c is spaced apart from the electrode 161a. The MOSFET 160a includes the electrodes 161a, 162c, and 163c. The MOSFET 160b includes the electrodes 161b, 162c, and 163c.

The electrodes 241 and 244 are arranged on a side close to the MOSFET 260a in the Y direction on the upper surface of the light receiving element 240a. The electrodes 242 and 243 are eliminated.

The MOSFETs 260a and 260b are provided as, for example, a single chip (hereinafter referred to as a “chip 260”). In other words, the MOSFETs 260a and 260b (the chip 260) are provided on the electrode 80 in an integral manner. In the example shown in FIG. 6, the electrodes 261a and 261b are arranged on the upper surface of the chip 260. The electrode 261a is spaced apart from the electrode 261b. The electrodes 262a and 262b described with reference to FIG. 5 and each functioning as a source electrode are integrally formed as a common electrode (hereinafter referred to as an “electrode 262c”). The electrode 262c is arranged on the upper surface of the chip 260. The electrode 262c is spaced apart from the electrode 261b. The electrodes 263a and 263b described with reference to FIG. 5 and each functioning as a gate electrode are integrally formed as a common electrode (hereinafter referred to as an “electrode 263c”). The electrode 263c is arranged on the upper surface of the chip 260. The electrode 263c is spaced apart from the electrode 261a. The MOSFET 260a includes the electrodes 261a, 262c, and 263c. The MOSFET 260b includes the electrodes 261b, 262c, and 263c.

The light receiving unit 140 (the light receiving element 140a) is provided on, for example, the MOSFETs 160a and 160b (the chip 160). The light receiving unit 240 (the light receiving element 240a) is provided on, for example, the MOSFETs 260a and 260b (the chip 260). The adhesive layers 180 and 280 are, for example, insulating films.

Although not shown in FIG. 6, the input/output terminal 5 is electrically coupled to the electrode 90 via a conductor penetrating the substrate 30. Although not shown in FIG. 6, the input/output terminal 6 is electrically coupled to the electrode 91 via a conductor penetrating the substrate 30. Although not shown in FIG. 6, the input/output terminal 7 is electrically coupled to the electrode 92 via a conductor penetrating the substrate 30. Although not shown in FIG. 6, the input/output terminal 8 is electrically coupled to the electrode 93 via a conductor penetrating the substrate 30.

The rest of the structure is similar to that shown in FIG. 5 described in the second modification of the first embodiment.

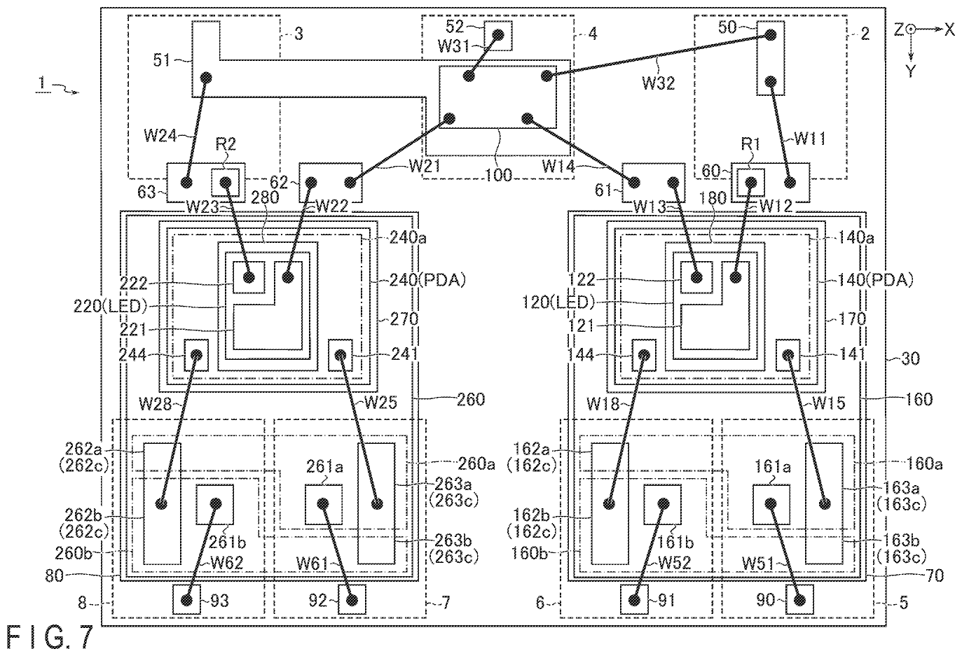

Electrical coupling within the semiconductor device 1 will be described with reference to FIG. 7. FIG. 7 is a plan view showing an example of the planar structure of the semiconductor device 1.

As shown in FIG. 7, the semiconductor device 1 further includes interconnects W51, W52, W61, and W62. The interconnects W16, W17, W19, W26, W27, and W29 in the first embodiment are eliminated.

The interconnect W15 provides electrical coupling between the electrode 141 and the electrode 163c. The interconnect W18 provides electrical coupling between the electrode 144 and the electrode 162c. The interconnect W25 provides electrical coupling between the electrode 241 and the electrode 263c. The interconnect W28 provides electrical coupling between the electrode 244 and the electrode 262c.

The interconnects W51, W52, W61, and W62 are, for example, wires that are formed by wire bonding. The interconnects W51, W52, W61, and W62 are formed of a conductive material. The interconnects W51, W52, W61, and W62 may be, for example, a flexible substrate.

The interconnect W51 provides electrical coupling between the electrode 161a and the electrode 90. The interconnect W52 provides electrical coupling between the electrode 161b and the electrode 91. The interconnect W61 provides electrical coupling between the electrode 261a and the electrode 92. The interconnect W62 provides electrical coupling between the electrode 261b and the electrode 93.

The rest of the structure is similar to that shown in FIG. 3 described in the first embodiment.

The electrodes 60 to 63 may be eliminated. In such a case, the resistance elements R1 and R2 are provided in the control circuit 100. Furthermore, the interconnects can be reduced in number as described in the first embodiment, thereby realizing downsizing and manufacturing at a low cost.

The present modification also produces advantageous effects similar to those of the second modification of the first embodiment.

According to the present modification, the MOSFETs 160a and 160b are provided as, for example, a single chip. The MOSFETs 260a and 260b are provided as, for example, a single chip. For this reason, the light receiving unit 140 is easily arranged on the MOSFETs 160a and 160b. The light receiving unit 240 is easily arranged on the MOSFETs 260a and 260b. This facilitates formation of a stacked structure of the MOSFETs, the light receiving units, and the light emitting elements.

### (Fourth Modification)

A semiconductor device according to a fourth modification of the first embodiment will be described. The semiconductor device 1 according to the fourth modification of the first embodiment differs from that of the first embodiment in that it controls the switch elements SW1 and SW2 based on a signal utilizing magnetic coupling (magnetic field coupling). The following will omit a description of a configuration similar to that of the first embodiment and will mainly provide a description of a configuration different from that of the first embodiment.

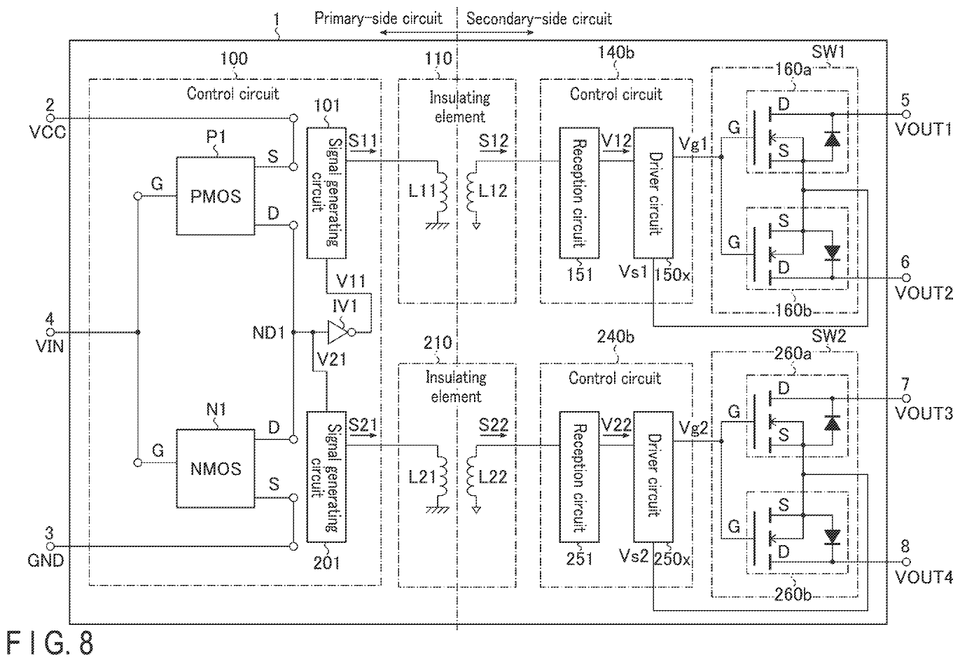

The configuration of the semiconductor device 1 will be described with reference to FIG. 8. FIG. 8 is a circuit diagram showing an example of the configuration of the semiconductor device 1.

As shown in FIG. 8, the control circuit 100 further includes an inverter circuit IV1 and signal generating circuits 101 and 201.

An input terminal of the inverter circuit IV1 is coupled to the node ND1 and the signal generating circuit 201. An output terminal of the inverter circuit IV1 is coupled to the signal generating circuit 101.

The signal generating circuit 101 is a circuit configured to generate a signal based on a voltage. Specifically, for example, the signal generating circuit 101 operates in the case where a voltage V11 output from the inverter circuit IV1 is at the “H” level. In the case where the voltage V11 is at the “H” level, the signal generating circuit 101 modulates the voltage V11 and transmits the modulated voltage as a signal S11 to one end of a coil L11 to be described later.

The signal generating circuit 201 is a circuit configured to generate a signal based on a voltage. Specifically, for example, the signal generating circuit 201 operates in the case where a voltage V21 input to the inverter circuit IV1 (a voltage of the node ND1) is at the “H” level. In the case where the voltage V21 is at the “H” level, the signal generating circuit 201 modulates the voltage V21 and transmits the modulated voltage as a signal S21 to one end of a coil L21 to be described later.

The insulating element 110 has a configuration in which the light emitting element 120 and the light receiving element 140a in the first embodiment are replaced with coils L11 and L12. Specifically, for example, one end of the coil L11 is coupled to the signal generating circuit 101. The other end of the coil L11 is grounded. One end of the coil L12 is coupled to the control circuit 140b (a reception circuit 151 to be described later). The other end of the coil L12 is grounded. The coil L11 and the coil L12 are electrically insulated from each other by an insulating layer (not shown) provided therebetween.

The insulating element 210 has a configuration in which the light emitting element 220 and the light receiving element 240a in the first embodiment are replaced with coils L21 and L22. Specifically, for example, one end of the coil L21 is coupled to the signal generating circuit 201. The other end of the coil L21 is grounded. One end of the coil L22 is coupled to the control circuit 240b (a reception circuit 251 to be described later). The other end of the coil L22 is grounded. The coil L21 and the coil L22 are electrically insulated from each other by an insulating layer (not shown) provided therebetween.

The control circuit 140b further includes a reception circuit 151. Furthermore, the control circuit 140b has a configuration in which the driver circuit 150 in the first embodiment is replaced with a driver circuit 150x.

The reception circuit 151 is a circuit configured to receive a signal. Specifically, for example, the reception circuit 151 demodulates a signal S12 received from the coil L12 and supplies the demodulated signal as a voltage V12 to the driver circuit 150x.

The driver circuit 150x is a circuit configured to drive the MOSFETs 160a and 160b based on the voltage V12 supplied from the reception circuit 151. For example, the driver circuit 150x applies the voltage Vg1 based on the voltage V12 to gates of the MOSFETs 160a and 160b. The driver circuit 150x applies the voltage Vs1 based on the voltage V12 to the sources of the MOSFETs 160a and 160b. The voltage Vg1 is, for example, a voltage equal to or greater than the voltage Vs1. In the case where the voltage V12 is not supplied from the reception circuit 151, for example, the driver circuit 150x applies a voltage at the “L” level as the voltage Vg1 to the gates of the MOSFETs 160a and 160b, and applies a voltage at the “L” level as the voltage Vs1 to the sources of the MOSFETs 160a and 160b.

As described above, the control circuit 140b controls a gate voltage and a source voltage of the MOSFET 160a and a gate voltage and a source voltage of the MOSFET 160b based on an output of the insulating element 110 (the coil L12).

The control circuit 240b further includes a reception circuit 251. Furthermore, the control circuit 240b has a configuration in which the driver circuit 250 in the first embodiment is replaced with a driver circuit 250x.

The reception circuit 251 is a circuit configured to receive a signal. Specifically, for example, the reception circuit 251 demodulates a signal S22 received from the coil L22 and supplies the demodulated signal as a voltage V22 to the driver circuit 250x.

The driver circuit 250x is a circuit configured to drive the MOSFETs 260a and 260b based on the voltage V22 supplied from the reception circuit 251. For example, the driver circuit 250x applies the voltage Vg2 based on the voltage V22 to the gates of the MOSFETs 260a and 260b. The driver circuit 250x applies the voltage Vs2 based on the voltage V22 to the sources of the MOSFETs 260a and 260b. The voltage Vg2 is, for example, a voltage equal to or greater than the voltage Vs2. In the case where the voltage V22 is not supplied from the reception circuit 251, for example, the driver circuit 250x applies a voltage at the “L” level as the voltage Vg2 to the gates of the MOSFETs 260a and 260b, and applies a voltage at the “L” level as the voltage Vs2 to the sources of the MOSFETs 260a and 260b.

As described above, the control circuit 240b controls a gate voltage and a source voltage of the MOSFET 260a and a gate voltage and a source voltage of the MOSFET 260b based on an output of the insulating element 210 (the coil L22).

As shown in FIG. 8, the resistance elements R1 and R2 in the first embodiment are eliminated from the primary-side circuit.

The rest of the circuit configuration is similar to that shown in FIG. 1 described in the first embodiment.

Next, the operation of the semiconductor device 1 will be described with reference to FIG. 8.

In the case where the voltage VIN is at the “H” level, the transistor P1 is turned off, and the transistor N1 is turned on. By this, a voltage of the node ND1 becomes the voltage GND (“L” level). As a result, since a voltage at the “L” level is supplied to the signal generating circuit 201, the signal generating circuit 201 does not operate. For this reason, the reception circuit 251 does not receive the signal S22 from the coil L22, and the voltage V22 is not supplied to the driver circuit 250x, so that the MOSFETs 260a and 260b (the switch element SW2) are turned off. Furthermore, since a voltage at the “H” level is supplied to the signal generating circuit 101, the signal generating circuit 101 generates the signal S11 based on the voltage V11 and transmits the generated signal S11 to one end of the coil L11.

In the case where the signal S11 is input to the coil L11, a current flows through the coil L11 based on the signal S11. This generates a magnetic field in the coil L11. This magnetic field causes a change in a magnetic flux that penetrates the coil L12. This causes a current (inductive current) to flow through the coil L12. In the case where a current flows through the coil L12, based on this current, the signal S12 is transmitted from the coil L12 to the reception circuit 151.

In the case where the reception circuit 151 receives the signal S12, the reception circuit 151 transmits the voltage V12 based on the signal S12 to the driver circuit 150x. The driver circuit 150x applies the voltage Vg1 (for example, 5 V) at the “H” level based on the voltage V12 supplied from the reception circuit 151 to the gates of the MOSFETs 160a and 160b. The driver circuit 150x applies the voltage Vs1 (for example, the voltage GND) at the “L” level based on the voltage V12 to the sources of the MOSFETs 160a and 160b. By this, the MOSFETs 160a and 160b (the switch element SW1) are turned on.

On the other hand, in the case where the voltage VIN is at the “L” level, the transistor P1 is turned on, and the transistor N1 is turned off. By this, a voltage of the node ND1 becomes the voltage VCC (“H” level). As a result, since a voltage at the “L” level is supplied to the signal generating circuit 101, the signal generating circuit 101 does not operate. For this reason, the reception circuit 151 does not receive the signal S12 from the coil L12, and the voltage V12 is not supplied to the driver circuit 150x, so that the MOSFETs 160a and 160b (the switch element SW1) are turned off. Furthermore, since a voltage at the “H” level is supplied to the signal generating circuit 201, the signal generating circuit 201 generates the signal S21 based on the voltage V21 and transmits the generated signal S21 to one end of the coil L21.

In the case where the signal S21 is input to the coil L21, a current flows through the coil L21 based on the signal S21. This generates a magnetic field in the coil L21. This magnetic field causes a change in magnetic flux that penetrates the coil L22. This causes a current (inductive current) to flow through the coil L22. In the case where a current flows through the coil L22, based on this current, the signal S22 is transmitted from the coil L22 to the reception circuit 251.

In the case where the reception circuit 251 receives the signal S22, the reception circuit 251 transmits the voltage V22 based on the signal S22 to the driver circuit 250x. The driver circuit 250x applies the voltage Vg2 (for example, 5 V) at the “H” level based on the voltage V22 supplied from the reception circuit 251 to the gates of the MOSFETs 260a and 260b. The driver circuit 250x applies the voltage Vs2 (for example, the voltage GND) at the “L” level based on the voltage V22 to the sources of the MOSFETs 260a and 260b. By this, the MOSFETs 260a and 260b (the switch element SW2) are turned on.

As described above, the semiconductor device 1 configured as described above controls the switch elements SW1 and SW2 based on a signal by utilizing magnetic coupling between the coil L11 and the coil L12, and magnetic coupling between the coil L21 and the coil L22.

The present modification also produces advantageous effects similar to those of the first embodiment.

### (Fifth Modification)

A semiconductor device according to a fifth modification of the first embodiment will be described. The semiconductor device 1 according to the fifth modification of the first embodiment differs from that of the fourth modification of the first embodiment in terms of type of magnetic coupling. In the following description, the description of the similar configurations to those of the fourth modification of the first embodiment will be omitted, and the configurations different from those of the fourth modification of the first embodiment will be mainly described.

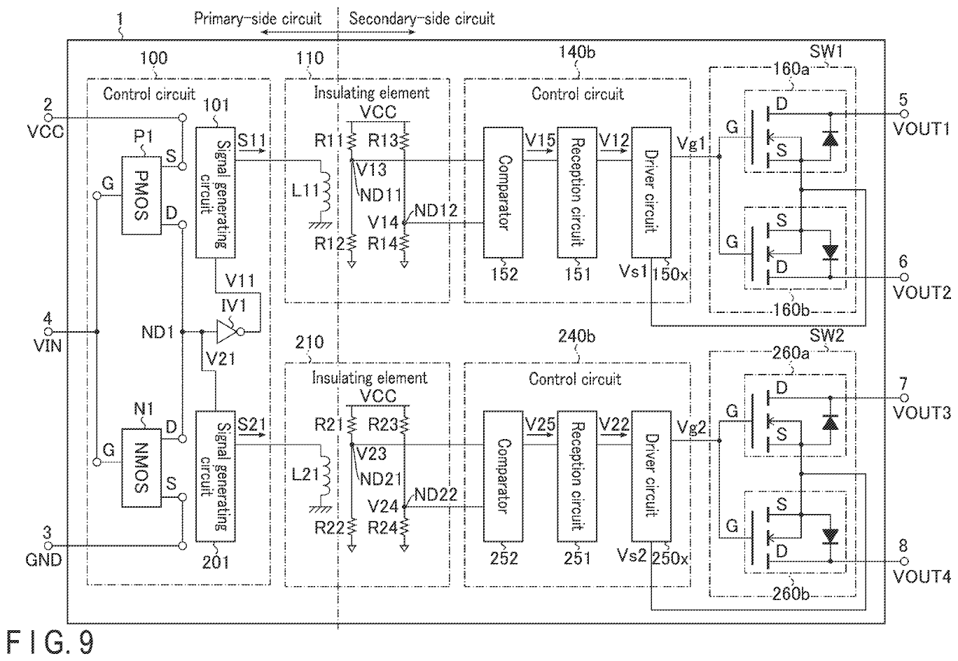

The configuration of the semiconductor device 1 will be described with reference to FIG. 9. FIG. 9 is a circuit diagram showing an example of the configuration of the semiconductor device 1.

As shown in FIG. 9, the insulating element 110 has a configuration in which the coil L12 in the fourth modification of the first embodiment is replaced with magnetic resistance elements R11 to R14. Examples of the magnetic resistance elements include a hall element. Specifically, for example, the voltage VCC is applied to one end of the magnetic resistance element R11. The other end of the magnetic resistance element R11 is coupled to the node ND11. One end of the magnetic resistance element R12 is coupled to the node ND11. The other end of the magnetic resistance element R12 is grounded. The node ND11 is coupled to the control circuit 140b (a comparator 152 to be described later). The voltage VCC is applied to one end of the magnetic resistance element R13. The other end of the magnetic resistance element R13 is coupled to the node ND12. One end of the magnetic resistance element R14 is coupled to the node ND12. The other end of the magnetic resistance element R14 is grounded. The node ND12 is coupled to the control circuit 140b (a comparator 152 to be described later). The coil L11 and the set of magnetic resistance elements R11 to R14 are electrically insulated from each other by an insulating layer (not shown) provided therebetween.

The insulating element 210 has a configuration in which the coil L22 in the fourth modification of the first embodiment is replaced with magnetic resistance elements R21 to R24. Specifically, for example, the voltage VCC is applied to one end of the magnetic resistance element R21. The other end of the magnetic resistance element R21 is coupled to the node ND21. One end of the magnetic resistance element R22 is coupled to the node ND21. The other end of the magnetic resistance element R22 is grounded. The node ND21 is coupled to the control circuit 240b (a comparator 252 to be described later). The voltage VCC is applied to one end of the magnetic resistance element R23. The other end of the magnetic resistance element R23 is coupled to the node ND22. One end of the magnetic resistance element R24 is coupled to the node ND22. The other end of the magnetic resistance element R24 is grounded. The node ND22 is coupled to the control circuit 240b (the comparator 252 to be described later). The coil L21 and the set of magnetic resistance elements R21 to R24 are electrically insulated from each other by an insulating layer (not shown) provided therebetween.

The control circuit 140b further includes the comparator 152.

The comparator 152 is a circuit configured to compare two voltages and output a voltage based on a result of the comparison. Specifically, for example, the comparator 152 compares a voltage V13 of the node ND11 with a voltage V14 of the node ND12 and supplies a voltage based on a result of the comparison (for example, the voltage V13, the voltage V14, or a difference voltage between the voltage V13 and the voltage V14) as a voltage V15 to the reception circuit 151.

The control circuit 240b further includes the comparator 252.

The comparator 252 is a circuit configured to compare two voltages and output a voltage based on a result of the comparison. Specifically, for example, the comparator 252 compares a voltage V23 of the node ND21 with a voltage V24 of the node ND22 and supplies a voltage based on a result of the comparison (for example, the voltage V23, the voltage V24, or a difference voltage between the voltage V23 and the voltage V24) as a voltage V25 to the reception circuit 251.

The rest of the circuit configuration is similar to that shown in FIG. 8 described in the fourth modification of the first embodiment.

Next, the operation of the semiconductor device 1 will be described with reference to FIG. 9.

In the case where the voltage VIN is at the “H” level, as with the fourth modification of the first embodiment, the signal generating circuit 201 does not operate and the MOSFETs 260a and 260b (the switch element SW2) are turned off. Furthermore, the signal generating circuit 101 generates the signal S11 based on the voltage V11, and transmits the generated signal S11 to one end of the coil L11.

In the case where the signal S11 is input to the coil L11, a current flows through the coil L11 based on the signal S11. This generates a magnetic field in the coil L11. This magnetic field causes a change in voltage of the nodes ND11 and ND12. The voltage V13 of the node ND11 and the voltage V14 of the node ND12 are supplied to the comparator 152.

In the case where the voltages V13 and V14 are supplied to the comparator 152, for example, the comparator 152 supplies a difference voltage between the voltages V13 and V14 as the voltage V15 to the reception circuit 151. After the voltage V15 is supplied to the reception circuit 151, the reception circuit 151 and the driver circuit 150x operate in a similar manner to those of the fourth modification of the first embodiment. As a result, the MOSFETs 160a and 160b (the switch element SW1) are turned on.

On the other hand, in the case where the voltage VIN is at the “L” level, as with the fourth modification of the first embodiment, the signal generating circuit 101 does not operate and the MOSFETs 160a and 160b (the switch element SW1) are turned off. Furthermore, the signal generating circuit 201 generates the signal S21 based on the voltage V21, and transmits the generated signal S21 to one end of the coil L21.

In the case where the signal S21 is input to the coil L21, a current flows through the coil L21 based on the signal S21. This generates a magnetic field in the coil L21. This magnetic field causes a change in the voltage of the nodes ND21 and ND22. The voltage V23 of the node ND21 and the voltage V24 of the node ND22 are supplied to the comparator 252.

In the case where the voltages V23 and V24 are supplied to the comparator 252, for example, the comparator 252 supplies a difference voltage between the voltages V23 and V24 as the voltage V25 to the reception circuit 251. After the voltage V25 is supplied to the reception circuit 251, the reception circuit 251 and the driver circuit 250x operate in a similar manner to those of the fourth modification of the first embodiment. As a result, the MOSFETs 260a and 260b (the switch element SW2) are turned on.

As described above, the semiconductor device 1 configured as described above controls the switch elements SW1 and SW2 based on a signal by utilizing magnetic coupling between the coil L11 and the magnetic resistance elements R11 to R14 and magnetic coupling between the coil L21 and the magnetic resistance elements R21 to R24.

The present modification also produces advantageous effects similar to those of the first embodiment.

### (Sixth Modification)

A semiconductor device according to a sixth modification of the first embodiment will be described. The semiconductor device 1 according to the sixth modification of the first embodiment differs from that of the fourth modification of the first embodiment in that it controls the switch elements SW1 and SW2 based on a signal utilizing capacitance coupling (electric field coupling). In the following description, the description of the similar configurations to those of the fourth modification of the first embodiment will be omitted, and the configurations different from those of the fourth modification of the first embodiment will be mainly described.

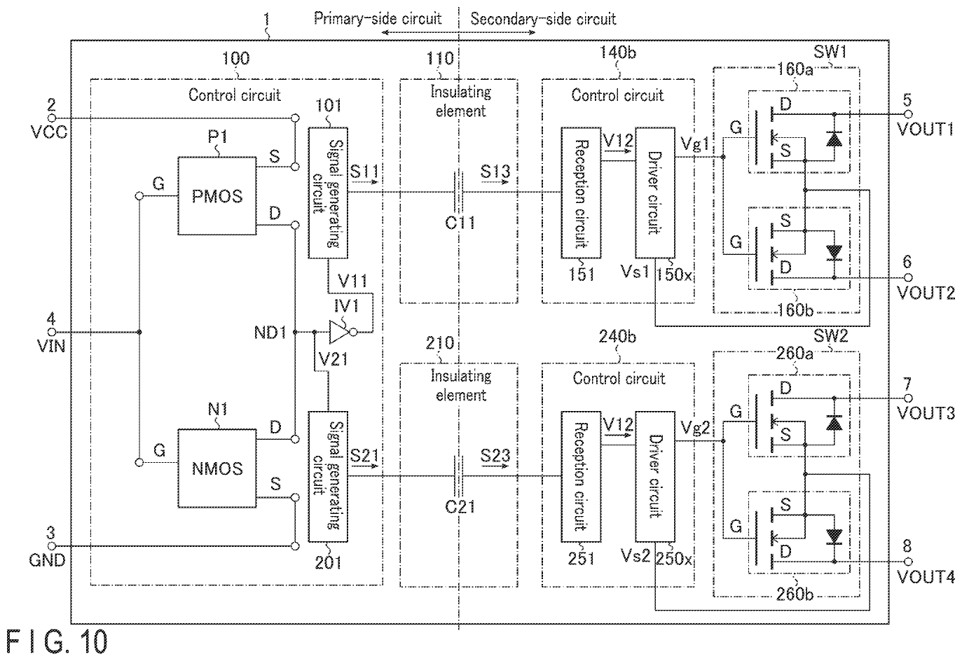

The configuration of the semiconductor device 1 will be described with reference to FIG. 10. FIG. 10 is a circuit diagram showing an example of the configuration of the semiconductor device 1.

As shown in FIG. 10, the insulating element 110 has a configuration in which the coils L11 and L12 in the fourth modification of the first embodiment are replaced with a capacitance element C11. Specifically, for example, one electrode of the capacitance element C11 is coupled to the signal generating circuit 101. The other electrode of the capacitance element C11 is coupled to the control circuit 140b (the reception circuit 151). One electrode of the capacitance element C11 and the other electrode of the capacitance element C11 are electrically insulated from each other by an insulating layer (not shown) provided therebetween.

The insulating element 210 has a configuration in which the coils L21 and L22 in the fourth modification of the first embodiment are replaced with a capacitance element C21. Specifically, for example, one electrode of the capacitance element C21 is coupled to the signal generating circuit 201. The other electrode of the capacitance element C21 is coupled to the control circuit 240b (the reception circuit 251). One electrode of the capacitance element C21 and the other electrode of the capacitance element C21 are electrically insulated from each other by an insulating layer (not shown) provided therebetween.

The rest of the circuit configuration is similar to that shown in FIG. 8 described in the fourth modification of the first embodiment.

Next, the operation of the semiconductor device 1 will be described with reference to FIG. 10.

In the case where the voltage VIN is at the “H” level, as with the fourth modification of the first embodiment, the signal generating circuit 201 does not operate and the MOSFETs 260a and 260b (the switch element SW2) are turned off. Furthermore, the signal generating circuit 101 generates the signal S11 based on the voltage V11, and transmits the generated signal S11 to one electrode of the capacitance element C11.

In the case where the signal S11 is input to one electrode of the capacitance element C11, capacitance coupling is formed between one electrode and the other electrode of the capacitance element C11. By this, the signal S13 is transmitted from the other electrode of the capacitance element C11 to the reception circuit 151. After the reception circuit 151 receives the signal S13, the reception circuit 151 and the driver circuit 150x operate in a similar manner to those of the fourth modification of the first embodiment. As a result, the MOSFETs 160a and 160b (the switch element SW1) are turned on.

On the other hand, in the case where the voltage VIN is at the “L” level, as with the fourth modification of the first embodiment, the signal generating circuit 101 does not operate and the MOSFETs 160a and 160b (the switch element SW1) are turned off. Furthermore, the signal generating circuit 201 generates the signal S21 based on the voltage V21, and transmits the generated signal S21 to one electrode of the capacitance element C21.

In the case where the signal S21 is input to one electrode of the capacitance element C21, capacitance coupling is formed between one electrode and the other electrode of the capacitance element C21. By this, the signal S23 is transmitted from the other electrode of the capacitance element C21 to the reception circuit 251.

After the reception circuit 251 receives the signal S23, the reception circuit 251 and the driver circuit 250x operate in a similar manner to those of the fourth modification of the first embodiment. As a result, the MOSFETs 260a and 260b (the switch element SW2) are turned on.

As described above, the semiconductor device 1 configured as described above controls the switch elements SW1 and SW2 based on a signal by utilizing capacitance coupling of the capacitance element C11 and capacitance coupling of the capacitance element C21.

The present modification also produces advantageous effects similar to those of the first embodiment.

### (Seventh Modification)

A semiconductor device according to a seventh modification of the first embodiment will be described. The semiconductor device 1 according to the seventh modification of the first embodiment differs from that of the fifth modification of the first embodiment in that it controls the switch elements SW1 and SW2 based on a signal utilizing magnetic resonance coupling. In the following description, the description of the similar configurations to those of the fifth modification of the first embodiment will be omitted, and the configurations different from those of the fifth modification of the first embodiment will be mainly described.

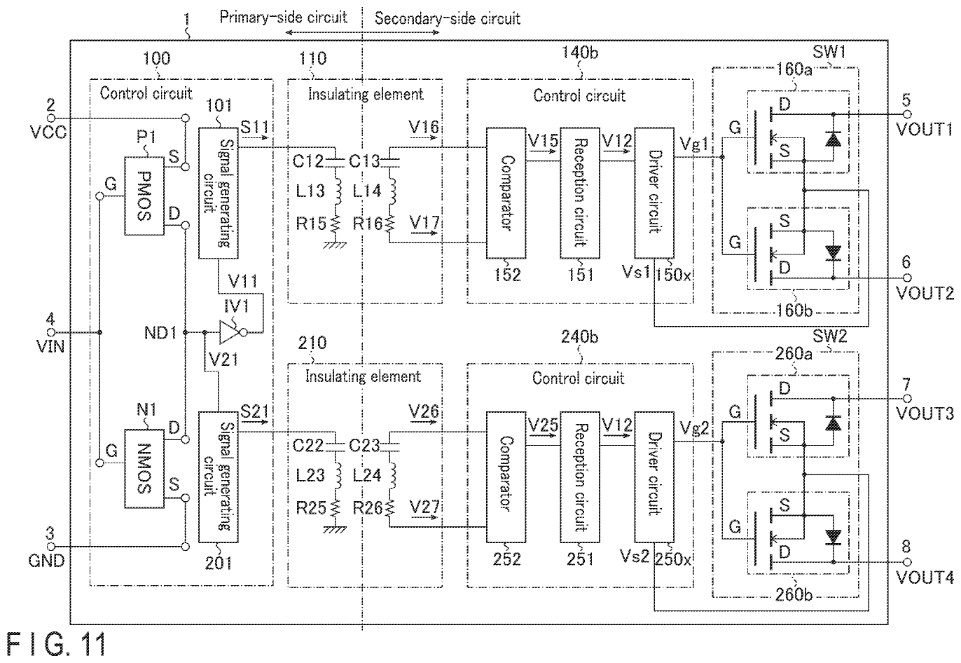

The configuration of the semiconductor device 1 will be described with reference to FIG. 11. FIG. 11 is a circuit diagram showing an example of the configuration of the semiconductor device 1.

As shown in FIG. 11, the insulating element 110 has a configuration in which the coil L11 and the magnetic resistance elements R11 to R14 in the fifth modification of the first embodiment are replaced with the capacitance elements C12 and C13, the coils L13 and L14, and the resistance elements R15 and R16. Specifically, for example, one electrode of the capacitance element C12 is coupled to the signal generating circuit 101. The other electrode of the capacitance element C12 is coupled to one end of the coil L13. The other end of the coil L13 is coupled to one end of the resistance element R15. The other end of the resistance element R15 is grounded. One electrode of the capacitance element C13 is coupled to the control circuit 140b (the comparator 152). The other electrode of the capacitance element C13 is coupled to one end of the coil L14. The other end of the coil L14 is coupled to one end of the resistance element R16. The other end of the resistance element R16 is coupled to the control circuit 140b (the comparator 152). That is, the capacitance element C12, the coil L13, and the resistance element R15 form a resonance circuit. The capacitance element C13, the coil L14, and the resistance element R16 form a resonance circuit. One resonance circuit and the other resonance circuit are electrically insulated from each other by an insulating layer (not shown) provided therebetween.

The insulating element 210 has a configuration in which the coil L21 and the magnetic resistance elements R21 to R24 in the fifth modification of the first embodiment are replaced with the capacitance elements C22 and C23, the coils L23 and L24, and the resistance elements R25 and R26. Specifically, for example, one electrode of the capacitance element C22 is coupled to the signal generating circuit 201. The other electrode of the capacitance element C22 is coupled to one end of the coil L23. The other end of the coil L23 is coupled to one end of the resistance element R25. The other end of the resistance element R25 is grounded. One electrode of the capacitance element C23 is coupled to the control circuit 240b (the comparator 252). The other electrode of the capacitance element C23 is coupled to one end of the coil L24. The other end of the coil L24 is coupled to one end of the resistance element R26. The other end of the resistance element R26 is coupled to the control circuit 240b (the comparator 252). That is, the capacitance element C22, the coil L23, and the resistance element R25 form a resonance circuit. The capacitance element C23, the coil L24, and the resistance element R26 form a resonance circuit. One resonance circuit and the other resonance circuit are electrically insulated from each other by an insulating layer (not shown) provided therebetween.

The rest of the circuit configuration is similar to that shown in FIG. 9 described in the fifth modification of the first embodiment.

Next, the operation of the semiconductor device 1 will be described with reference to FIG. 11.

In the case where the voltage VIN is at the “H” level, as with the fifth modification of the first embodiment, the signal generating circuit 201 does not operate and the MOSFETs 260a and 260b (the switch element SW2) are turned off. Furthermore, the signal generating circuit 101 generates the signal S11 based on the voltage V11, and transmits the generated signal S11 to one electrode of the capacitance element C12.

In the case where the signal S11 is input to one electrode of the capacitance element C12, magnetic resonance coupling is formed between the resonance circuit including the capacitance element C12, the coil L13, and the resistance element R15, and the resonance circuit including the capacitance element C13, the coil L14, and the resistance element R16. By this, a voltage V16 is supplied from one end of the resonance circuit including the capacitance element C13, the coil L14, and the resistance element R16 to the comparator 152. A voltage V17 is supplied from the other end of the resonance circuit including the capacitance element C13, the coil L14, and the resistance element R16 to the comparator 152.

After the voltages V16 and V17 are supplied to the comparator 152, the comparator 152, the reception circuit 151, and the driver circuit 150x operate in a similar manner to those of the fifth modification of the first embodiment. As a result, the MOSFETs 160a and 160b (the switch element SW1) are turned on.

On the other hand, in the case where the voltage VIN is at the “L” level, as with the fifth modification of the first embodiment, the signal generating circuit 101 does not operate and the MOSFETs 160a and 160b (the switch element SW1) are turned off. Furthermore, the signal generating circuit 201 generates the signal S21 based on the voltage V21, and transmits the generated signal S21 to one electrode of the capacitance element C22.

In the case where the signal S21 is input to one electrode of the capacitance element C22, magnetic resonance coupling is formed between the resonance circuit including the capacitance element C22, the coil L23, and the resistance element R25, and the resonance circuit including the capacitance element C23, the coil L24, and the resistance element R26. By this, a voltage V26 is supplied from one end of the resonance circuit including the capacitance element C23, the coil L24, and the resistance element R26 to the comparator 252. A voltage V27 is supplied from the other end of the resonance circuit including the capacitance element C23, the coil L24, and the resistance element R26 to the comparator 252.

After the voltages V26 and V27 are supplied to the comparator 252, the comparator 252, the reception circuit 251, and the driver circuit 250x operate in a similar manner to those of the fifth modification of the first embodiment. As a result, the MOSFETs 260a and 260b (the switch element SW2) are turned on.

As described above, the semiconductor device 1 configured as described above controls the switch elements SW1 and SW2 based on a signal by utilizing magnetic resonance coupling between the resonance circuit including the capacitance element C12, the coil L13, and the resistance element R15 and the resonance circuit including the capacitance element C13, the coil L14, and the resistance element R16, and magnetic resonance coupling between the resonance circuit including the capacitance element C22, the coil L23, and the resistance element R25 and the resonance circuit including the capacitance element C23, the coil L24, and the resistance element R26.

The present modification also produces advantageous effects similar to those of the first embodiment.

### (Eighth Modification)

A semiconductor device according to an eighth modification of the first embodiment will be described. The semiconductor device 1 according to the eighth modification of the first embodiment differs from that of the fourth modification of the first embodiment in that it controls the switch elements SW1 and SW2 based on a signal utilizing sonic wave coupling (oscillation). In the following description, the description of the similar configurations to those of the fourth modification of the first embodiment will be omitted, and the configurations different from those of the fourth modification of the first embodiment will be mainly described.

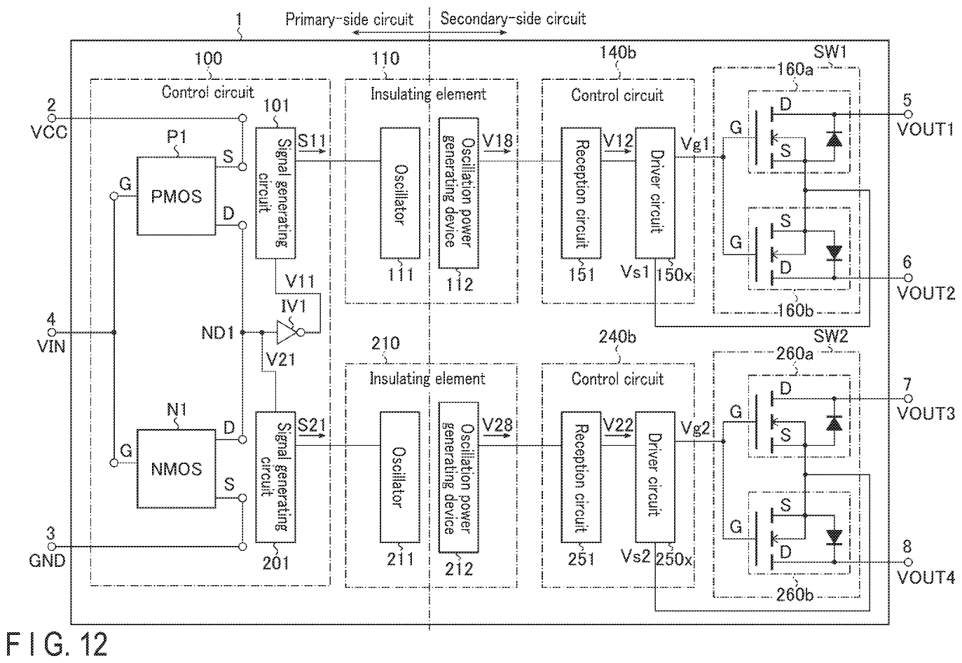

The configuration of the semiconductor device 1 will be described with reference to FIG. 12. FIG. 12 is a circuit diagram showing an example of the configuration of the semiconductor device 1.

As shown in FIG. 12, the insulating element 110 has a configuration in which the coils L11 and L12 in the fourth modification of the first embodiment are replaced with an oscillator 111 and an oscillation power generating device 112. Specifically, for example, the oscillator 111 is coupled to the signal generating circuit 101. The oscillation power generating device 112 is coupled to the control circuit 140b (the reception circuit 151). The oscillator 111 and the oscillation power generating device 121 are electrically insulated from each other by an insulating layer (not shown) provided therebetween.

The insulating element 210 has a configuration in which the coils L21 and L22 in the fourth modification of the first embodiment are replaced with an oscillator 211 and an oscillation power generating device 212. Specifically, for example, the oscillator 211 is coupled to the signal generating circuit 201. The oscillation power generating device 212 is coupled to the control circuit 240b (the reception circuit 251). The oscillator 211 and the oscillation power generating device 212 are electrically insulated from each other by an insulating layer (not shown) provided therebetween.

The oscillators 111 and 211 are each, for example, a circuit configured to generate an oscillation. The oscillators 111 and 211 are each, for example, a micro electro mechanical systems (MEMS) oscillator.

The oscillation power generating devices 112 and 212 are each, for example, a device configured to convert an oscillation into a voltage.

The rest of the circuit configuration is similar to that shown in FIG. 8 described in the fourth modification of the first embodiment.

Next, the operation of the semiconductor device 1 will be described with reference to FIG. 12.

In the case where the voltage VIN is at the “H” level, as with the fourth modification of the first embodiment, the signal generating circuit 201 does not operate and the MOSFETs 260a and 260b (the switch element SW2) are turned off. Furthermore, the signal generating circuit 101 generates the signal S11 based on the voltage V11, and transmits the generated signal S11 to the oscillator 111.

In the case where the signal S11 is input to the oscillator 111, the oscillator 111 generates an oscillation. The oscillation power generating device 112 detects the generated oscillation and converts the detected oscillation into a voltage. The oscillation power generating device 112 supplies the converted voltage as a voltage V18 to the reception circuit 151.

After the voltage V18 is supplied to the reception circuit 151, the reception circuit 151 and the driver circuit 150x operate in a similar manner to those of the fourth modification of the first embodiment. As a result, the MOSFETs 160a and 160b (the switch element SW1) are turned on.

On the other hand, in the case where the voltage VIN is at the “L” level, as with the fourth modification of the first embodiment, the signal generating circuit 101 does not operate and the MOSFETs 160a and 160b (the switch element SW1) are turned off. Furthermore, the signal generating circuit 201 generates the signal S21 based on the voltage V21, and transmits the generated signal S21 to the oscillator 211.

In the case where the signal S21 is input to the oscillator 211, the oscillator 211 generates an oscillation. The oscillation power generating device 212 detects the generated oscillation and converts the detected oscillation into a voltage. The oscillation power generating device 212 supplies the converted voltage as a voltage V28 to the reception circuit 251.

After the voltage V28 is supplied to the reception circuit 251, the reception circuit 251 and the driver circuit 250x operate in a similar manner to those of the fourth modification of the first embodiment. As a result, the MOSFETs 260a and 260b (the switch element SW2) are turned on.

As described above, the semiconductor device 1 configured as described above controls the switch elements SW1 and SW2 based on a signal by utilizing sonic wave coupling (oscillation) between the oscillator 111 and the oscillation power generating device 112, and sonic wave coupling (oscillation) between the oscillator 211 and the oscillation power generating device 212.

The present modification also produces advantageous effects similar to those of the first embodiment.

### 2. Second Embodiment

A semiconductor device according to a second embodiment will be described. The semiconductor device 1 according to the second embodiment differs from that of the first embodiment in terms of configuration of the control circuit 100. Furthermore, the semiconductor device 1 according to the second embodiment differs from that of the first embodiment in terms of the primary-side circuit not having the resistance elements R1 and R2. The following will omit a description of configurations similar to those of the first embodiment and will mainly provide a description of configurations different from those of the first embodiment.

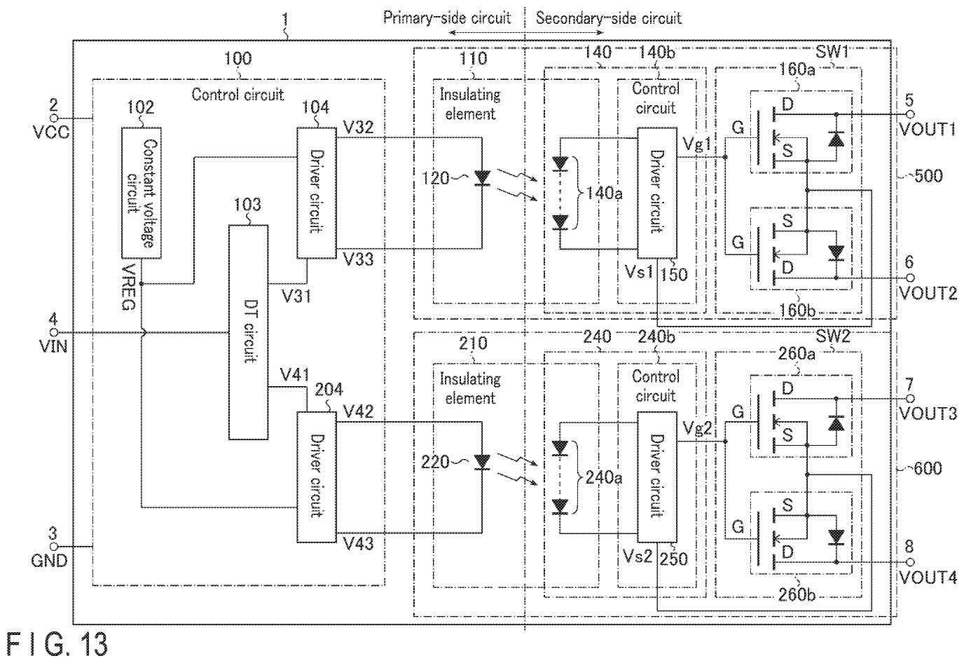

The configuration of the semiconductor device 1 will be described with reference to FIG. 13. FIG. 13 is a circuit diagram showing an example of the configuration of the semiconductor device 1.

As shown in FIG. 13, the control circuit 100 includes a constant voltage circuit 102, a dead time (DT) circuit 103, and driver circuits 104 and 204. The transistors P1 and N1 in the first embodiment are eliminated.

The constant voltage circuit 102 is, for example, a circuit configured to supply a constant voltage VREG to the DT circuit 103 and the driver circuits 104 and 204. The constant voltage circuit 102 is, for example, a linear regulator.

The DT circuit 103 is a circuit configured to exert control to prevent the pair of MOSFETs 160a and 160b (the switch element SW1) and the pair of MOSFETs 260a and 260b (the switch element SW2) from being simultaneously turned on. The DT circuit 103 generates a voltage V31 based on the voltage VIN and a voltage V41 based on the voltage VIN. The voltages V31 and V41 are, for example, at the same voltage level as the voltage VIN. The voltages V31 and V41 may be at a different voltage level from the voltage VIN. The DT circuit 103 supplies the generated voltage V31 to the driver circuit 104. The DT circuit 103 supplies the generated voltage V41 to the driver circuit 204. At the time of supplying a voltage to each of the driver circuits 104 and 204, the DT circuit 103 supplies the generated voltages V31 and V41 at different timings. In other words, the DT circuit 103 causes one of the insulating elements 110 and 210 to operate at a different timing from that of the other one based on the voltage VIN. The DT circuit 103 includes, for example, a delay circuit. The delay circuit includes, for example, an inverter circuit.

For example, when the voltage VIN rises (when the voltage VIN transitions from the “L” level to the “H” level), the DT circuit 103 supplies the voltage V31 at the “H” level to the driver circuit 104 at a timing delayed from that of the voltage VIN by time DTon. The DT circuit 103 supplies the voltage V41 at the “H” level to the driver circuit 204 without delay. The DT circuit 103 performs a similar operation during a period in which the voltage VIN is at the “H” level. On the other hand, when the voltage VIN falls (when the voltage VIN transitions from the “H” level to the “L” level), the DT circuit 103 supplies the voltage V31 at the “L” level to the driver circuit 104 without delay. The DT circuit 103 supplies the voltage V41 at the L″ level to the driver circuit 204 at a timing delayed from that of the voltage VIN by time DToff. The DT circuit 103 performs a similar operation during a period in which the voltage VIN is at the “L” level.

The time DTon corresponds to a dead time during rising of the MOSFETs 160a and 160b (falling of the MOSFETs 260a and 260b). The time DToff corresponds to a dead time during falling of the MOSFETs 160a and 160b (rising of the MOSFETs 260a and 260b). The times DTon and DToff are set in order to avoid overlap between a timing when the MOSFETs 160a and 160b rise or fall and a timing when the MOSFETs 260a and 260b fall or rise, that is, to prevent the pair of MOSFETs 160a and 160b and the pair of MOSFETs 260a and 260b from being simultaneously turned on. The time DTon is set to be longer than the time during which the MOSFETs 160a and 160b rise (the time during which the MOSFETs 260a and 260b fall). The time DToff is set to be longer than the time during which the MOSFETs 160a and 160b fall (the time during which the MOSFETs 260a and 260b rise). The times DTon and DToff may be set to any number in accordance with the characteristic values of the MOSFETs 160a, 160b, 260a, and 260b. The times DTon and DToff are, for example, 1 ms, 2 ms, etc.

The driver circuit 104 is a circuit configured to drive the insulating element 110 (the light emitting element 120) based on the voltage V31 supplied from the DT circuit 103. For example, the driver circuit 104 applies the voltage VCC as a voltage V32 to the anode of the light emitting element 120. The driver circuit 104 applies a voltage V33 based on the voltage V31 to the cathode of the light emitting element 120.

For example, when the voltage VIN rises, the driver circuit 104 applies the voltage V33 at the “L” level based on the voltage V31 at the “H” level to the cathode of the light emitting element 120. At this time, the light emitting element 120 transitions to the emission state. The driver circuit 104 performs a similar operation during a period in which the voltage VIN is at the “H” level. On the other hand, when the voltage VIN falls, the driver circuit 104 applies the voltage V33 at the “H” level based on the voltage V31 at the “L” level to the cathode of the light emitting element 120. At this time, the light emitting element 120 transitions to the non-emission state. The driver circuit 104 performs a similar operation during a period in which the voltage VIN is at the “L” level. That is, the driver circuit 104 applies the voltage V33 at a different voltage level from that of the voltage V31 to the cathode of the light emitting element 120.

The driver circuit 204 is a circuit configured to drive the insulating element 210 (the light emitting element 220) based on the voltage V41 supplied from the DT circuit 103. For example, the driver circuit 204 applies the voltage VCC as a voltage V42 to the anode of the light emitting element 220. The driver circuit 204 applies a voltage V43 based on the voltage V41 to the cathode of the light emitting element 220.

For example, when the voltage VIN rises, the driver circuit 204 applies the voltage V43 at the “H” level based on the voltage V41 at the “H” level to the cathode of the light emitting element 220. At this time, the light emitting element 220 transitions to the non-emission state. The driver circuit 204 performs a similar operation during a period in which the voltage VIN is at the “H” level. On the other hand, when the voltage VIN falls, the driver circuit 204 applies the voltage V43 at the “L” level based on the voltage V41 at the “L” level to the cathode of the light emitting element 220. At this time, the light emitting element 220 transitions to the emission state. The driver circuit 204 performs a similar operation during a period in which the voltage VIN is at the “L” level. That is, the driver circuit 204 applies the voltage V43 at the same voltage level as that of the voltage V41 to the cathode of the light emitting element 220. In other words, the driver circuit 204 has a different configuration from that of the driver circuit 104.

The rest of the circuit configuration is similar to that shown in FIG. 1 described in the first embodiment.

The structure of the semiconductor device 1 is similar to that shown in FIG. 2 and FIG. 3 described in the first embodiment.

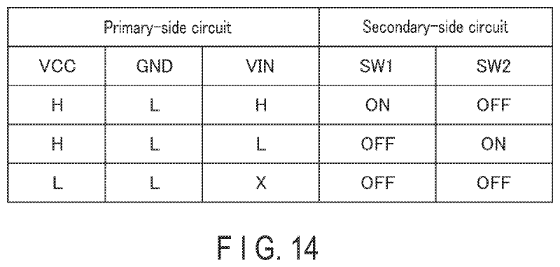

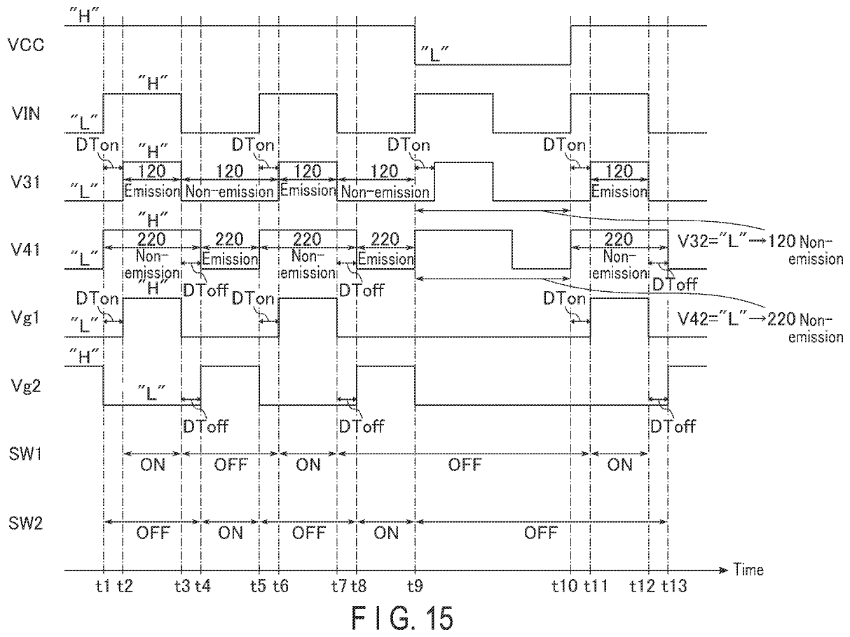

Next, the operation of the semiconductor device 1 will be described with reference to FIG. 14 and FIG. 15.

FIG. 14 is a truth table showing an example of the operation of the semiconductor device 1. The example in FIG. 14 shows a relationship between each of the voltages VCC, GND, and VIN in the primary-side circuit and the operations of the switch elements SW1 and SW2 in the secondary-side circuit. FIG. 15 is a timing chart showing an example of the operation of the semiconductor device 1. The example in FIG. 15 shows each of the voltages VCC, VIN, V31, V41, Vg1, and Vg2, and each state of the switch elements SW1 and SW2 at each time. The following will describe the case in which the voltage VCC is at the “H” level from time t1 to time t9, transitions to the “L” level at the time t9, transitions to the “H” level at time t10, and is thereafter at the “H” level from the time t10 to time t13. During a period before the time t1, the switch element SW1 is turned off and the switch element SW2 is turned on.

First, the case in which the voltage VCC is at the “H” level, the voltage GND is at the “L” level, and the voltage VIN is at the “H” level, as shown in the first line of the truth table in FIG. 14, will be described.

At the time t1, in the case where the voltage VIN transitions from the “L” level to the “H” level, the DT circuit 103 supplies the voltage V41 at the “H” level to the driver circuit 204 without delay (at the time t1). The DT circuit 103 supplies the voltage V31 at the “H” level to the driver circuit 104 with delay (at the time t2 which is later by the time Dion than the time t1). That is, the voltage V41 is set to the “H” level at the time t1 through those operations of the DT circuit 103. The voltage V31 is set to the “H” level at the time t2. At the time t1, the driver circuit 204 applies the voltage V43 at the “H” level based on the voltage V41 at the “H” level to the cathode of the light emitting element 220. The light emitting element 220 transitions to the non-emission state at the time t1 because the voltage VCC has been applied as the voltage V42 to the anode of the light emitting element 220. At the time t2, the driver circuit 104 applies the voltage V33 at the “L” level based on the voltage V31 at the “H” level to the cathode of the light emitting element 120. The light emitting element 120 transitions to the emission state at the time t2 because the voltage VCC has been applied as the voltage V32 to the anode of the light emitting element 120.

In the case where the light emitting element 220 transitions to the non-emission state, the light receiving element 240a and the control circuit 240b (the driver circuit 250) operate in a similar manner to that of the first embodiment, and the voltage Vg2 is set to the “L” level at the time t1. By this, the MOSFETs 260a and 260b (the switch element SW2) are turned off, and the input/output terminals 7 and 8 are not electrically coupled together. Furthermore, in the case where the light emitting element 120 transitions to the emission state, the light receiving element 140a and the control circuit 140b (the driver circuit 150) operate in a similar manner to that of the first embodiment, and the voltage Vg1 is set to the “H” level at the time t2. By this, the MOSFETs 160a and 160b (the switch element SW1) are turned on, and the input/output terminals 5 and 6 are electrically coupled together.

The voltage V31 maintains the “H” level from the time t2 to the time t3. By this, the light emitting element 120 maintains the emission state from the time t2 to the time t3. The voltage V41 maintains the “H” level from the time t1 to time t4. By this, the light emitting element 220 maintains the non-emission state from the time t1 to the time t4.

The voltage Vg1 maintains the “H” level from the time t2 to the time t3. By this, the switch element SW1 maintains the ON state from the time t2 to the time t3. The voltage Vg2 maintains the “L” level from the time t1 to the time t4. By this, the switch element SW2 maintains the OFF state from the time t1 to the time t4.

Next, the case in which the voltage VCC is at the “H” level, the voltage GND is at the “L” level, and the voltage VIN is at the “L” level, as shown in the second line of the truth table in FIG. 14, will be described.

At the time t3, in the case where the voltage VIN transitions from the “H” level to the “L” level, the DT circuit 103 supplies the voltage V31 at the “L” level to the driver circuit 104 without delay (at the time t3). The DT circuit 103 supplies the voltage V41 at the “L” level to the driver circuit 204 with delay (at the time t4 which is later by the time DToff than the time t3). That is, the voltage V31 is set to the “L” level at the time t3 through those operations of the DT circuit 103. The voltage V41 is set to the “L” level at the time t4. At the time t3, the driver circuit 104 applies the voltage V33 at the “H” level based on the voltage V31 at the “L” level to the cathode of the light emitting element 120. The light emitting element 120 transitions to the non-emission state at the time t3 because the voltage VCC has been applied as the voltage V32 to the anode of the light emitting element 120. At the time t4, the driver circuit 204 applies the voltage V43 at the “L” level based on the voltage V41 at the “L” level to the cathode of the light emitting element 220. The light emitting element 220 transitions to the emission state at the time t4 because the voltage VCC has been applied as the voltage V42 to the anode of the light emitting element 220.

In the case where the light emitting element 120 transitions to the non-emission state, the light receiving element 140a and the control circuit 140b (the driver circuit 150) operate in a similar manner to that of the first embodiment, and the voltage Vg1 is set to the “L” level at the time t3. By this, the MOSFETs 160a and 160b (the switch element SW1) are turned off, and the input/output terminals 5 and 6 are not electrically coupled together. Furthermore, in the case where the light emitting element 220 transitions to the emission state, the light receiving element 240a and the control circuit 240b (the driver circuit 250) operate in a similar manner to that of the first embodiment, and the voltage Vg2 is set to the “H” level at the time t4. By this, the MOSFETs 260a and 260b (the switch element SW2) are turned on, and the input/output terminals 7 and 8 are electrically coupled together.

The voltage V31 maintains the “L” level from the time t3 to time t6. By this, the light emitting element 120 maintains the non-emission state from the time t3 to the time t6. The voltage V41 maintains the “L” level from the time t4 to time t5. By this, the light emitting element 220 maintains the emission state from the time t4 to the time t5.

The voltage Vg1 maintains the “L” level from the time t3 to the time t6. By this, the switch element SW1 maintains the OFF state from the time t3 to the time t6. The voltage Vg2 maintains the “H” level from the time t4 to the time t5. By this, the switch element SW2 maintains the ON state from the time t4 to the time t5.

The operation from the time t5 to time t9 is the same as the operation from the time t1 to the time t5.

Next, the case in which the voltage VCC is at the “L” level, the voltage GND is at the “L” level, and the voltage VIN is at an “X” level (the “H” level or the “L” level), as shown in the third line of the truth table in FIG. 14, that is, the case in which the voltage VCC is not supplied, will be described.

At time t9, in the case where the voltage VCC transitions to the “L” level, the DT circuit 103 operates in a similar manner to the operation at the time t1. The driver circuit 104 applies the voltage V32 at the “L” level to the anode of the light emitting element 120 at the time t9. By this, the light emitting element 120 transitions to the non-emission state. At the time t9, the driver circuit 204 applies the voltage V42 at the “L” level to the anode of the light emitting element 220. By this, the light emitting element 220 transitions to the non-emission state.

In the case where the light emitting element 120 transitions to the non-emission state, the light receiving element 140a and the control circuit 140b (the driver circuit 150) operate in a similar manner to that of the first embodiment, and the voltage Vg1 is set to the “L” level at the time t9. By this, the MOSFETs 160a and 160b (the switch element SW1) are turned off. Furthermore, in the case where the light emitting element 220 transitions to the non-emission state, the light receiving element 240a and the control circuit 240b (the driver circuit 250) operate in a similar manner to that of the first embodiment, and the voltage Vg2 is set to the “L” level at the time t9. By this, the MOSFETs 260a and 260b (the switch element SW2) are turned off.

The voltage level of the voltage V31 from the time t9 to time t10 is set to be similar to the voltage level from the time t1 to the time t5. At the time t9, in the case where the voltage V32 at the “L” level is applied to the anode of the light emitting element 120, the light emitting element 120 maintains the non-emission state from the time t9 to the time t10. The voltage level of the voltage V41 from the time t9 to the time t10 is set to be similar to the voltage level from the time t1 to the time t5. At the time t9, in the case where the voltage V42 at the “L” level is applied to the anode of the light emitting element 220, the light emitting element 220 maintains the non-emission state from the time t9 to the time t10.

The voltage Vg1 maintains the “L” level from the time t9 to time t10. By this, the switch element SW1 maintains the OFF state from the time t9 to the time t10. The voltage Vg2 maintains the “L” level from the time t9 to the time t10. By this, the switch element SW2 maintains the OFF state from the time t9 to the time t10.

The operation from the time t10 to time t13 is the same as the operation from the time t1 to the time t4.

The present embodiment also produces advantageous effects similar to those of the first embodiment.

According to the present embodiment, the control circuit 100 includes the DT circuit 103. The DT circuit 103 causes one of the insulating elements 110 and 210 to operate at a different timing from that of the other one based on the control signal VIN.

Specifically, the DT circuit 103 supplies the voltage V31 to the driver circuit 104 at the first time (for example, the time t2 in FIG. 15) based on the control signal VIN, and supplies the voltage V41 to the driver circuit 204 at the second time (for example, the time t1 in FIG. 15) based on the control signal VIN. The driver circuit 104 drives the insulating element 110 based on the voltage V31. The driver circuit 204 drives the insulating element 210 based on the voltage V41.

Thus, the present embodiment can prevent a timing when the light emitting element 120 transitions to the emission state and a timing when the light emitting element 220 transitions to the non-emission state from becoming simultaneous. This can prevent a timing when the switch element SW1 transitions to the ON state and a timing when the switch element SW2 transitions to the OFF state from becoming simultaneous. Furthermore, the present embodiment can prevent a timing when the light emitting element 120 transitions to the non-emission state and a timing when the light emitting element 220 transitions to the emission state from becoming simultaneous. This can prevent a timing when the switch element SW1 transitions to the OFF state and a timing when the switch element SW2 transitions to the ON state from becoming simultaneous.

The structures of the first to third modifications of the first embodiment are applicable to the semiconductor device 1 according to the present embodiment.

### (First Modification)

A semiconductor device according to a first modification of the second embodiment will be described. The semiconductor device 1 according to the first modification of the second embodiment differs from that of the second embodiment in that it controls the switch elements SW1 and SW2 based on a signal utilizing magnetic coupling (magnetic field coupling). The following will omit a description of a configuration similar to that of the second embodiment and will mainly provide a description of a configuration different from that of the second embodiment.

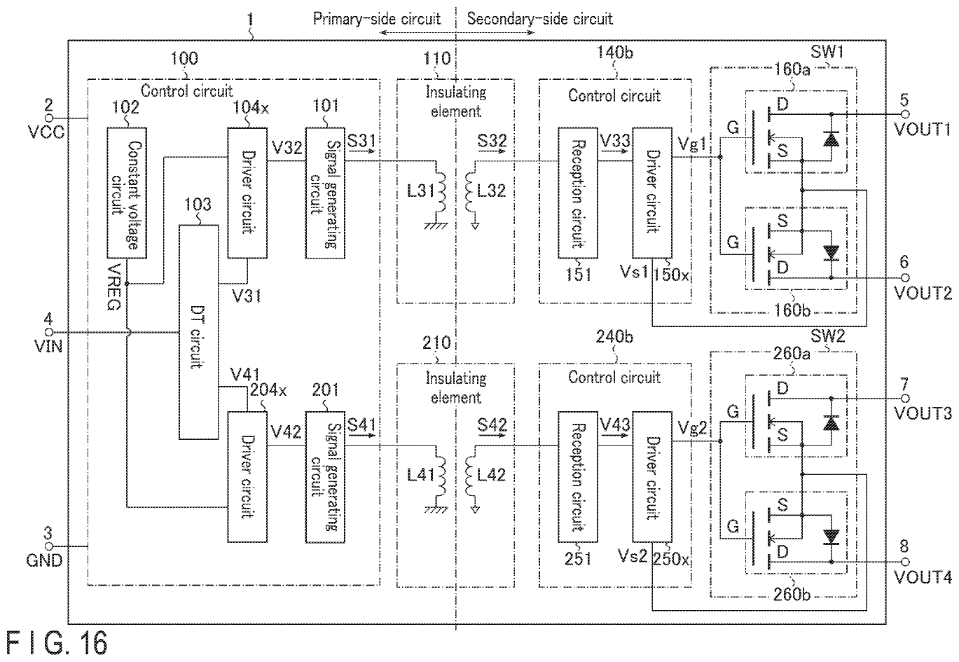

The configuration of the semiconductor device 1 will be described with reference to FIG. 16. FIG. 16 is a circuit diagram showing an example of the configuration of the semiconductor device 1.

As shown in FIG. 16, the control circuit 100 further includes the signal generating circuits 101 and 201. The signal generating circuits 101 and 201 each have a configuration similar to that shown in FIG. 8 described in the fourth modification of the first embodiment. Furthermore, the control circuit 100 has a configuration in which the driver circuits 104 and 204 in the second embodiment are respectively replaced with driver circuits 104x and 204x.

The driver circuit 104x is a circuit configured to drive the insulating element 110 based on the voltage V31 supplied from the DT circuit 103. For example, the driver circuit 104x supplies the voltage V32 based on the voltage V31 (for example, a voltage at the same voltage level as that of the voltage V31) to the signal generating circuit 101.

The driver circuit 204x is a circuit configured to drive the insulating element 210 based on the voltage V41 supplied from the DT circuit 103. For example, the driver circuit 204x supplies the voltage V42 based on the voltage V41 (for example, a voltage at a different voltage level from that of the voltage V41) to the signal generating circuit 201.

The insulating element 110 has a configuration in which the light emitting element 120 and the light receiving element 140a in the second embodiment are replaced with coils L31 and L32. Specifically, for example, one end of the coil L31 is coupled to the signal generating circuit 101. The other end of the coil L31 is grounded. One end of the coil L32 is coupled to the control circuit 140b (the reception circuit 151). The other end of the coil L32 is grounded. The coil L31 and the coil L32 are electrically insulated from each other by an insulating layer (not shown) provided therebetween.

The insulating element 210 has a configuration in which the light emitting element 220 and the light receiving element 240a in the second embodiment are replaced with coils L41 and L42. Specifically, for example, one end of the coil L41 is coupled to the signal generating circuit 201. The other end of the coil L41 is grounded. One end of the coil L42 is coupled to the control circuit 240b (the reception circuit 251). The other end of the coil L42 is grounded. The coil L41 and the coil L42 are electrically insulated from each other by an insulating layer (not shown) provided therebetween.

The control circuit 140b further includes the reception circuit 151. Furthermore, the control circuit 140b has a configuration in which the driver circuit 150 in the second embodiment is replaced with the driver circuit 150x. The reception circuit 151 and the driver circuit 150x each have a configuration similar to that shown in FIG. 8 described in the fourth modification of the first embodiment.

The control circuit 240b further includes the reception circuit 251. Furthermore, the control circuit 240b has a configuration in which the driver circuit 250 in the second embodiment is replaced with a driver circuit 250x. The reception circuit 251 and the driver circuit 250x each have a configuration similar to that shown in FIG. 8 described in the fourth modification of the first embodiment.

The rest of the circuit configuration is similar to that shown in FIG. 13 described in the second embodiment.

Next, the operation of the semiconductor device 1 will be described with reference to FIG. 16.

In the case where the voltage VIN transitions from the “L” level to the “H” level, the DT circuit 103 supplies the voltage V41 at the “H” level to the driver circuit 204x without delay. The DT circuit 103 supplies the voltage V31 at the “H” level to the driver circuit 104x at a timing delayed by the time DTon.

The driver circuit 204x supplies the voltage V42 at the “L” level based on the voltage V41 at the “H” level to the signal generating circuit 201. The signal generating circuit 201 does not operate because the voltage V42 at the “L” level is supplied thereto. For this reason, the reception circuit 251 does not receive the signal S42 from the coil L42, the voltage V43 is not supplied to the driver circuit 250x, and the MOSFETs 260a and 260b (the switch element SW2) are turned off.

The driver circuit 104x supplies the voltage V32 at the “H” level based on the voltage V31 at the “H” level to the signal generating circuit 101 after a lapse of the time DTon from when driving of the driver circuit 204x is started. Since the voltage V42 at the “H” level is supplied to the signal generating circuit 101, the signal generating circuit 101 generates a signal S31 based on the voltage V32 and transmits the generated signal S31 to one end of the coil L31.

In the case where the signal S31 is input to the coil L31, a signal S32 is transmitted from the coil L32 to the reception circuit 151 by magnetic coupling between the coil L31 and the coil L32.

In the case where the reception circuit 151 receives the signal S32, the reception circuit 151 transmits the voltage V33 based on the signal S32 to the driver circuit 150x. The driver circuit 150x applies the voltage Vg1 (for example, 5 V) at the “H” level based on the voltage V33 supplied from the reception circuit 151, to the gates of the MOSFETs 160a and 160b. The driver circuit 150x applies the voltage Vs1 (for example, the voltage GND) at the “L” level based on the voltage V33 to the sources of the MOSFETs 160a and 160b. This causes the MOSFETs 160a and 160b (the switch element SW1) to transition to the ON state after a lapse of the time DTon from the transition of the MOSFETs 260a and 260b (the switch element SW2) to the OFF state.

On the other hand, in the case where the voltage VIN transitions from the “H” level to the “L” level, the DT circuit 103 supplies the voltage V31 at the “L” level to the driver circuit 104x without delay. The DT circuit 103 supplies the voltage V41 at the “L” level to the driver circuit 204x at a timing delayed by the time DToff.

The driver circuit 104x supplies the voltage V32 at the “L” level based on the voltage V31 at the “L” level to the signal generating circuit 101. The signal generating circuit 101 does not operate because the voltage V32 at the “L” level is supplied thereto. For this reason, the reception circuit 151 does not receive the signal S32 from the coil L32, the voltage V33 is not supplied to the driver circuit 150x, and the MOSFETs 160a and 160b (the switch element SW1) are turned off.

The driver circuit 204x supplies the voltage V42 at the “H” level based on the voltage V41 at the “L” level to the signal generating circuit 201 after a lapse of the time DToff from when driving of the driver circuit 104x is started. Since the voltage V42 at the “H” level is supplied to the signal generating circuit 201, the signal generating circuit 201 generates a signal S41 based on the voltage V42 and transmits the generated signal S41 to one end of the coil L41.

In the case where the signal S41 is input to the coil L41, a signal S42 is transmitted from the coil L42 to the reception circuit 251 by magnetic coupling between the coil L41 and the coil L42.

In the case where the reception circuit 251 receives the signal S42, the reception circuit 251 transmits the voltage V43 based on the signal S42 to the driver circuit 250x. The driver circuit 250x applies the voltage Vg2 (for example, 5 V) at the “H” level based on the voltage V43 supplied from the reception circuit 251, to the gates of the MOSFETs 260a and 260b. The driver circuit 250x applies the voltage Vs2 (for example, the voltage GND) at the “L” level based on the voltage V43 to the sources of the MOSFETs 260a and 260b. This causes the MOSFETs 260a and 260b (the switch element SW2) to transition to the ON state after a lapse of the time DToff from the transition of the MOSFETs 160a and 160b (the switch element SW1) to the OFF state.

The present modification also produces advantageous effects similar to those of the second embodiment.

### (Second Modification)

A semiconductor device according to a second modification of the second embodiment will be described. The semiconductor device 1 according to the second modification of the second embodiment differs from that of the first modification of the second embodiment in terms of type of magnetic coupling. In the following description, the description of the similar configurations to those of the first modification of the second embodiment will be omitted, and the configurations different from those of the first modification of the second embodiment will be mainly described.

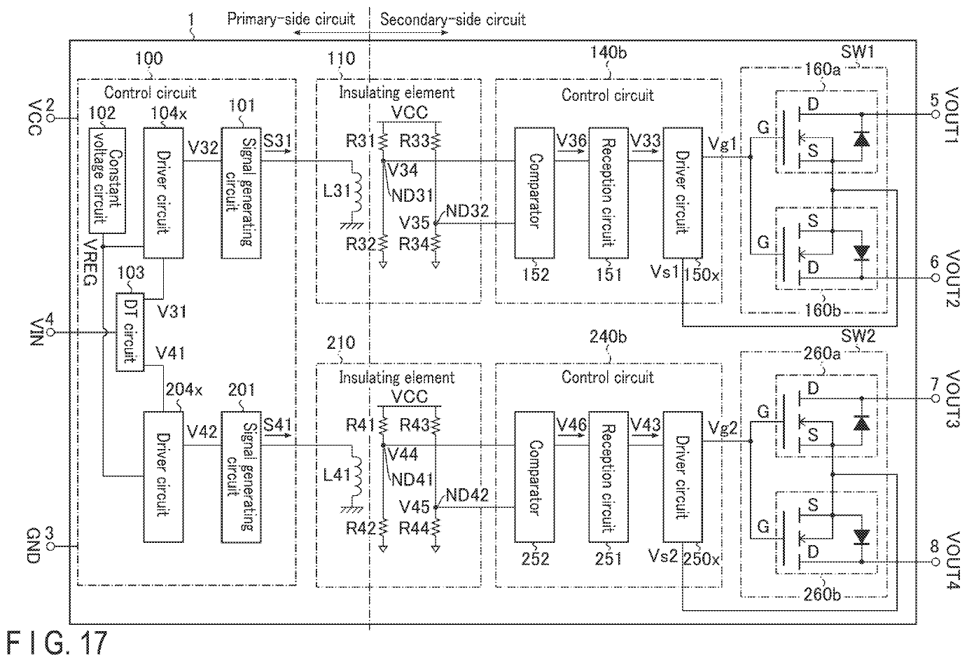

A configuration of the semiconductor device 1 will be described with reference to FIG. 17. FIG. 17 is a circuit diagram showing an example of a configuration of the semiconductor device 1.

As shown in FIG. 17, the insulating element 110 has a configuration in which the coil L32 in the first modification of the second embodiment is replaced with magnetic resistance elements R31 to R34. Examples of the magnetic resistance elements include a hall element. Specifically, for example, the voltage VCC is applied to one end of the magnetic resistance element R31. The other end of the magnetic resistance element R31 is coupled to the node ND31. One end of the magnetic resistance element R32 is coupled to the node ND31. The other end of the magnetic resistance element R32 is grounded. The node ND31 is coupled to the control circuit 140b (a comparator 152). The voltage VCC is applied to one end of the magnetic resistance element R33. The other end of the magnetic resistance element R33 is coupled to the node ND32. One end of the magnetic resistance element R34 is coupled to the node ND32. The other end of the magnetic resistance element R34 is grounded. The node ND32 is coupled to the control circuit 140b (a comparator 152). The coil L31 and the set of magnetic resistance elements R31 to R34 are electrically insulated from each other by an insulating layer (not shown) provided therebetween.

The insulating element 210 has a configuration in which the coil L42 in the first modification of the second embodiment is replaced with magnetic resistance elements R41 to R44. Specifically, for example, the voltage VCC is applied to one end of the magnetic resistance element R41. The other end of the magnetic resistance element R41 is coupled to the node ND41. One end of the magnetic resistance element R42 is coupled to the node ND41. The other end of the magnetic resistance element R42 is grounded. The node ND41 is coupled to the control circuit 240b (the comparator 252). The voltage VCC is applied to one end of the magnetic resistance element R43. The other end of the magnetic resistance element R43 is coupled to the node ND42. One end of the magnetic resistance element R44 is coupled to the node ND42. The other end of the magnetic resistance element R44 is grounded. The node ND42 is coupled to the control circuit 240b (the comparator 252). The coil L41 and the set of magnetic resistance elements R41 to R44 are electrically insulated from each other by an insulating layer (not shown) provided therebetween.

The control circuit 140b further includes the comparator 152. The control circuit 240b further includes the comparator 252. The comparator 152 and 252 each have a configuration similar to that shown in FIG. 9 described in the fifth modification of the first embodiment.

The rest of the circuit configuration is similar to that shown in FIG. 16 described in the first modification of the second embodiment.

Next, the operation of the semiconductor device 1 will be described with reference to FIG. 17.

In the case where the voltage VIN transitions from the “L” level to the “H” level, the DT circuit 103 supplies the voltage V41 at the “H” level to the driver circuit 204x without delay. The DT circuit 103 supplies the voltage V31 at the “H” level to the driver circuit 104x at a timing delayed by the time DTon.

The driver circuit 204x supplies the voltage V42 at the “L” level based on the voltage V41 at the “H” level to the signal generating circuit 201. The signal generating circuit 201 does not operate because the voltage V42 at the “L” level is supplied thereto. That is, the MOSFETs 260a and 260b (the switch element SW2) are turned off.

The driver circuit 104x supplies the voltage V32 at the “H” level based on the voltage V31 at the “H” level to the signal generating circuit 101 after a lapse of the time DTon from when driving of the driver circuit 204x is started. Since the voltage V32 at the “H” level is supplied to the signal generating circuit 101, the signal generating circuit 101 generates the signal S31 based on the voltage V32 and transmits the generated signal S31 to one end of the coil L31.

In the case where the signal S31 is input to the coil L31, magnetic coupling between the coil L31 and the magnetic resistance elements R31 to R34 causes a change in voltage of the nodes ND31 and ND32. A voltage V34 of the node ND31 and a voltage V35 of the node ND32 are supplied to the comparator 152.

In the case where the voltages V34 and V35 are supplied to the comparator 152, for example, the comparator 152 supplies a difference voltage between the voltages V34 and V35 as a voltage V36 to the reception circuit 151. After the voltage V36 is supplied to the reception circuit 151, the reception circuit 151 and the driver circuit 150x operate in a similar manner to those of the first modification of the second embodiment. As a result, the MOSFETs 160a and 160b (the switch element SW1) transition to the ON state after a lapse of the time Dion from the transition of the MOSFETs 260a and 260b (the switch element SW2) to the OFF state.

On the other hand, in the case where the voltage VIN transitions from the “H” level to the “L” level, the DT circuit 103 supplies the voltage V31 at the “L” level to the driver circuit 104x without delay. The DT circuit 103 supplies the voltage V41 at the “L” level to the driver circuit 204x at a timing delayed by the time DToff.

The driver circuit 104x supplies the voltage V32 at the “L” level based on the voltage V31 at the “L” level to the signal generating circuit 101. The signal generating circuit 101 does not operate because the voltage V32 at the “L” level is supplied thereto. That is, the MOSFETs 160a and 160b (the switch element SW1) are turned off.

The driver circuit 204x supplies the voltage V42 at the “H” level based on the voltage V41 at the “L” level to the signal generating circuit 201 after a lapse of the time DToff from when driving of the driver circuit 104x is started. Since the voltage V42 at the “H” level is supplied to the signal generating circuit 201, the signal generating circuit 201 generates the signal S41 based on the voltage V42 and transmits the generated signal S41 to one end of the coil L41.

In the case where the signal S41 is input to the coil L41, magnetic coupling between the coil L41 and the magnetic resistance elements R41 to R44 cause a change in voltage of the nodes ND41 and ND42. A voltage V44 of the node ND41 and a voltage V45 of the node ND42 are supplied to the comparator 252.

In the case where the voltages V44 and V45 are supplied to the comparator 252, for example, the comparator 252 supplies a difference voltage between the voltages V44 and V45 as a voltage V46 to the reception circuit 251. After the voltage V46 is supplied to the reception circuit 251, the reception circuit 251 and the driver circuit 250x operate in a similar manner to those of the first modification of the second embodiment. As a result, the MOSFETs 260a and 260b (the switch element SW2) transition to the ON state after a lapse of the time DToff from the transition of the MOSFETs 160a and 160b (the switch element SW1) to the OFF state.

The present modification also produces advantageous effects similar to those of the second embodiment.

### (Third Modification)

A semiconductor device according to a third modification of the second embodiment will be described. The semiconductor device 1 according to the third modification of the second embodiment differs from that of the first modification of the second embodiment in that it controls the switch elements SW1 and SW2 based on a signal utilizing capacitance coupling (electric field coupling). In the following description, the description of the similar configurations to those of the first modification of the second embodiment will be omitted, and the configurations different from those of the first modification of the second embodiment will be mainly described.

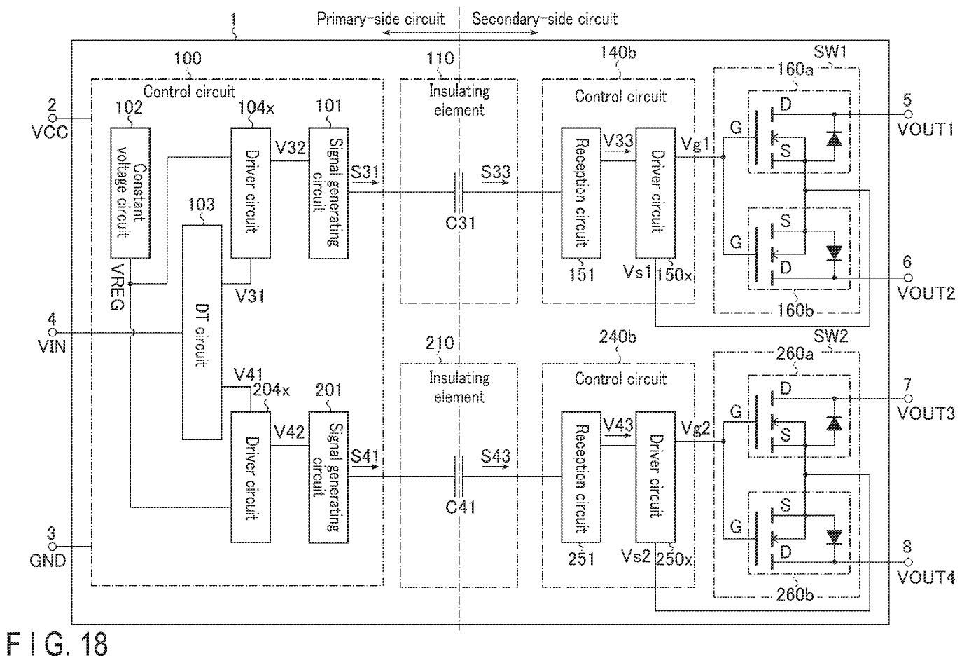

A configuration of the semiconductor device 1 will be described with reference to FIG. 18. FIG. 18 is a circuit diagram showing an example of the configuration of the semiconductor device 1.

As shown in FIG. 18, the insulating element 110 has a configuration in which the coils L31 and L32 in the first modification of the second embodiment are replaced with a capacitance element C31. Specifically, for example, one electrode of the capacitance element C31 is coupled to the signal generating circuit 101. The other electrode of the capacitance element C31 is coupled to the control circuit 140b (the reception circuit 151). One electrode of the capacitance element C31 and the other electrode of the capacitance element C31 are electrically insulated from each other by an insulating layer (not shown) provided therebetween.

The insulating element 210 has a configuration in which the coils L41 and L42 in the first modification of the second embodiment are replaced with a capacitance element C41. Specifically, for example, one electrode of the capacitance element C41 is coupled to the signal generating circuit 201. The other electrode of the capacitance element C41 is coupled to the control circuit 240b (the reception circuit 251). One electrode of the capacitance element C41 and the other electrode of the capacitance element C41 are electrically insulated from each other by an insulating layer (not shown) provided therebetween.

The rest of the circuit configurations is similar to that shown in FIG. 16 described in the first modification of the second embodiment.

Next, the operation of the semiconductor device 1 will be described with reference to FIG. 18.

In the case where the voltage VIN transitions from the “L” level to the “H” level, the DT circuit 103 supplies the voltage V41 at the “H” level to the driver circuit 204x without delay. The DT circuit 103 supplies the voltage V31 at the “H” level to the driver circuit 104x at a timing delayed by the time DTon.

The driver circuit 204x supplies the voltage V42 at the “L” level based on the voltage V41 at the “H” level to the signal generating circuit 201. The signal generating circuit 201 does not operate because the voltage V42 at the “L” level is supplied thereto. That is, the MOSFETs 260a and 260b (the switch element SW2) are turned off.

The driver circuit 104x supplies the voltage V32 at the “H” level based on the voltage V31 at the “H” level to the signal generating circuit 101 after a lapse of the time DTon from when driving of the driver circuit 204x is started. Since the voltage V32 at the “H” level is supplied to the signal generating circuit 101, the signal generating circuit 101 generates the signal S31 based on the voltage V32 and transmits the generated signal S31 to one electrode of the capacitance element C31.

In the case where the signal S31 is input to one electrode of the capacitance element C31, capacitance coupling is formed between one electrode and the other electrode of the capacitance element C31. By this, the signal S33 is transmitted from the other electrode of the capacitance element C31 to the reception circuit 151.

After the reception circuit 151 receives the signal S33, the reception circuit 151 and the driver circuit 150x operate in a similar manner to those of the first modification of the second embodiment. As a result, the MOSFETs 160a and 160b (the switch element SW1) transition to the ON state after a lapse of the time Dion from the transition of the MOSFETs 260a and 260b (the switch element SW2) to the OFF state.

On the other hand, in the case where the voltage VIN transitions from the “H” level to the “L” level, the DT circuit 103 supplies the voltage V31 at the “L” level to the driver circuit 104x without delay. The DT circuit 103 supplies the voltage V41 at the L″ level to the driver circuit 204x at a timing delayed by the time DToff.

The driver circuit 104x supplies the voltage V32 at the “L” level based on the voltage V31 at the “L” level to the signal generating circuit 101. The signal generating circuit 101 does not operate because the voltage V32 at the “L” level is supplied thereto. That is, the MOSFETs 160a and 160b (the switch element SW1) are turned off.

The driver circuit 204x supplies the voltage V42 at the “H” level based on the voltage V41 at the “L” level to the signal generating circuit 201 after a lapse of the time DToff from when driving of the driver circuit 104x is started. Since the voltage V42 at the “H” level is supplied to the signal generating circuit 201, the signal generating circuit 201 generates the signal S41 based on the voltage V42 and transmits the generated signal S41 to one electrode of the capacitance element C41.

In the case where the signal S41 is input to one electrode of the capacitance element C41, capacitance coupling is formed between one electrode and the other electrode of the capacitance element C41. By this, the signal S43 is transmitted from the other electrode of the capacitance element C41 to the reception circuit 251.

After the reception circuit 251 receives the signal S43, the reception circuit 251 and the driver circuit 250x operate in a similar manner to those of the first modification of the second embodiment. As a result, the MOSFETs 260a and 260b (the switch element SW2) transition to the ON state after a lapse of the time DToff from the transition of the MOSFETs 160a and 160b (the switch element SW1) to the OFF state.

The present modification also produces advantageous effects similar to those of the second embodiment.

### (Fourth Modification)

A semiconductor device according to a fourth modification of the second embodiment will be described. The semiconductor device 1 according to the fourth modification of the second embodiment differs from that of the second modification of the second embodiment in that it controls the switch elements SW1 and SW2 based on a signal utilizing magnetic resonance coupling. In the following description, the description of the similar configurations to those of the second modification of the second embodiment will be omitted, and the configurations different from those of the second modification of the second embodiment will be mainly described.

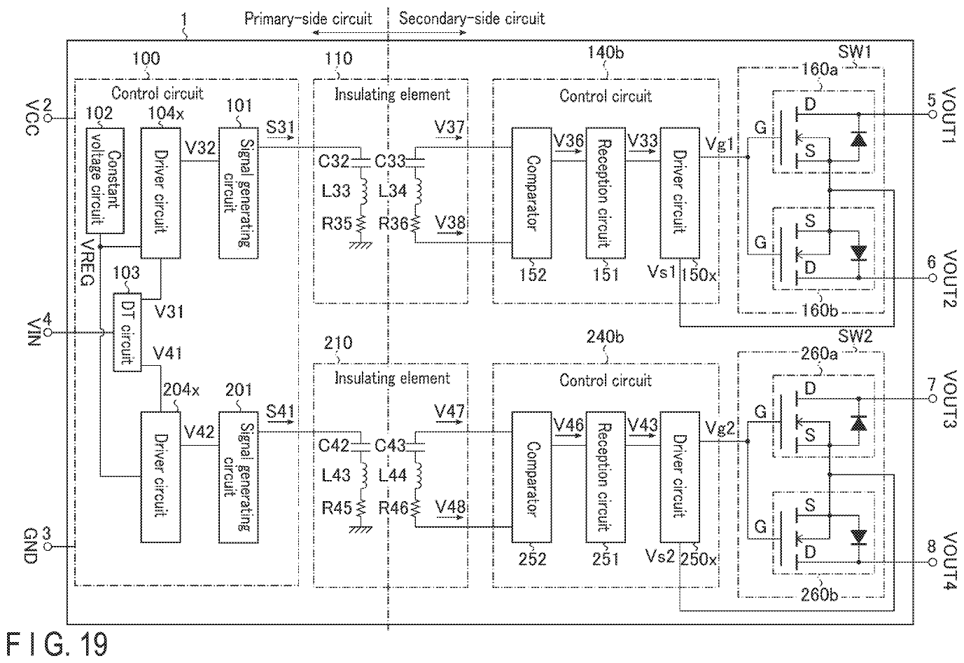

A configuration of the semiconductor device 1 will be described with reference to FIG. 19. FIG. 19 is a circuit diagram showing an example of the configuration of the semiconductor device 1.

As shown in FIG. 19, the insulating element 110 has a configuration in which the coil L31 and the magnetic resistance elements R31 to R34 in the second modification of the second embodiment are replaced with the capacitance elements C32 and C33, the coils L33 and L34, and the resistance elements R35 and R36. Specifically, for example, one electrode of the capacitance element C32 is coupled to the signal generating circuit 101. The other electrode of the capacitance element C32 is coupled to one end of the coil L33. The other end of the coil L33 is coupled to one end of the resistance element R35. The other end of the resistance element R35 is grounded. One electrode of the capacitance element C33 is coupled to the control circuit 140b (the comparator 152). The other electrode of the capacitance element C33 is coupled to one end of the coil L34. The other end of the coil L34 is coupled to one end of the resistance element R36. The other end the resistance element R36 is coupled to the control circuit 140b (the comparator 152). That is, the capacitance element C32, the coil L33, and the resistance element R35 form a resonance circuit. The capacitance element C33, the coil L34, and the resistance element R36 form a resonance circuit. One resonance circuit and the other resonance circuit are electrically insulated from each other by an insulating layer (not shown) provided therebetween.

The insulating element 210 has a configuration in which the coil L41 and the magnetic resistance elements R41 to R44 in the second modification of the second embodiment are replaced with capacitance elements C42 and C43, coils L43 and L44, and resistance elements R45 and R46. Specifically, for example, one electrode of the capacitance element C42 is coupled to the signal generating circuit 201. The other electrode of the capacitance element C42 is coupled to one end of the coil L43. The other end of the coil L43 is coupled to one end of the resistance element R45. The other end of the resistance element R45 is grounded. One electrode of the capacitance element C43 is coupled to the control circuit 240b (the comparator 252). The other electrode of the capacitance element C43 is coupled to one end of the coil L44. The other end of the coil L44 is coupled to one end of the resistance element R46. The other end of the resistance element R46 is coupled to the control circuit 240b (the comparator 252). That is, the capacitance element C42, the coil L43, and the resistance element R45 form a resonance circuit. The capacitance element C43, the coil L44, and the resistance element R46 form a resonance circuit. One resonance circuit and the other resonance circuit are electrically insulated from each other by an insulating layer (not shown) provided therebetween.

The rest of the circuit configuration is similar to that shown in FIG. 17 described in the second modification of the second embodiment.

Next, the operation of the semiconductor device 1 will be described with reference to FIG. 19.

In the case where the voltage VIN transitions from the “L” level to the “H” level, the DT circuit 103 supplies the voltage V41 at the “H” level to the driver circuit 204x without delay. The DT circuit 103 supplies the voltage V31 at the “H” level to the driver circuit 104x at a timing delayed by the time DTon.

The driver circuit 204x supplies the voltage V42 at the “L” level based on the voltage V41 at the “H” level to the signal generating circuit 201. The signal generating circuit 201 does not operate because the voltage V42 at the “L” level is supplied thereto. That is, the MOSFETs 260a and 260b (the switch element SW2) are turned off.

The driver circuit 104x supplies the voltage V32 at the “H” level based on the voltage V31 at the “H” level to the signal generating circuit 101 after a lapse of the time DTon from when driving of the driver circuit 204x is started. Since the voltage V32 at the “H” level is supplied to the signal generating circuit 101, the signal generating circuit 101 generates the signal S31 based on the voltage V32 and transmits the generated signal S31 to one electrode of the capacitance element C32.

In the case where the signal S31 is input to one electrode of the capacitance element C32, magnetic resonance coupling is formed between the resonance circuit including the capacitance element C32, the coil L33, and the resistance element R35, and the resonance circuit including the capacitance element C33, the coil L34, and the resistance element R36. By this, a voltage V37 is supplied from one end of the resonance circuit including the capacitance element C33, the coil L34, and the resistance element R36 to the comparator 152. A voltage V38 is supplied from the other end of the resonance circuit including the capacitance element C33, the coil L34, and the resistance element R36 to the comparator 152.

After the voltages V37 and V38 are supplied to the comparator 152, the comparator 152, the reception circuit 151, and the driver circuit 150x operate in a similar manner to those of the second modification of the second embodiment. As a result, the MOSFETs 160a and 160b (the switch element SW1) transition to the ON state after a lapse of the time Dion from the transition of the MOSFETs 260a and 260b (the switch element SW2) to the OFF state.

On the other hand, in the case where the voltage VIN transitions from the “H” level to the “L” level, the DT circuit 103 supplies the voltage V31 at the “L” level to the driver circuit 104x without delay. The DT circuit 103 supplies the voltage V41 at the L″ level to the driver circuit 204x at a timing delayed by the time DToff.

The driver circuit 104x supplies the voltage V32 at the “L” level based on the voltage V31 at the “L” level to the signal generating circuit 101. The signal generating circuit 101 does not operate because the voltage V32 at the “L” level is supplied thereto. That is, the MOSFETs 160a and 160b (the switch element SW1) are turned off.

The driver circuit 204x supplies the voltage V42 at the “H” level based on the voltage V41 at the “L” level to the signal generating circuit 201 after a lapse of the time DToff from when driving of the driver circuit 104x is started. Since the voltage V42 at the “H” level is supplied to the signal generating circuit 201, the signal generating circuit 201 generates the signal S41 based on the voltage V42 and transmits the generated signal S41 to one electrode of the capacitance element C42.

In the case where the signal S41 is input to one electrode of the capacitance element C42, magnetic resonance coupling is formed between the resonance circuit including the capacitance element C42, the coil L43, and the resistance element R45, and the resonance circuit including the capacitance element C43, the coil L44, and the resistance element R46. By this, a voltage V47 is supplied from one end of the resonance circuit including the capacitance element C43, the coil L44, and the resistance element R46 to the comparator 252. A voltage V48 is supplied from the other end of the resonance circuit including the capacitance element C43, the coil L44, and the resistance element R46 to the comparator 252.

After the voltages V47 and V48 are supplied to the comparator 252, the comparator 252, the reception circuit 251, and the driver circuit 250x operate in a similar manner to those of the second modification of the second embodiment. As a result, the MOSFETs 260a and 260b (the switch element SW2) transition to the ON state after a lapse of the time DToff from the transition of the MOSFETs 160a and 160b (the switch element SW1) to the OFF state.

The present modification also produces advantageous effects similar to those of the second embodiment.

### (Fifth Modification)

A semiconductor device according to a fifth modification of the second embodiment will be described. The semiconductor device 1 according to the fifth modification of the second embodiment differs from that of the first modification of the second embodiment in that it controls the switch elements SW1 and SW2 based on a signal utilizing sonic wave coupling (oscillation). In the following description, the description of the similar configurations to those of the first modification of the second embodiment will be omitted, and the configurations different from those of the first modification of the second embodiment will be mainly described.

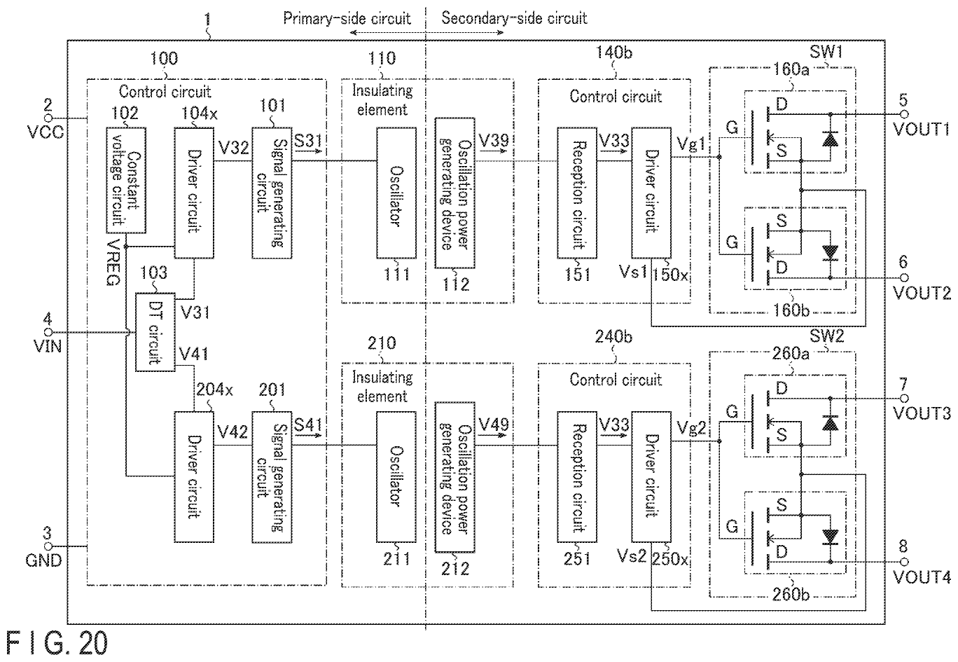

A configuration of the semiconductor device 1 will be described with reference to FIG. 20. FIG. 20 is a circuit diagram showing an example of the configuration of the semiconductor device 1.

As shown in FIG. 20, the insulating element 110 has a configuration in which the coils L31 and L32 in the first modification of the second embodiment are replaced with the oscillator 111 and the oscillation power generating device 112. Specifically, for example, the oscillator 111 is coupled to the signal generating circuit 101. The oscillation power generating device 112 is coupled to the control circuit 140b (the reception circuit 151). The oscillator 111 and the oscillation power generating device 112 are electrically insulated from each other by an insulating layer (not shown) provided therebetween.

The insulating element 210 has a configuration in which the coils L41 and L42 in the first modification of the second embodiment are replaced with an oscillator 211 and an oscillation power generating device 212. Specifically, for example, the oscillator 211 is coupled to the signal generating circuit 201. The oscillation power generating device 212 is coupled to the control circuit 240b (the reception circuit 251). The oscillator 211 and the oscillation power generating device 212 are electrically insulated from each other by an insulating layer (not shown) provided therebetween.

The oscillators 111 and 211 and the oscillation power generating device 112 and 212 each have a configuration similar to that shown in FIG. 12 described in the eighth modification of the first embodiment.

The rest of the circuit configuration is similar to that shown in FIG. 16 described in the first modification of the second embodiment.

Next, the operation of the semiconductor device 1 will be described with reference to FIG. 20.

In the case where the voltage VIN transitions from the “L” level to the “H” level, the DT circuit 103 supplies the voltage V41 at the “H” level to the driver circuit 204x without delay. The DT circuit 103 supplies the voltage V31 at the “H” level to the driver circuit 104x at a timing delayed by the time DTon.

The driver circuit 204x supplies the voltage V42 at the “L” level based on the voltage V41 at the “H” level to the signal generating circuit 201. The signal generating circuit 201 does not operate because the voltage V42 at the “L” level is supplied thereto. That is, the MOSFETs 260a and 260b (the switch element SW2) are turned off.

The driver circuit 104x supplies the voltage V32 at the “H” level based on the voltage V31 at the “H” level to the signal generating circuit 101 after a lapse of the time DTon from when driving of the driver circuit 204x is started. Since the voltage V32 at the “H” level is supplied to the signal generating circuit 101, the signal generating circuit 101 generates the signal S31 based on the voltage V32 and transmits the generated signal S31 to the oscillator 111.

In the case where the signal S31 is input to the oscillator 111, the oscillator 111 generates an oscillation. The oscillation power generating device 112 detects the generated oscillation and converts the detected oscillation into a voltage. The oscillation power generating device 112 supplies the converted voltage as a voltage V39 to the reception circuit 151.

After the voltage V39 is supplied to the reception circuit 151, the reception circuit 151 and the driver circuit 150x operate in a similar manner to those of the first modification of the second embodiment. As a result, the MOSFETs 160a and 160b (the switch element SW1) transition to the ON state after a lapse of the time DTon from the transition of the MOSFETs 260a and 260b (the switch element SW2) to the OFF state.

On the other hand, in the case where the voltage VIN transitions from the “H” level to the “L” level, the DT circuit 103 supplies the voltage V31 at the “L” level to the driver circuit 104x without delay. The DT circuit 103 supplies the voltage V41 at the L″ level to the driver circuit 204x at a timing delayed by the time DToff.

The driver circuit 104x supplies the voltage V32 at the “L” level based on the voltage V31 at the “L” level to the signal generating circuit 101. The signal generating circuit 101 does not operate because the voltage V32 at the “L” level is supplied thereto. That is, the MOSFETs 160a and 160b (the switch element SW1) are turned off.

The driver circuit 204x supplies the voltage V42 at the “H” level based on the voltage V41 at the “L” level to the signal generating circuit 201 after a lapse of the time DToff from when driving of the driver circuit 104x is started. Since the voltage V42 at the “H” level is supplied to the signal generating circuit 201, the signal generating circuit 201 generates the signal S41 based on the voltage V42 and transmits the generated signal S41 to the oscillator 211.

In the case where the signal S41 is input to the oscillator 211, the oscillator 211 generates an oscillation. The oscillation power generating device 212 detects the generated oscillation and converts the detected oscillation into a voltage. The oscillation power generating device 212 supplies the converted voltage as a voltage V49 to the reception circuit 251.

After the voltage V49 is supplied to the reception circuit 251, the reception circuit 251 and the driver circuit 250x operate in a similar manner to those of the first modification of the second embodiment. As a result, the MOSFETs 260a and 260b (the switch element SW2) transition to the ON state after a lapse of the time DToff from the transition of the MOSFETs 160a and 160b (the switch element SW1) to the OFF state.

The present modification also produces advantageous effects similar to those of the second embodiment.

### 3. Third Embodiment

A semiconductor device according to a third embodiment will be described. The semiconductor device 1 according to the third embodiment differs from that of the second embodiment in terms of configurations of the control circuit 240b and the switch element SW2. The following will omit a description of a configuration similar to that of the second embodiment and will mainly provide a description of a configuration different from that of the second embodiment.

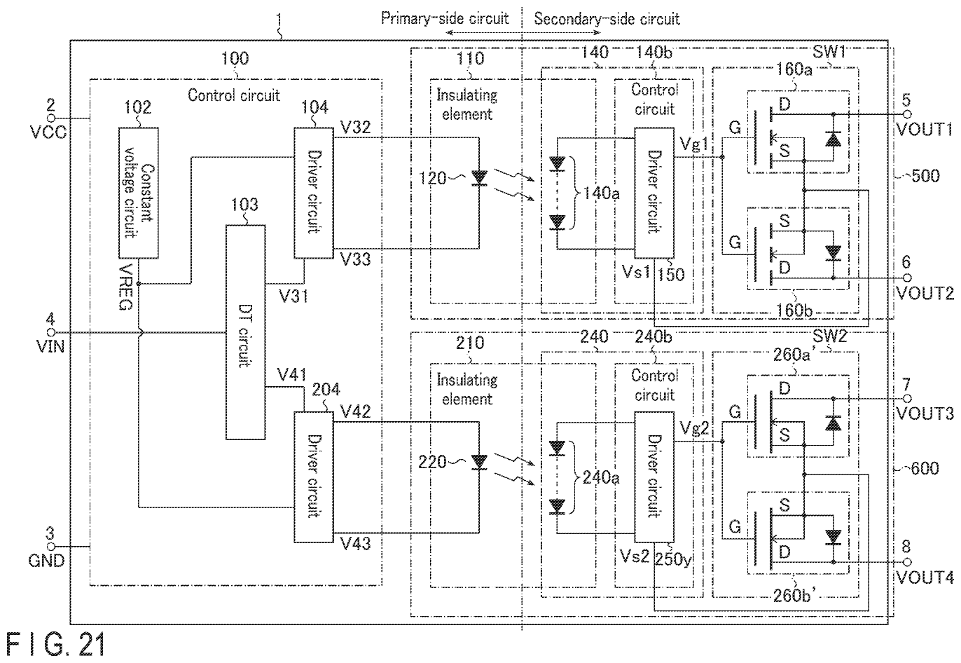

The configuration of the semiconductor device 1 will be described with reference to FIG. 21. FIG. 21 is a circuit diagram showing an example of the configuration of the semiconductor device 1.

The switch element SW2 has a configuration in which the MOSFETs 260a and 260b in the second embodiment are respectively replaced with MOSFETs 260a′ and 260b′.

The MOSFETs 260a′ and 260b′ are, for example, re-channel MOS transistors of a depression type. A threshold voltage of each of the MOSFETs 260a′ and 260b′ is, for example, −1 V. In the case where the MOSFETs 260a′ and 260b′ are in the ON state, the semiconductor device 1 transmits a signal. In the case where the MOSFETs 260a′ and 260b′ are in the OFF state, the semiconductor device 1 does not transmit a signal.

The control circuit 240b has a configuration in which the driver circuit 250 in the second embodiment is replaced with a driver circuit 250y.

The driver circuit 250y is a circuit configured to drive the MOSFETs 260a′ and 260b′ based on voltages at both ends of the light receiving element 240a. For example, the driver circuit 250y applies the voltage Vg2 based on voltages at both ends of the light receiving element 240a to gates of the MOSFETs 260a′ and 260b′. The voltage Vg2 is, for example, a voltage at the anode of the light receiving element 240a. The driver circuit 250y applies the voltage Vs2 based on voltages at both ends of the light receiving element 240a to sources of the MOSFETs 260a′ and 260b′. The voltage Vs2 is, for example, a voltage at the cathode of the light receiving element 240a.

The gate of the MOSFET 260a′ is coupled to the gate of the MOSFET 260b′. The source of the MOSFET 260a′ is coupled to the source of the MOSFET 260b′. A drain of the MOSFET 260a′ is coupled to the input/output terminal 7. A drain of the MOSFET 260b′ is coupled to the input/output terminal 8.

The rest of the circuit configuration is similar to that shown in FIG. 13 described in the second embodiment.

The structure of the semiconductor device 1 is similar to those shown in FIG. 2 and FIG. 3 described in the first embodiment.

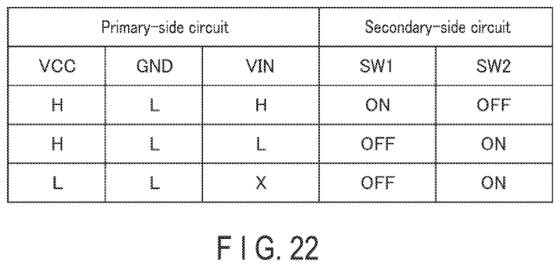

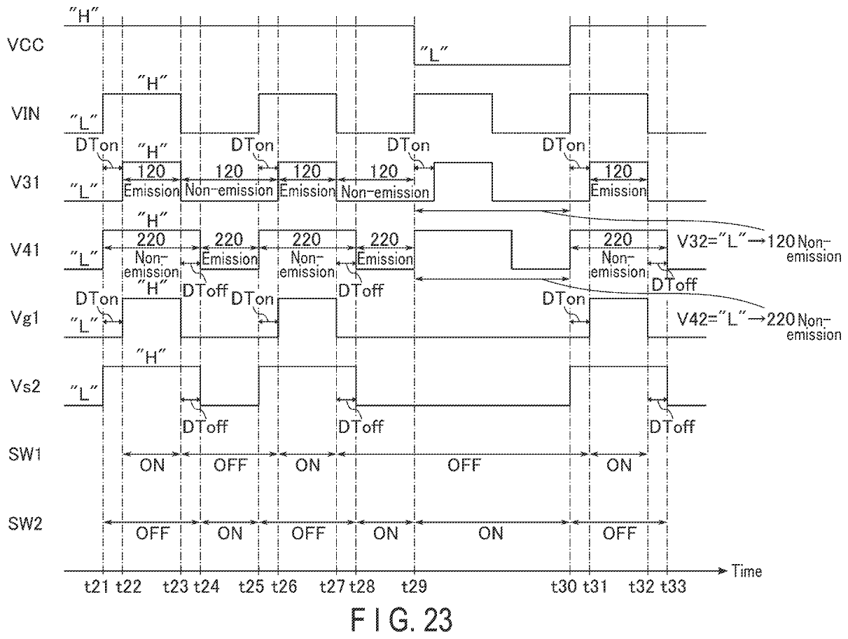

Next, the operation of the semiconductor device 1 will be described with reference to FIG. 22 and FIG. 23.

FIG. 22 is a truth table showing an example of the operation of the semiconductor device 1. The example in FIG. 22 shows a relationship between each of the voltages VCC, GND, and VIN in the primary-side circuit and the operations of the switch elements SW1 and SW2 in the secondary-side circuit. FIG. 23 is a timing chart showing an example of the operation of the semiconductor device 1. The example in FIG. 23 shows each of the voltages VCC, VIN, V31, V41, Vg1, and Vs2, and each state of the switch elements SW1 and SW2 at each time. The following will describe the case in which the voltage VCC is at the “H” level from time t21 to time t29, transitions to the “L” level at the time t29, transitions to the “H” level at time t30, and is thereafter at the “H” level from the time t30 to time t33. During a period before the time t21, the switch element SW1 is turned off and the switch element SW2 is turned on.

First, the case in which the voltage VCC is at the “H” level, the voltage GND is at the “L” level, and the voltage VIN is at the “H” level, as shown in the first line of the truth table in FIG. 22, will be described.

At the time t21, in the case where the voltage VIN transitions from the “L” level to the “H” level, the DT circuit 103 operates based on the voltage VIN in a similar manner to that of the second embodiment, and the voltage V41 is set to the “H” level at the time t21 whereas the voltage V31 is set to the “H” level at time t22. The driver circuit 204 operates based on the voltage V41 in a similar manner to that of the second embodiment, and the light emitting element 220 transitions to the non-emission state at the time t21. The driver circuit 104 operates based on the voltage V31 in a similar manner to that of the second embodiment, and the light emitting element 120 transitions to the emission state at the time t22.

In the case where the light emitting element 220 transitions to the non-emission state, the light receiving element 240a receives no light from the light emitting element 220, thereby generating no voltage. The driver circuit 250y applies the voltage Vg2 (for example, the voltage GND) at the “L” level based on voltages at both ends of the light receiving element 240a to the gates of the MOSFETs 260a′ and 260b′. The driver circuit 250y applies the voltage Vs2 (for example, 5 V) at the “H” level based on voltages at both ends of the light receiving element 240a to the sources of the MOSFETs 260a′ and 260b′. By this, the voltage Vs2 is set to the “H” level at the time t21. As a result, the MOSFETs 260a′ and 260b′ (the switch element SW2) are turned off, and the input/output terminals 7 and 8 are not electrically coupled together. Furthermore, in the case where the light emitting element 120 transitions to the emission state, the light receiving element 140a and the control circuit 140b (the driver circuit 150) operate in a similar manner to that of the second embodiment, and the voltage Vg1 is set to the “H” level at the time t22. By this, the MOSFETs 160a and 160b (the switch element SW1) are turned on, and the input/output terminals 5 and 6 are electrically coupled together.

The voltage V31 maintains the “H” level from the time t22 to time t23. By this, the light emitting element 120 maintains the emission state from the time t22 to the time t23. The voltage V41 maintains the “H” level from the time t21 to time t24. By this, the light emitting element 220 maintains the non-emission state from the time t21 to the time t24.

The voltage Vg1 maintains the “H” level from the time t22 to the time t23. By this, the switch element SW1 maintains the ON state from the time t22 to the time t23. The voltage Vs2 maintains the “H” level from the time t21 to the time t24. By this, the switch element SW2 maintains the OFF state from the time t21 to the time t24.

Next, the case in which the voltage VCC is at the “H” level, the voltage GND is at the “L” level, and the voltage VIN is at the “L” level, as shown in the second line of the truth table in FIG. 22, will be described.

At the time t23, in the case where the voltage VIN transitions from the “H” level to the “L” level, the DT circuit 103 operates based on the voltage VIN in a similar manner to that of the second embodiment, and the voltage V31 is set to the “L” level at the time t23 whereas the voltage V41 is set to the “L” level at the time t24. The driver circuit 104 operates based on the voltage V31 in a similar manner to that of the second embodiment, and the light emitting element 120 transitions to the non-emission state at the time t23. The driver circuit 204 operates based on the voltage V41 in a similar manner to that of the second embodiment, and the light emitting element 220 transitions to the emission state at the time t24.

In the case where the light emitting element 120 transitions to the non-emission state, the light receiving element 140a and the control circuit 140b (the driver circuit 150) operate in a similar manner to those of the second embodiment, and the voltage Vg1 is set to the “L” level at the time t23. By this, the MOSFETs 160a and 160b (the switch element SW1) are turned off, and the input/output terminals 5 and 6 are not electrically coupled together. In the case where the light emitting element 220 transitions to the emission state, the light receiving element 240a receives light from the light emitting element 220, thereby generating a voltage. The driver circuit 250y applies the voltage Vg2 (for example, the voltage GND) at the “L” level based on voltages at both ends of the light receiving element 240a to the gates of the MOSFETs 260a′ and 260b′. The driver circuit 250y applies the voltage Vs2 (for example, the voltage GND) at the “L” level based on voltages at both ends of the light receiving element 240a to the sources of the MOSFETs 260a′ and 260b′. By this, the voltage Vs2 is set to the “L” level at the time t24. As a result, the MOSFETs 260a′ and 260b′ (the switch element SW2) are turned on, and the input/output terminals 7 and 8 are electrically coupled together.

The voltage V31 maintains the “L” level from the time t23 to time t26. By this, the light emitting element 120 maintains the non-emission state from the time t23 to the time t26. The voltage V41 maintains the “L” level from the time t24 to time t25. By this, the light emitting element 220 maintains the emission state from the time t24 to the time t25.

The voltage Vg1 maintains the “L” level from the time t23 to the time t26. By this, the switch element SW1 maintains the OFF state from the time t23 to the time t26. The voltage Vs2 maintains the “L” level from the time t24 to the time t25. By this, the switch element SW2 maintains the ON state from the time t24 to the time t25.

The operation from the time t25 to time t29 is the same as the operation from the time t21 to the time t25.

Next, the case in which the voltage VCC is at the “L” level, the voltage GND is at the “L” level, and the voltage VIN is at the “X” level (the “H” level or the “L” level), as shown in the third line of the truth table in FIG. 22, that is, the case in which the voltage VCC is not supplied, will be described.

At the time t29, in the case where the voltage VCC transitions to the “L” level, the DT circuit 103 operates in a similar manner to the operation at the time t21. The driver circuit 104 applies the voltage V32 at the “L” level to the anode of the light emitting element 120 at the time t29. By this, the light emitting element 120 transitions to the non-emission state. The driver circuit 204 applies the voltage V42 at the “L” level to the anode of the light emitting element 220 at the time t29. By this, the light emitting element 220 transitions to the non-emission state.

In the case where the light emitting element 120 transitions to the non-emission state, the light receiving element 140a and the control circuit 140b (the driver circuit 150) operate in a similar manner to those of the second embodiment, and the voltage Vg1 is set to the “L” level at the time t29. By this, the MOSFETs 160a and 160b (the switch element SW1) are turned off. Furthermore, in the case where the light emitting element 220 transitions to the non-emission state, the driver circuit 250y applies the voltage Vg2 (for example, the voltage GND) at the “L” level to the gates of the MOSFETs 260a′ and 260b′. The driver circuit 250y applies the voltage Vs2 (for example, the voltage GND) at the “L” level to the sources of the MOSFETs 260a′ and 260b′. By this, the voltage Vs2 is set to the “L” level at the time t29. As a result, the MOSFETs 260a′ and 260b′ (the switch element SW2) are turned on, and input/output terminals 7 and 8 are electrically coupled together.

The voltage level of the voltage V31 from the time t29 to time t30 is set to be similar to the voltage level from the time t21 to the time t25. At the time t29, in the case where the voltage V32 at the “L” level is applied to the anode of the light emitting element 120, the light emitting element 120 maintains the non-emission state from the time t29 to the time t30. The voltage level of the voltage V41 from the time t29 to the time t30 is set to be similar to the voltage level from the time t21 to the time t25. At the time t29, in the case where the voltage V42 at the “L” level is applied to the anode of the light emitting element 220, the light emitting element 220 maintains the non-emission state from the time t29 to the time t30.

The voltage Vg1 maintains the “L” level from the time t29 to the time t30. By this, the switch element SW1 maintains the OFF state from the time t29 to the time t30. The voltage Vs2 maintains the “L” level from the time t29 to the time t30. By this, the switch element SW2 maintains the ON state from the time t29 to the time t30.

The operation from the time t30 to time t33 is the same as the operation from the time t21 to the time t24.

The present embodiment also produces advantageous effects similar to those of the second embodiment.

Furthermore, according to the present embodiment, the semiconductor device 1 includes the MOSFETs 260a′ and 260b′ of a depression type (the switch element SW2). Therefore, in the case where the voltage VCC is at the “L” level, the switch element SW2 can be turned on.

The circuit configurations of the magnetic coupling, the capacitance coupling, the magnetic resonance coupling, and the sonic wave coupling described in the first to fifth modifications of the second embodiment are applicable to the semiconductor device 1 according to the present embodiment. Each of the structures of the first to third modifications of the first embodiment is applicable to the semiconductor device 1 according to the present embodiment.

### 4. Fourth Embodiment

A semiconductor device according to a fourth embodiment will be described. The semiconductor device 1 according to the fourth embodiment differs from that of the third embodiment in terms of the primary-side circuit and the secondary-side circuit. The following will omit a description of a configuration similar to that of the third embodiment and will mainly provide a description of a configuration different from that of the third embodiment.

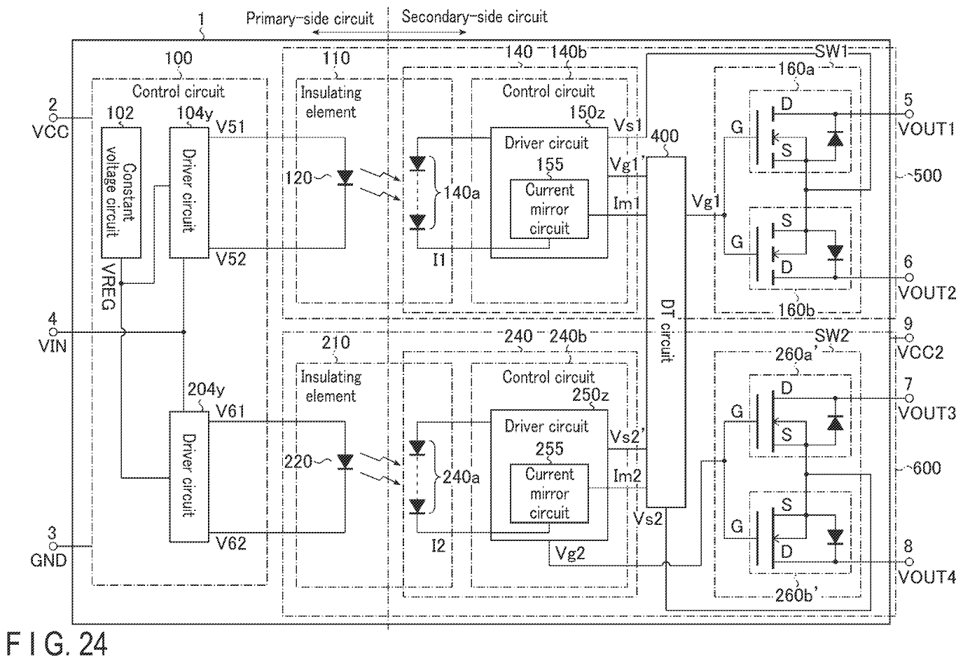

A configuration of the semiconductor device 1 will be described with reference to FIG. 24. FIG. 24 is a circuit diagram showing an example of a configuration of the semiconductor device 1.

As shown in FIG. 24, the control circuit 100 has a configuration in which the driver circuits 104 and 204 in the third embodiment are respectively replaced with driver circuits 104y and 204y. The DT circuit 103 in the third embodiment is eliminated.

The driver circuit 104y is a circuit configured to drive the insulating element 110 (the light emitting element 120) based on the voltage VIN. For example, the driver circuit 104y applies the voltage VCC as a voltage V51 to the anode of the light emitting element 120. The driver circuit 104y applies a voltage V52 based on the voltage VIN (for example, a voltage at a different voltage level from that of the voltage VIN) to the cathode of the light emitting element 120.

The driver circuit 204y is a circuit configured to drive the insulating element 210 (the light emitting element 220) based on the voltage VIN. For example, the driver circuit 204y applies the voltage VCC as a voltage V61 to the anode of the light emitting element 220. The driver circuit 204y applies a voltage V62 based on the voltage VIN (for example, a voltage at the same voltage level from that of the voltage VIN) to the cathode of the light emitting element 220.

In the secondary-side circuit, the control circuit 140b has a configuration in which the driver circuit 150 in the third embodiment is replaced with a driver circuit 150z.

The driver circuit 150z is a circuit configured to drive the MOSFETs 160a and 160b based on voltages at both ends of the light receiving element 140a and an optical current I1 flowing through the light receiving element 140a.

The driver circuit 150z includes, for example, a current mirror circuit 155. The current mirror circuit 155 is a circuit configured to generate a mirror current Im1 corresponding to the optical current I1 flowing through the light receiving element 140a. For example, the driver circuit 150z supplies a voltage Vg1′ based on voltages at both ends of the light receiving element 140a to a DT circuit 400 to be described later. The voltage Vg1′ is, for example, a voltage at the anode of the light receiving element 140a. The driver circuit 150z applies a voltage Vs1 based on voltages at both ends of the light receiving element 140a to the sources of the MOSFETs 160a and 160b. The voltage Vs1 is, for example, a voltage at the cathode of the light receiving element 140a. The current mirror circuit 155 supplies the mirror current Im1 corresponding to the optical current I1 flowing through the light receiving element 140a to the DT circuit 400 to be described later.

The control circuit 240b has a configuration in which the driver circuit 250y in the third embodiment is replaced with a driver circuit 250z.

The driver circuit 250z is a circuit configured to drive the MOSFETs 260a′ and 260b′ based on voltages at both ends of the light receiving element 240a and an optical current I2 flowing through the light receiving element 240a.

The driver circuit 250z includes, for example, a current mirror circuit 255. The current mirror circuit 255 is a circuit configured to generate a mirror current Im2 corresponding to the optical current I2 flowing through the light receiving element 240a. For example, the driver circuit 250z applies the voltage Vg2 based on voltages at both ends of the light receiving element 240a to gates of the MOSFETs 260a′ and 260b′. The voltage Vg2 is, for example, a voltage at the anode of the light receiving element 240a. The driver circuit 250z supplies a voltage Vs2′ based on voltages at both ends of the light receiving element 240a to the DT circuit 400 to be described later. The voltage Vs2′ is, for example, a voltage at the cathode of the light receiving element 240a. The current mirror circuit 255 supplies the mirror current Im2 corresponding to the optical current I2 flowing through the light receiving element 240a to the DT circuit 400 to be described later.

The secondary-side circuit further includes the power supply voltage terminal 9 and the DT circuit 400.

A voltage VCC2 is externally supplied to the power supply voltage terminal 9. The light receiving elements 140a and 240a, the control circuit 140b and 240b, the DT circuit 400, and the MOSFETs 160a, 160b, 260a′, 260b′ are driven with the voltage VCC2.

The DT circuit 400 is a circuit configured to exert control to prevent the pair of MOSFETs 160a and 160b (the switch element SW1) and the pair of MOSFETs 260a′ and 260b′ (the switch element SW2) from being simultaneously turned on. The voltage Vg1′ and the current Im1 are supplied from the control circuit 140b to the DT circuit 400, and the voltage Vs2′ and the current Im2 are supplied from the control circuit 240b to the DT circuit 400. The DT circuit 400 controls the voltage Vs2′ based on the current Im1 supplied from the current mirror circuit 155. The DT circuit 400 controls the voltage Vg1′ based on the current Im2 supplied from the current mirror circuit 255.

Specifically, in the case where the current Im1 has been supplied to the DT circuit 400, that is, the optical current I1 is flowing through the light receiving element 140a, the DT circuit 400 pulls up (level-shifts) the voltage Vs2′. In the case where the current Im1 has not been supplied to the DT circuit 400, that is, the optical current I1 is not flowing through the light receiving element 140a, the DT circuit 400 does not pull up the voltage Vs2′.

In the case where the current Im2 has been supplied to the DT circuit 400, that is, the optical current I2 is flowing through the light receiving element 240a, the DT circuit 400 pulls down (level-shifts) the voltage Vg1′. In the case where the current Im2 has not been supplied to the DT circuit 400, that is, the optical current I2 is not flowing through the light receiving element 240a, the DT circuit 400 does not pull down the voltage Vg1′.

Next, the operation of the semiconductor device 1 will be described with reference to FIG. 24.

In the case where the voltage VIN is at the “H” level, the driver circuit 104y applies the voltage VCC as the voltage V51 to the anode of the light emitting element 120. The driver circuit 104y applies the voltage V52 at the “L” level based on the voltage VIN to the cathode of the light emitting element 120. By this, the light emitting element 120 transitions to the emission state. The driver circuit 204y applies the voltage VCC as the voltage V61 to the anode of the light emitting element 220. The driver circuit 204y applies the voltage V62 at the “H” level based on the voltage VIN to the cathode of the light emitting element 220. By this, the light emitting element 220 transitions to the non-emission state.

In the case where the light emitting element 120 transitions to the emission state, the light receiving element 140a receives light from the light emitting element 120, thereby generating a voltage. The optical current I1 flows through the light receiving element 140a. The driver circuit 150z supplies the voltage Vg1′ (for example, 5 V) at the “H” level based on voltages at both ends of the light receiving element 140a to the DT circuit 400. The driver circuit 150z applies the voltage Vs1 (for example, the voltage GND) at the “L” level based on voltages at both ends of the light receiving element 140a to the sources of the MOSFETs 160a and 160b. The current mirror circuit 155 supplies the mirror current Im1 corresponding to the optical current I1 to the DT circuit 400.

Furthermore, in the case where the light emitting element 220 transitions to the non-emission state, the light receiving element 240a receives no light from the light emitting element 220, thereby generating no voltage. The optical current I2 does not flow through the light receiving element 240a. The driver circuit 250z applies the voltage Vg2 (for example, the voltage GND) at the “L” level based on voltages at both ends of the light receiving element 240a to the gates of the MOSFETs 260a′ and 260b′. The driver circuit 250z supplies the voltage Vs2′ (for example, 5 V) at the “H” level based on voltages at both ends of the light receiving element 240a to the DT circuit 400. The current mirror circuit 255 does not supply the mirror current Im2 corresponding to the optical current I2 to the DT circuit 400.

The DT circuit 400 does not pull down the voltage Vg1′ because the current Im2 is not supplied thereto. The DT circuit 400 applies the voltage Vg1′ not pulled down, as the voltage Vg1 to the gates of the MOSFETs 160a and 160b. By this, the MOSFETs 160a and 160b (the switch element SW1) are turned on.

Furthermore, the DT circuit 400 pulls up the voltage Vs2′ because the current Im1 is supplied thereto. The DT circuit 400 applies the pulled-up voltage Vs2′ as the voltage Vs2 to the sources of the MOSFETs 260a′ and 260b′. By this, the MOSFETs 260a′ and 260b′ (the switch element SW2) are turned off.

On the other hand, in the case where the voltage VIN is at the “L” level, the driver circuit 104y applies the voltage VCC as the voltage V51 to the anode of the light emitting element 120. The driver circuit 104y applies the voltage V52 at the “H” level based on the voltage VIN to the cathode of the light emitting element 120. By this, the light emitting element 120 transitions to the non-emission state. The driver circuit 204y applies the voltage VCC as the voltage V61 to the anode of the light emitting element 220. The driver circuit 204y applies the voltage V62 at the “L” level based on the voltage VIN to the cathode of the light emitting element 220. By this, the light emitting element 220 transitions to the emission state.

In the case where the light emitting element 220 transitions to the emission state, the light receiving element 240a receives light from the light emitting element 220, thereby generating a voltage. The optical current I2 flows through the light receiving element 240a. The driver circuit 250z applies the voltage Vg2 (for example, the voltage GND) at the “L” level based on voltages at both ends of the light receiving element 240a to the gates of the MOSFETs 260a′ and 260b′. The driver circuit 250z supplies the voltage Vs2′ (for example, the voltage GND) at the “L” level based on voltages at both ends of the light receiving element 240a to the DT circuit 400. The current mirror circuit 255 supplies the mirror current Im2 corresponding to the optical current I2 to the DT circuit 400.

Furthermore, in the case where the light emitting element 120 transitions to the non-emission state, the light receiving element 140a receives no light from the light emitting element 120, thereby generating no voltage. The optical current I1 does not flow through the light receiving element 140a. The driver circuit 150z supplies the voltage Vg1′ (for example, the voltage GND) at the “L” level based on voltages at both ends of the light receiving element 140a to the DT circuit 400. The driver circuit 150z applies the voltage Vs1 (for example, the voltage GND) at the “L” level based on voltages at both ends of the light receiving element 140a to the sources of the MOSFETs 160a and 160b. The current mirror circuit 155 does not supply the mirror current Im1 corresponding to the optical current I1 to the DT circuit 400.

The DT circuit 400 does not pull up the voltage Vs2′ because the current Im1 is supplied thereto. The DT circuit 400 applies the voltage Vs2′ not pulled up, as the voltage Vs2 to the sources of the MOSFETs 260a′ and 260b′. By this, the MOSFETs 260a′ and 260b′ (the switch element SW2) are turned on.

Furthermore, the DT circuit 400 pulls down the voltage Vg1′ because the current Im2 is supplied thereto. The DT circuit 400 applies the pulled-down voltage Vg1′ as the voltage Vg1 to the gates of the MOSFETs 160a and 160b. By this, the MOSFETs 160a and 160b (the switch element SW1) are turned off.

The rest of the circuit configuration is similar to that shown in FIG. 21 described in the third embodiment. In the present embodiment, the light emitting elements 120 and 220 are alternatively driven by the driver circuits 104y and 204y within the control circuit 100.

Furthermore, the secondary-side circuit includes the DT circuit 400. The DT circuit 400 adjusts the voltage Vs2′ supplied from the control circuit 240b based on the current Im1 supplied from the control circuit 140b, and adjusts the voltage Vg1′ supplied from the control circuit 140b based on the current Im2 supplied from the control circuit 240b. The DT circuit 400 applies the adjusted voltage Vg1′ as the voltage Vg1 to the gates of the MOSFETs 160a and 160b. The DT circuit 400 applies the adjusted voltage Vs2′ as the voltage Vs2 to the sources of the MOSFETs 260a′ and 260b′.

Specifically, the DT circuit 400 pulls up the voltage Vs2′ supplied from the control circuit 240b, based on the current Im1 supplied from the control circuit 140b, and pulls down the voltage Vg1′ supplied from the control circuit 140b, based on the current Im2 supplied from the control circuit 240b. The DT circuit 400 pulls up the voltage Vs2′ in the case where the current Im1 is supplied, and does not pull up the voltage Vs2′ in the case where the current Im1 is not supplied. The DT circuit 400 pulls down the voltage Vg1′ in the case where the current Im2 is supplied, and does not pull down the voltage Vg1′ in the case where the current Im2 is not supplied.

In the case where the current Im1 is supplied from the control circuit 140b, the DT circuit 400 applies the pulled-up voltage Vs2′ as the voltage Vs2 to the sources of the MOSFETs 260a′ and 260b′. In the case where the current Im1 is not supplied from the control circuit 140b, the DT circuit 400 applies the voltage Vs2′ not pulled up as the voltage Vs2 to the sources of the MOSFETs 260a′ and 260b′. In the case where the current Im2 is supplied from the control circuit 240b, the DT circuit 400 applies the pulled-down voltage Vg1′ as the voltage Vg1 to the gates of the MOSFETs 160a and 160b. In the case where the current Im2 is not supplied from the control circuit 240b, the DT circuit 400 applies the voltage Vg1′ not pulled down as the voltage Vg1 to the gates of the MOSFETs 160a and 160b.

Thus, according to the present embodiment, in the case where the MOSFETs 160a and 160b are in the ON state, the MOSFETs 260a′ and 260b′ are turned off. In the case where the MOSFETs 260a′ and 260b′ are in the ON state, the MOSFETs 160a and 160b are turned off. This can prevent the switch elements SW1 and SW2 from being simultaneously turned on.

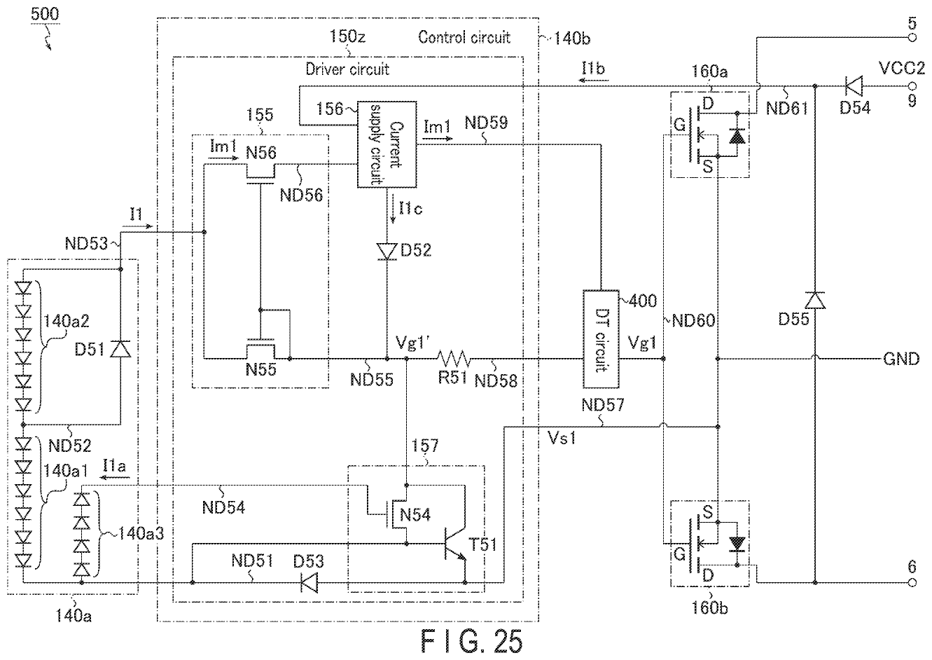

A configuration of the secondary-side circuit will be described with reference to FIG. 25. FIG. 25 is a circuit diagram showing an example of the configuration of the secondary-side circuit. The example in FIG. 25 shows the configuration of the photo relay 500. Meanwhile, as shown in FIG. 24, the configuration of the photo relay 600 is similar to that of the photo relay 500 except that coupling between the driver circuit 250z and the DT circuit 400, coupling between the driver circuit 250z and the gates of the MOSFETs 260a′ and 260b′, and coupling between the DT circuit 400 and the sources of the MOSFETs 260a′ and 260b′ are respectively different from coupling between the driver circuit 150z and the DT circuit 400, coupling between the driver circuit 150z and the sources of the MOSFETs 160a and 160b, and coupling between the DT circuit 400 and the gates of the MOSFETs 160a and 160b.

The light receiving element 140a includes a light receiving element 140a1 having a plurality of (six in the example of FIG. 25) photodiodes coupled in series, a light receiving element 140a2 having a plurality of (six in the example of FIG. 25) photodiodes coupled in series, a light receiving element 140a3 having a plurality of (four in the example of FIG. 25) photodiodes coupled in series, and a diode D51.

An anode of the light receiving element 140a1 is coupled to a node ND52. A cathode of the light receiving element 140a1 is coupled to a node ND51. An anode of the light receiving element 140a2 is coupled to a node ND53. A cathode of the light receiving element 140a2 is coupled to the node ND52. In other words, the light receiving elements 140a1 and 140a2 are coupled in series. The light receiving elements 140a1 and 140a2 are provided in order to charge up the voltage Vg1′ of a node ND55.

An anode of the diode D51 is coupled to the node ND52. A cathode of the diode D51 is coupled to the node ND53.

In the case where the light emitting element 120 (not shown) transitions to the emission state, the light receiving elements 140a1 and 140a2 transition to the ON state, thereby causing currents to respectively flow through the light receiving elements 140a1 and 140a2. As a result, a current (current I1) as a sum of the currents respectively flowing through the light receiving elements 140a1 and 140a2 flows to the node ND53. In the case where the light emitting element 120 (not shown) transitions to the non-emission state, the light receiving elements 140a1 and 140a2 transition to the OFF state, thereby causing no current to flow through each of the light receiving elements 140a1 and 140a2. As a result, the current I1 does not flow through the node ND53.

An anode of the light receiving element 140a3 is coupled to the node ND51. A cathode of the light receiving element 140a3 is coupled to a node ND54. The light receiving element 140a3 is provided in order to discharge the voltage Vg1′ of the node ND55.

In the case where the light emitting element 120 (not shown) transitions to the emission state, the light receiving element 140a3 transitions to the ON state, thereby causing a current I1a to flow from the node ND54 to the light receiving element 140a3. In the case where the light emitting element 120 (not shown) transitions to the non-emission state, the light receiving element 140a3 transitions to the OFF state, thereby causing the current I1a to flow from the light receiving element 140a3 to the node ND54.

The current mirror circuit 155 includes n-channel MOS transistors N55 and N56.

A source and a gate of the transistor N55 are coupled to the node ND55. A drain of the transistor N55 is coupled to the node ND53.

A source of the transistor N56 is coupled to the node ND56. A drain of the transistor N56 is coupled to the node ND53. A gate of the transistor N56 is coupled to the node ND55. That is, the transistor N55 and the transistor N56 form a current mirror.

The driver circuit 150z further includes a current supply circuit 156, a diode D52, a resistance element R51, a discharge circuit 157, and a diode D53.

The current supply circuit 156 is a circuit configured to supply a current based on both the current I1b based on the voltage VCC2 supplied from the power supply voltage terminal 9 and the mirror current Im1 corresponding to the current I1. Specifically, the current supply circuit 156 supplies a current I1c (=I1b+Im1) obtained by adding the current I1b to the current Im1, to an anode of the diode D52. The current supply circuit 156 supplies the current Im1 to the DT circuit 400.

The anode of the diode D52 is coupled to the current supply circuit 156. A cathode of the diode D52 is coupled to the node ND55. The diode D52 is provided in order to prevent the current I1c from flowing from the node ND55 to the current supply circuit 156.

One end of the resistance element R51 is coupled to the node ND55. The other end of the resistance element R51 is coupled to a node ND58. The resistance element R51 is provided in order to limit currents flowing through transistors N54 and T51 to be described later within the discharge circuit 157.

The discharge circuit 157 is a circuit configured to discharge the voltage Vg1′ of the node ND55. The discharge circuit 157 includes an n-channel MOS transistor N54 of a depression type and a bipolar transistor T51 of an npn type.

A source of the transistor N54 is coupled to the node ND51. A drain of the transistor N54 is coupled to the node ND55. A gate of the transistor N54 is coupled to the node ND54.

A collector of the transistor T51 is coupled to the node ND55. A base of the transistor T51 is coupled to the node ND51. An emitter of the transistor T51 is coupled to a node ND57. A voltage GND is supplied to the node ND57.

An anode of the diode D53 is coupled to the node ND57. A cathode of the diode D53 is coupled to the node ND51.

The secondary-side circuit further includes diodes D54 and D55.

An anode of the diode D54 is coupled to the power supply voltage terminal 9. A cathode of the diode D54 is coupled to a node ND61.

An anode of the diode D55 is coupled to the input/output terminal 6. A cathode of the diode D55 is coupled to the node ND61.

The voltage Vg1′ of the node ND55 is supplied from the driver circuit 150z to the DT circuit 400. The current Im1 is supplied from the current supply circuit 156 to the DT circuit 400. The DT circuit 400 adjusts the voltage Vg1′ based on the current Im2 supplied from the driver circuit 250z of the photo relay 600 (not shown). The DT circuit 400 applies the adjusted voltage Vg1′ as the voltage Vg1 to the gates of the MOSFETs 160a and 160b.

The gates of the MOSFET at 160a and 160b are coupled to a node ND60. The sources of the MOSFETs 160a and 160b are coupled to the node ND57. The drain of the MOSFET 160a is coupled to the input/output terminal 5. The drain of the MOSFET 160b is coupled to the input/output terminal 6.

In the case where the light emitting element 120 (not shown) transitions to the emission state, the light receiving elements 140a1 and 140a2 transition to the ON state, thereby causing the current I1 to flow through the node ND53. The current mirror circuit 155 supplies the mirror current Im1 corresponding to the current I1 to the current supply circuit 156. Based on the current I1b supplied from the power supply voltage terminal 9 and the current Im1 supplied from the current mirror circuit 155, the current supply circuit 156 supplies the current I1c (=I1b+Im1) to the diode D52 and supplies the current Im1 to the DT circuit 400. Furthermore, in the case where the light emitting element 120 (not shown) transitions to the emission state, the light receiving element 140a3 transitions to the ON state, thereby causing the current I1a to flow from the node ND54 to the light receiving element 140a3. By this, a voltage at the node ND54 with respect to the node ND57 becomes smaller than the threshold voltage (for example, −1 V) of the transistor N54, so that the transistors N54 and T51 within the discharge circuit 157 are turned off. As a result, the voltage Vg1′ at the node ND55 is charged up based on the current I1c. Because the current I1b based on the voltage VCC2 is supplied to the control circuit 140b, the voltage Vg1′ at the node ND55 is charged up at a higher speed as compared to the case in which no voltage is externally supplied to the secondary-side circuit. In other words, the secondary-side circuit operates at a higher speed as compared to the case in which no voltage is externally supplied to the secondary-side circuit.

On the other hand, in the case where the light emitting element 120 (not shown) transitions to the non-emission state, the light receiving elements 140a1 and 140a2 transition to the OFF state, thereby causing no current I1 to flow through the node ND53. The current mirror circuit 155 does not supply the current Im1 corresponding to the current I1 to the current supply circuit 156. Based on the current I1b supplied from the power supply voltage terminal 9, the current supply circuit 156 supplies the current I1c (=I1b) to the diode D52 and does not supply the current Im1 to the DT circuit 400. Furthermore, in the case where the light emitting element 120 (not shown) transitions to the non-emission state, the light receiving elements 140a3 transition to the OFF state, thereby causing the current I1a to flow from the light receiving element 140a3 to the node ND54. By this, a voltage at the node ND54 with respect to the node ND57 becomes equal to or greater than the threshold voltage (for example, −1 V) of the transistor N54, so that the transistors N54 and T51 within the discharge circuit 157 are turned on, thereby causing an emitter current to flow from the node ND55 to the node ND51. As a result, the voltage Vg1′ at the node ND55 is discharged. Because the current I1b based on the voltage VCC2 is supplied to the control circuit 140b, the voltage Vg1′ at the node ND55 is discharged at a higher speed as compared to the case in which no voltage is externally supplied to the secondary-side circuit. In other words, the secondary-side circuit operates at a higher speed as compared to the case in which no voltage is externally supplied to the secondary-side circuit.

As described above, according to the present embodiment, the secondary-side circuit includes the power supply voltage terminal 9. The voltage VCC2 is externally supplied to the power supply voltage terminal 9. The light receiving elements 140a and 240a, the control circuit 140b and 240b, the DT circuit 400, and the MOSFETs 160a, 160b, 260a′, 260b′ are driven with the voltage VCC2. The current I1b based on the voltage VCC2 is supplied from the power supply voltage terminal 9 to the control circuit 140b (the driver circuit 150z). Because the current I1b is supplied to the control circuit 140b, the secondary-side circuit can operate at a higher speed as compared to the case in which no voltage is externally supplied to the secondary-side circuit.

The second embodiment may be applied to the semiconductor device 1 according to the present embodiment by replacing the MOSFETs 260a′ and 260b′ with the MOSFETs 260a and 260b of the enhancement type. In such a case, the DT circuit 400 may adjust (pull down) the voltage Vg2 to be applied to the gates of the MOSFETs 260a and 260b, based on the current Im1.

### (First Modification)

A semiconductor device according to a first modification of the fourth embodiment will be described. The semiconductor device 1 according to the first modification of the fourth embodiment differs from that of the fourth embodiment in that the secondary-side circuit is provided with a protection circuit. The following will omit a description of a configuration similar to that of the fourth embodiment and will mainly provide a description of a configuration different from that of the fourth embodiment.

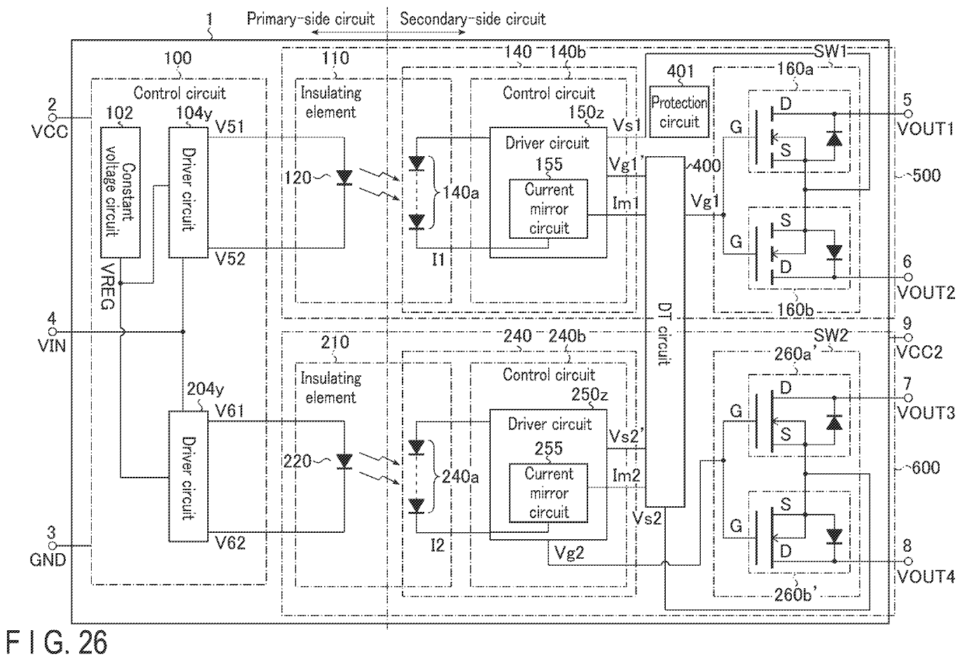

A configuration of the semiconductor device 1 will be described with reference to FIG. 26. FIG. 26 is a circuit diagram showing an example of the configuration of the semiconductor device 1.

As shown in FIG. 26, the secondary-side circuit further includes a protection circuit 401.

The protection circuit 401 is a circuit configured to protect the semiconductor device 1. The protection circuit 401 is, for example, an overcurrent protection circuit, an overheat protection circuit, an overvoltage protection circuit, a voltage drop detection circuit, etc.

For example, in the case where a current flowing through the semiconductor device 1 exceeds a reference value, the overcurrent protection circuit determines that the semiconductor device 1 is abnormal (detects an abnormality). For example, in the case where a temperature of the semiconductor device 1 exceeds a reference value, the overheat protection circuit determines that the semiconductor device 1 is abnormal. For example, in the case where a voltage supplied to the semiconductor device 1 exceeds a reference value, the overvoltage protection circuit determines that the semiconductor device 1 is abnormal. The voltage drop detection circuit detects a drop in the gate voltage of, for example, the MOSFETs 160a, 160b, 260a′, and 260b′. The protection circuit 401 may be provided inside each of the control circuits 140b and 240b.

The present modification also produces advantageous effects similar to those of the fourth embodiment.

Furthermore, the present modification provides the secondary-side circuit with the protection circuit 401. This can suppress breakage of the semiconductor device 1.

### 5. Fifth Embodiment

A semiconductor device according to a fifth embodiment will be described. The semiconductor device 1 according to the fifth embodiment differs from that of the first embodiment in terms of the circuit configuration of the switch elements SW1 and SW2 and the structure of the semiconductor device 1. The following will omit a description of configurations similar to those of the first embodiment and will mainly provide a description of configurations different from those of the first embodiment.

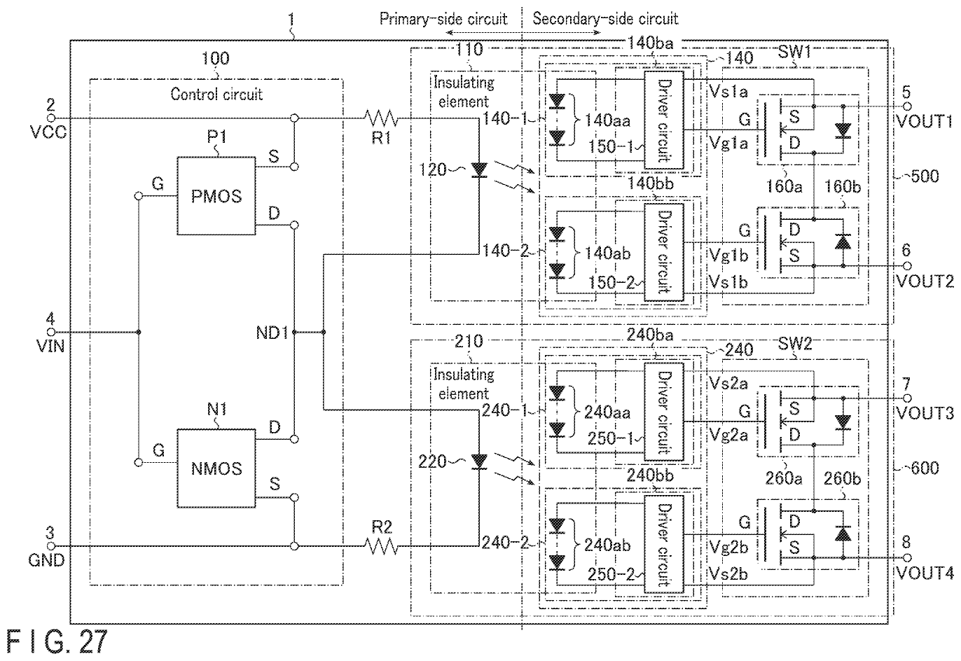

A configuration of the semiconductor device 1 will be described with reference to FIG. 27. FIG. 27 is a circuit diagram showing an example of the configuration of the semiconductor device 1.

As shown in FIG. 27, the light receiving unit 140 includes light receiving units 140-1 and 140-2. The light receiving unit 140-1 includes a light receiving element 140aa and a control circuit 140ba. The control circuit 140ba includes a driver circuit 150-1. The light receiving unit 140-2 includes a light receiving element 140ab and a control circuit 140bb. The control circuit 140bb includes a driver circuit 150-2. The light receiving unit 240 includes light receiving units 240-1 and 240-2. The light receiving unit 240-1 includes a light receiving element 240aa and a control circuit 240ba. The control circuit 240ba includes a driver circuit 250-1. The light receiving unit 240-2 includes a light receiving element 240ab and a control circuit 240bb. The control circuit 240bb includes a driver circuit 250-2.

The gate of the MOSFET 160a is coupled to the driver circuit 150-1. A voltage Vg1a is applied from the driver circuit 150-1 to the gate of the MOSFET 160a. The drain of the MOSFET 160a is coupled to the drain of the MOSFET 160b. The source of the MOSFET 160a is coupled to the input/output terminal 5 and the driver circuit 150-1. A voltage Vs1a is applied from the driver circuit 150-1 to the source of the MOSFET 160a. The gate of the MOSFET 160b is coupled to the driver circuit 150-2. A voltage Vg1b is applied from the driver circuit 150-2 to the gate of the MOSFET 160b. The source of the MOSFET 160b is coupled to the input/output terminal 6 and the driver circuit 150-2. A voltage Vs1b is applied from the driver circuit 150-2 to the source of the MOSFET 160b. The gate of the MOSFET 260a is coupled to the driver circuit 250-1. A voltage Vg2a is applied from the driver circuit 250-1 to the gate of the MOSFET 260a. The drain of the MOSFET 260a is coupled to the drain of the MOSFET 260b. The source of the MOSFET 260a is coupled to the input/output terminal 7 and the driver circuit 250-1. A voltage Vs2a is applied from the driver circuit 250-1 to the source of the MOSFET 260a. The gate of the MOSFET 260b is coupled to the driver circuit 250-2. A voltage Vg2b is applied from the driver circuit 250-2 to the gate of the MOSFET 260b. The source of the MOSFET 260b is coupled to the input/output terminal 8 and the driver circuit 250-2. A voltage Vs2b is applied from the driver circuit 250-2 to the source of the MOSFET 260b.

The rest of the circuit configuration is similar to that shown in FIG. 1 described in the first embodiment.

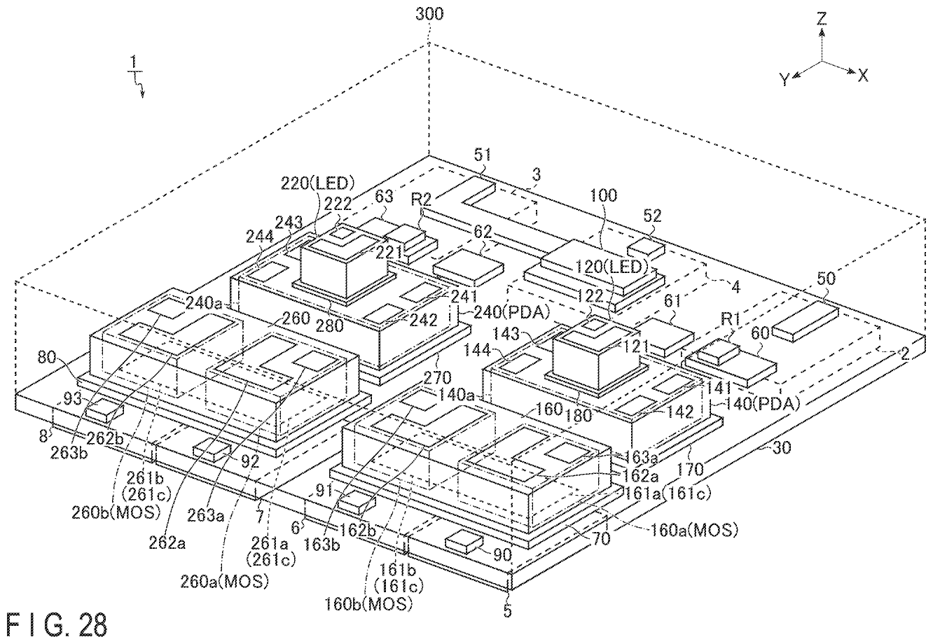

The structure of the semiconductor device 1 will be described with reference to FIG. 28. FIG. 28 is a perspective view showing an example of the structure of the semiconductor device 1.

As shown in FIG. 28, the semiconductor device 1 further includes electrodes 70, 80, and 90 to 93. The electrodes 70a, 70b, 80a, and 80b in the first embodiment are eliminated.

The electrodes 70, 80, and 90 to 93 are provided on the upper surface of the substrate 30.

Although not illustrated in FIG. 28, the light receiving unit 140 includes the light receiving units 140-1 and 140-2. The electrode 141 functions as, for example, an anode electrode of the light receiving element 140aa included in the light receiving unit 140-1. The electrode 142 functions as, for example, a cathode electrode of the light receiving element 140aa. The electrode 143 functions as, for example, an anode electrode of the light receiving element 140ab included in the light receiving unit 140-2. The electrode 144 functions as, for example, a cathode electrode of the light receiving element 140ab. Although not shown in FIG. 28, the light receiving unit 240 includes the light receiving units 240-1 and 240-2. The electrode 241 functions as, for example, an anode electrode of the light receiving element 240aa included in the light receiving unit 240-1. The electrode 242 functions as, for example, a cathode electrode of the light receiving element 240aa. The electrode 243 functions as, for example, an anode electrode of the light receiving element 240ab included in the light receiving unit 240-2. The electrode 244 functions as, for example, a cathode electrode of the light receiving element 240ab.

The MOSFETs 160a and 160b are provided as, for example, a single chip (hereinafter referred to as a “chip 160”). In other words, the MOSFETs 160a and 160b (the chip 160) are provided on the electrode 70 in an integral manner. In the example illustrated in FIG. 28, the electrodes 161a and 161b each functioning as a drain electrode are integrally formed as a common electrode (hereinafter referred to as an “electrode 161c”). The electrode 161c is arranged on the lower surface of the chip 160. On the lower surface of the chip 160, the electrode 161c is arranged in contact with the electrode 70. The electrodes 162a and 163a are arranged on the upper surface of the chip 160. The MOSFET 160a includes the electrodes 161c, 162a, and 163a. The electrodes 162b and 163b are arranged on the upper surface of the chip 160. The electrode 162b is spaced apart from the electrode 162a. The MOSFET 160b includes electrodes 161c, 162b, and 163b.

The MOSFETs 260a and 260b are provided as, for example, a single chip (hereinafter referred to as a “chip 260”). In other words, the MOSFETs 260a and 260b (the chip 260) are provided on the electrode 80 in an integral manner. In the example shown in FIG. 28, the electrodes 261a and 261b each functioning as a drain electrode are integrally formed as a common electrode (hereinafter referred to as an “electrode 261c”). The electrode 261c is arranged on the lower surface of the chip 260. On the lower surface of the chip 260, the electrode 261c is arranged in contact with the electrode 80. The electrodes 262a and 263a are arranged on the upper surface of the chip 260. The MOSFET 260a includes electrodes 261c, 262a, and 263a. The electrodes 262b and 263b are arranged on the upper surface of the chip 260. The electrode 262b is spaced apart from the electrode 262a. The MOSFET 260b includes the electrodes 261c, 262b, and 263b.

Furthermore, the adhesive layers 180 and 280 are, for example, insulating films.

Although not shown in FIG. 28, the input/output terminal 5 is electrically coupled to the electrode 90 via a conductor penetrating the substrate 30. Although not shown in FIG. 28, the input/output terminal 6 is electrically coupled to the electrode 91 via a conductor penetrating the substrate 30. Although not shown in FIG. 28, the input/output terminal 7 is electrically coupled to the electrode 92 via a conductor penetrating the substrate 30. Although not shown in FIG. 28, the input/output terminal 8 is electrically coupled to the electrode 93 via a conductor penetrating the substrate 30.

The rest of the structure is similar to that shown in FIG. 2 described in the first embodiment.

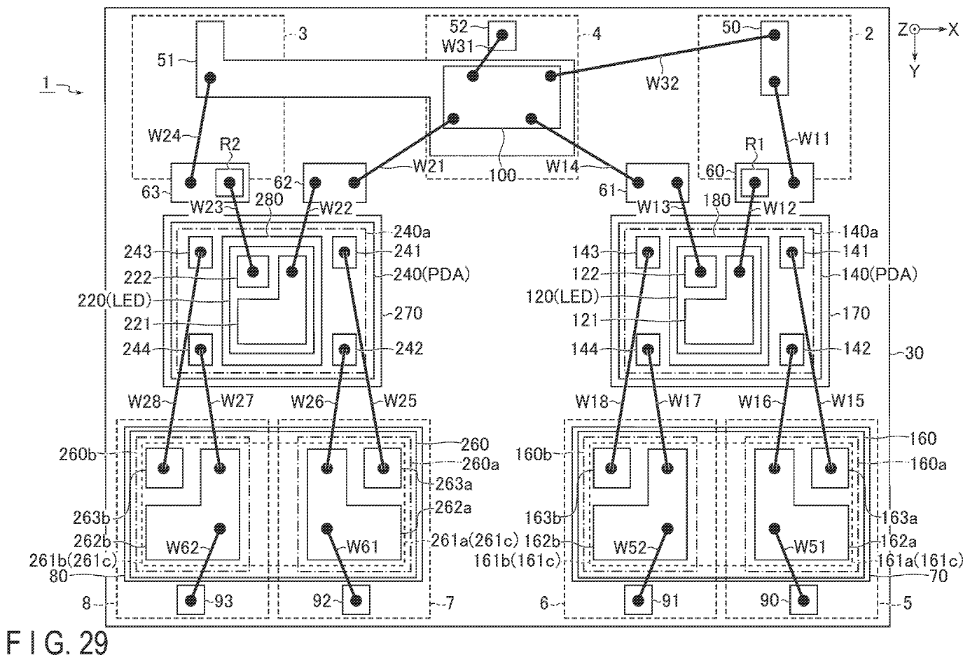

Electrical coupling within the semiconductor device 1 will be described with reference to FIG. 29. FIG. 29 is a plan view showing an example of the planar structure of the semiconductor device 1.

As shown in FIG. 29, the semiconductor device 1 further includes interconnects W51, W52, W61, and W62. The interconnects W19 and W29 in the first embodiment are eliminated.

The interconnects W51, W52, W61, and W62 are, for example, wire that is formed by wire bonding. The interconnects W51, W52, W61, and W62 are formed of a conductive material. The interconnects W51, W52, W61, and W62 may be, for example, a flexible substrate.

The interconnect W51 provides electrical coupling between the electrode 162a and the electrode 90. The interconnect W52 provides electrical coupling between the electrode 162b and the electrode 91. The interconnect W61 provides electrical coupling between the electrode 262a and the electrode 92. The interconnect W62 provides electrical coupling between the electrode 262b and the electrode 93.

The rest of the structure is similar to that shown in FIG. 3 described in the first embodiment.

In the case of eliminating the electrodes 60 to 63, the number of interconnects can be reduced by coupling the control circuit 100 to the light emitting element 120 via an interconnect and coupling the control circuit 100 to the light emitting element 220 via an interconnect. Specifically, the resistance elements R1 and R2 are each incorporated in the control circuit 100. While the interconnects W12 and W13 are eliminated, the interconnect W11 is directly coupled to the electrode 121, and the interconnect W14 is directly coupled to the electrode 122. While the interconnects W22 and W23 are eliminated, the interconnect W21 is directly coupled to the electrode 221, and the interconnect W24 is directly coupled to the electrode 222.

The present embodiment also produces advantageous effects similar to those of the first embodiment.

The circuit configurations of the magnetic coupling, the capacitance coupling, the magnetic resonance coupling, and the sonic wave coupling described in the fourth to eighth modifications of the first embodiment are applicable to the semiconductor device 1 according to the present embodiment. The circuit configuration of the switch elements SW1 and SW2 in the semiconductor device 1 according to the present embodiment is applicable to the second embodiment, the first to fifth modifications of the second embodiment, the third embodiment, the fourth embodiment, and the first modification of the fourth embodiment. Furthermore, the structure of the semiconductor device 1 according to the present embodiment in which the MOSFETs 160a and 160b are formed as a single chip and the drain electrodes 161a and 161b are integrally formed, and the structure in which the MOSFETs 260a and 260b are formed as a single chip and the drain electrodes 261a and 261b are integrally formed are applicable to the first to third modifications of the first embodiment.

### 6. Modification, Etc

As described above, a semiconductor device (1) according to an embodiment includes: a first insulating element (110) and a second insulating element (210) each controlled based on a control signal (VIN); a first control circuit (100) configured to control selection of one of the first insulating element (110) and the second insulating element (210) based on the control signal (VIN); a first switch element (SW1); a second switch element (SW2); a second control circuit (140b) configured to control the first switch element (SW1) based on an output of the first insulating element (110); and a third control circuit (240b) configured to control the second switch element (SW2) based on an output of the second insulating element (210).

The embodiments are not limited to those described in the above, and various modifications can be made.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device comprising:
a first insulating element and a second insulating element each controlled based on a control signal;
a first control circuit configured to control selection of one of the first insulating element and the second insulating element based on the control signal;
a first switch element;
a second switch element;
a second control circuit configured to control the first switch element based on an output of the first insulating element; and
a third control circuit configured to control the second switch element based on an output of the second insulating element.

2. The device according to claim 1, wherein
the first switch element includes a first MOSFET of an enhancement type and a second MOSFET of an enhancement type,
the second switch element includes a third MOSFET of an enhancement type and a fourth MOSFET of an enhancement type,
the second control circuit controls a first gate voltage and a first source voltage of the first MOSFET and a second gate voltage and a second source voltage of the second MOSFET based on the output of the first insulating element, and
the third control circuit controls a third gate voltage and a third source voltage of the third MOSFET and a fourth gate voltage and a fourth source voltage of the fourth MOSFET based on the output of the second insulating element.

3. The device according to claim 2, wherein
a source of the first MOSFET is coupled to a source of the second MOSFET, and
a source of the third MOSFET is coupled to a source of the fourth MOSFET.

4. The device according to claim 1, wherein
the first control circuit includes:
a first transistor having a gate to which the control signal is input, a source to which a power supply voltage is applied, and a drain coupled to a first node; and
a second transistor having a gate to which the control signal is input, a drain coupled to the first node, and a source to which a ground voltage is applied, and
one of the first insulating element and the second insulating element is selected based on a voltage of the first node.

5. The device according to claim 2, wherein
the first insulating element includes a first light emitting element and a first light receiving element, and
the second insulating element includes a second light emitting element and a second light receiving element.

6. The device according to claim 5, wherein
the first control circuit includes:
a first transistor having a gate to which the control signal is input, a source to which a power supply voltage is applied, and a drain coupled to a first node; and
a second transistor having a gate to which the control signal is input, a drain coupled to the first node, and a source to which a ground voltage is applied, and
an anode of the first light emitting element is configured to be coupled to the source of the first transistor,
a cathode of the first light emitting element is coupled to the first node,
an anode of the second light emitting element is coupled to the first node, and
a cathode of the second light emitting element is configured to be coupled to the source of the second transistor.

7. The device according to claim 5, further comprising a substrate, wherein
the first MOSFET, the second MOSFET, the third MOSFET, and the fourth MOSFET are provided above the substrate,
the first light receiving element and the second light receiving element are provided above the substrate,
the first light emitting element is provided above the first light receiving element,
the second light emitting element is provided above the second light receiving element,
a partial upper surface of the first light receiving element and the first light emitting element are covered with a first sealing member, and
a partial upper surface of the second light receiving element and the second light emitting element are covered with a second sealing member.

8. The device according to claim 5, further comprising a substrate, wherein
the first MOSFET, the second MOSFET, the third MOSFET, and the fourth MOSFET are provided above the substrate,
the first light receiving element is provided on the first MOSFET and the second MOSFET,
the second light receiving element is provided on the third MOSFET and the fourth MOSFET,
the first light emitting element is provided above the first light receiving element, and
the second light emitting element is provided above the second light receiving element.

9. The device according to claim 5, further comprising a substrate, wherein
the first MOSFET and the second MOSFET are integrally provided above the substrate,
the third MOSFET and the fourth MOSFET are integrally provided above the substrate,
the first light receiving element is provided on the first MOSFET and the second MOSFET,
the second light receiving element is provided on the third MOSFET and the fourth MOSFET,
the first light emitting element is provided above the first light receiving element, and
the second light emitting element is provided above the second light receiving element.

10. The device according to claim 1, wherein the first control circuit includes a first circuit configured to cause, based on the control signal, one of the first insulating element and the second insulating element to operate at a timing different from a timing of a remaining one.

11. The device according to claim 10, wherein
the first control circuit further includes:
a second circuit configured to drive the first insulating element based on a first voltage; and
a third circuit configured to drive the second insulating element based on a second voltage, and
the first circuit supplies the first voltage to the second circuit at a first time based on the control signal, and supplies the second voltage to the third circuit at a second time different from the first time based on the control signal.

12. The device according to claim 1, wherein
the first switch element includes a fifth MOSFET of an enhancement type and a sixth MOSFET of an enhancement type,
the second switch element includes a seventh MOSFET of a depression type and an eighth MOSFET of a depression type,
the second control circuit controls a fifth gate voltage and a fifth source voltage of the fifth MOSFET and a sixth gate voltage and a sixth source voltage of the sixth MOSFET based on the output of the first insulating element, and
the third control circuit controls a seventh gate voltage and a seventh source voltage of the seventh MOSFET and an eighth gate voltage and an eighth source voltage of the eighth MOSFET based on the output of the second insulating element.

13. The device according to claim 12, wherein
a source of the fifth MOSFET is coupled to a source of the sixth MOSFET, and
a source of the seventh MOSFET is coupled to a source of the eighth MOSFET.

14. The device according to claim 12, wherein the first control circuit includes a first circuit configured to cause, based on the control signal, one of the first insulating element and the second insulating element to operate at a timing different from a timing of a remaining one.

15. The device according to claim 14, wherein
the first control circuit further includes:
a fourth circuit configured to drive the first insulating element based on a third voltage; and
a fifth circuit configured to drive the second insulating element based on a fourth voltage, and
the first circuit supplies the third voltage to the fourth circuit at a third time based on the control signal, and supplies the fourth voltage to the fifth circuit at a fourth time different from the third time based on the control signal.

16. The device according to claim 2, wherein
a drain of the first MOSFET is coupled to a drain of the second MOSFET, and
a drain of the third MOSFET is coupled to a drain of the fourth MOSFET.

17. The device according to claim 1, wherein each of the first insulating element and the second insulating element includes two coils.

18. The device according to claim 1, wherein each of the first insulating element and the second insulating element includes a capacitance element.

19. The device according to claim 1, wherein each of the first insulating element and the second insulating element includes two resonance circuits.

20. The device according to claim 1, wherein each of the first insulating element and the second insulating element includes an oscillator and an oscillation power generating device.
